(19) United States
(12) Patent Application Publication
(10) Pub. No.: US 2019/0276575 A1
(43) Pub. Date: Sep. 12, 2019

(54) METHOD FOR PRODUCING RESIN AND METHOD FOR PRODUCING ACTINIC RAY-SENSITIVE OR RADIATION-SENSITIVE COMPOSITION

(71) Applicant: FUJIFILM Corporation, Tokyo (JP)

(72) Inventors: Akihiro KANEKO, Haibara-gun (JP); Shuji Hirano, Haibara-gun (JP); Wataru Nihashi, Haibara-gun (JP)

(73) Assignee: FUJIFILM Corporation, Tokyo (JP)

(21) Appl. No.: 16/362,820

(22) Filed: Mar. 25, 2019

Related U.S. Application Data
(63) Continuation of application No. PCT/JP2017/035839, filed on Oct. 2, 2017.

(30) Foreign Application Priority Data
Oct. 31, 2016 (JP) 2016-212953
Mar. 7, 2017 (JP) 2017-042996

(51) Int. Cl. C08F 212/14; G03F 7/20; G03F 7/039; G03F 7/038; C08F 220/16

(52) U.S. Cl. CPC C08F 212/14; G03F 7/20; C08F 220/16; G03F 7/038; G03F 7/039

(57) ABSTRACT

By a method for producing a resin, a resin containing a repeating unit represented by General Formula (1) and a repeating unit containing a group that decomposes by the action of an acid to generate a polar group is produced, and the method includes a first step of obtaining a resin precursor containing a repeating unit represented by General Formula (2) and the repeating unit containing a group that decomposes by the action of an acid to generate a polar group, and a second step of obtaining the repeating unit represented by General Formula (1) by deprotecting a group represented by —OY in the repeating unit represented by General Formula (2) in the resin precursor with an acid or a base.

### CROSS-REFERENCE TO RELATED APPLICATIONS

This application is a Continuation of PCT International Application No. PCT/JP2017/035839, filed on Oct. 2, 2017, which claims priority under 35 U.S.C. § 119(a) to Japanese Patent Application No. 2016-212953, filed on Oct. 31, 2016, and Japanese Patent Application No. 2017-042996, filed on Mar. 7, 2017. Each of the above application(s) is hereby expressly incorporated by reference, in its entirety, into the present application.

### BACKGROUND OF THE INVENTION

### 1. Field of the Invention

The present invention relates to a method for producing a resin and a method for producing an actinic ray-sensitive or radiation-sensitive composition.

### 2. Description of the Related Art

In processes for manufacturing semiconductor devices such as an integrated circuit (IC) and a large scale integrated circuit (LSI) in the related art, microfabrication by lithography using an actinic ray-sensitive or radiation-sensitive composition (hereinafter also referred to as a “resist composition” in the present specification) has been carried out.

In recent years, formation of finer patterns has been demanded in accordance with realization of high integration for integrated circuits, and in the formation of a fine pattern, a chemically amplified actinic ray-sensitive or radiation-sensitive film (hereinafter also referred to as a “resist film” in the present specification) using an acid as a catalyst has been used. As an exposure light source in such a case, high energy beams such as KrF excimer laser light, ArF excimer laser light, EUV (EUV is an abbreviation of extreme ultraviolet rays), and EB (EB is an abbreviation of electron beams) have been used in many cases.

Such a technique for forming a fine pattern has also been used in a method for forming a photomask blank in the preparation of a photomask for manufacturing a semiconductor.

As a resin for use in the resist composition, a resin which contains a repeating unit containing a hydroxyl group and a group that decomposes by the action of an acid to generate a polar group (hereinafter also referred to as an “acid-decomposable group” in the present specification) is known. JP2002-062652A describes a resist material which contains a 4-hydroxystyrene-based repeating unit and a repeating unit having an acid-decomposable group.

### SUMMARY OF THE INVENTION

The present inventors have demonstrated that in a case where a resist film is formed using a resist composition containing the resist material described in 2002-062652A, and the resist film is exposed and developed to form a pattern, its resolution does not reach a level that has recently been required. In addition, a reduction in scum has also been required in the formation of a pattern.

Therefore, an object of the present invention is to provide a method for producing a resin, which is capable of forming a resist film having excellent resolution and is also capable of producing a resin that can reduce scum in the formation of a pattern. In addition, another object of the present invention is to provide a method for producing an actinic ray-sensitive or radiation-sensitive composition.

The present inventors have conducted extensive studies in order to accomplish the objects, and as a result, they have found that the objects can be accomplished by the following configuration.

[1] A method for producing a resin containing a repeating unit represented by General Formula (1) and a repeating unit containing a group that decomposes by the action of an acid to generate a polar group, the method comprising:

a first step of obtaining a resin precursor containing a repeating unit represented by General Formula (2) and the repeating unit containing a group that decomposes by the action of an acid to generate a polar group; and

a second step of obtaining the repeating unit represented by General Formula (1) by deprotecting a group represented by —OY in the repeating unit represented by General Formula (2) in the resin precursor with an acid or a base.

[2] The method for producing a resin as described in [1],

in which the repeating unit containing a group that decomposes by the action of an acid to generate a polar group is represented by General Formula (3).

[3] The method for producing a resin as described in [1] or [2],

in which Y is represented by General Formula (4) and the group represented by —OY is deprotected with a base in the second step.

[4] The method for producing a resin as described in [3],

in which an acid dissociation constant of a conjugate acid of the base is 6.0 or more.

[5] The method for producing a resin as described in [1] or [2],

in which Y is represented by General Formula (5) and the group represented by —OY is deprotected with an acid in the second step; or the repeating unit represented by General Formula (2) is represented by General Formula (6) and a group represented by —O—Z—O— is deprotected with an acid in the second step.

[6] The method for producing a resin as described in [5],

in which the repeating unit represented by General Formula (2) is represented by General Formula (6) and the group represented by —O—Z—O— is deprotected with an acid in the second step.

[7] The method for producing a resin as described in [5] or [6],

in which an acid dissociation constant of the acid is −1.0 or more.

[8] The method for producing a resin as described in any one of [1] to [7],

in which the content of the repeating unit represented by General Formula (1) in the resin is 15% by mole or more with respect to all the repeating units in the resin.

[9] A method for producing an actinic ray-sensitive or radiation-sensitive composition, the method comprising a step of mixing a resin produced by the method for producing a resin as described in any one of [1] to [8] and a compound that generates an acid upon irradiation with actinic rays or radiation.

According to the present invention, it is possible to provide a method for producing a resin, which is capable of forming a resist film having excellent resolution and is capable of producing a resin that can reduce scum in the formation of a pattern. In addition, the present invention can provide a method for producing an actinic ray-sensitive or radiation-sensitive composition.

### DESCRIPTION OF THE PREFERRED EMBODIMENTS

Moreover, in citations for a group and an atomic group in the present specification, in a case where the group or the atomic group is denoted without specifying whether it is substituted or unsubstituted, the group or the atomic group includes both a group or an atomic group not containing a substituent and a group or an atomic group containing a substituent. For example, an “alkyl group” which is not denoted about whether it is substituted or unsubstituted includes not only an alkyl group not containing a substituent (unsubstituted alkyl group), but also an alkyl group containing a substituent (substituted alkyl group).

In the present invention, “actinic rays” or “radiation” means, for example, a bright line spectrum of a mercury lamp, an excimer laser, extreme ultraviolet rays (EUV rays), X-rays, electron beams, ion beams, or the like. In addition, in the present invention, “light” means actinic rays or radiation.

In addition, “exposure” in the present specification is intended to mean, unless otherwise specified, not only exposure by a bright line spectrum of a mercury lamp, an excimer laser, X-rays, extreme ultraviolet rays (EUV rays), or the like, but also writing by electron beams, ion beams, or the like.

Furthermore, in the present specification, “(meth)acrylate” means “at least one of acrylate or methacrylate”. In addition, “(meth)acrylic acid” means “at least one of acrylic acid or methacrylic acid”.

Moreover, in the present specification, “(a value) to (a value)” means a range including the numerical values described before and after “to” as a lower limit value and an upper limit value, respectively.

[Method for Producing Resin]

The method for producing a resin according to an embodiment of the present invention is a method for producing a resin, in which a resin containing a repeating unit represented by General Formula (1) and a repeating unit containing a group that decomposes by the action of an acid to generate a polar group is produced. The method for producing a resin according to the embodiment of the present invention includes the following steps.
First step: A step of obtaining a resin precursor containing a repeating unit represented by General Formula (2) and a repeating unit containing a group that decomposes by the action of an acid to generate a polar group; and
Second step: A step of obtaining the repeating unit represented by General Formula (1) by deprotecting a group represented by —OY in the repeating unit represented by General Formula (2) in the resin precursor with an acid or a base.

Taking into consideration a view that there is room for improvement of the resolution of the resist film formed from a resist composition that contains a resin containing a repeating unit containing a hydroxyl group and a repeating unit containing an acid-decomposable group, described in JP2002-062652A, the present inventors have undergone studies, focusing on the number of hydroxyl groups contained in the repeating units.

That is, the present inventors have considered that a resist film having more excellent resolution is obtained in a case of using a resist composition which contains a resin containing a polyhydric hydroxystyrene-based repeating unit, they have conducted extensive studies. However, a resist film obtained from the resist composition which contains a resin containing a polyhydric hydroxystyrene-based repeating unit has lower limit resolution, but residues (scum) are generated in the unexposed area during development in some cases. Therefore, with regard to the above aspects, it was not possible to accomplish both of the two objects of making it possible to form a resist film having excellent resolution as well as to reduce scum upon formation of a pattern. Further, in the present specification, the limit resolution and the scum are intended to mean performance of a resist film to be evaluated by a method which will be described in Examples, and an expression of “the resist film has excellent resolution” is intended to mean a state where the resist film has low limit resolution and generation of scum is suppressed.

The present inventors have conducted extensive studies, and as a result, they have first found that polyhydric hydroxystyrene is unintendedly polymerized upon synthesis of a resin, which can possibly cause scum. It was presumed that the polyhydric hydroxystyrene has lower stability as a monomer, as compared with the hydroxystyrenes in the related art, and the polyhydric hydroxystyrenes easily form a polymer, and as a result, they unintendedly produce a polymeric substance upon synthesis of a resin, which causes scum. Based on this, an invention of the production method of the embodiment of the present invention, in which a resin precursor containing a repeating unit represented by General Formula (2) and a repeating unit containing a group that decomposes by the action of an acid to generate a polar group is obtained, and the group represented by —OY in the resin precursor is deprotected with an acid or a base to produce a resin containing a polyhydric hydroxystyrene-based repeating unit and a repeating unit containing an acid-decomposable group, has been completed.

Hereinafter, the resin (hereinafter also referred to as a “resin (A)”) produced by the production method will first be described, and then the method for producing the resin (A) will be described with reference to each of the steps.

[Resin (A)]

The resin (A) can be any resin that contains a repeating unit represented by General Formula (1) which will be described later (hereinafter also referred to as a “repeating unit (a)”) and a repeating unit containing a group that decomposes by the action of an acid to generate a polar group (hereinafter also referred to as a “repeating unit (b)”), and may also contain another repeating unit (hereinafter also referred to as a “repeating unit (c)”) other than the above repeating units. Hereinafter, each of the repeating units contained in the resin (A) will be described.

<Repeating Unit (a)>

The resin (A) contains the repeating unit (a). It is presumed that since the repeating unit (a) contains a plurality of hydroxyl groups in the repeating unit, a resist film formed from the resist composition containing the resin (A) has more excellent adhesiveness onto a substrate which will be described later, or the like. Accordingly, it is presumed that the resist film formed from the resist composition containing the resin (A) is hardly detached from a substrate or the like even in the case where the pattern has a small line width, and as a result, the resist film has more excellent resolution.

The content of the repeating unit (a) in the resin (A) is not particularly limited and generally, it is preferably 5% by mole or more, more preferably 15% by mole or more, and still more preferably 25% by mole or more, with respect to all the repeating units in the resin. The upper limit is not particularly limited, and is preferably 90% by mole or less, more preferably 80% by mole or less, and still more preferably 70% by mole or less.

In a case where the content of the repeating unit (a) is 15% by mole or more, a resist composition containing the resin has more excellent resolution.

The repeating units (a) may be used alone or in combination of two or more kinds thereof. In a case where two or more kinds of the repeating units (a) are used in combination, the total content thereof is preferably within the range.

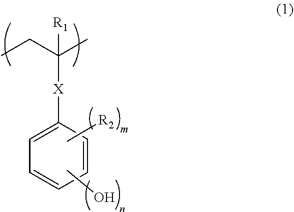

In General Formula (1), R₁ represents a hydrogen atom, a halogen atom, an alkyl group, a cycloalkyl group, a cyano group, or an alkoxycarbonyl group, X represents a single bond, —COO—, or —CONR₃—, R₂ represents a substituent, R₃ represents a hydrogen atom, or an alkyl group, n represents an integer of 2 to 5, and m represents an integer of 0 to 3. Further, R₂'s which are present in plural number may be the same as or different from each other.

In General Formula (1), as the halogen atom of R₁, a fluorine atom, a chlorine atom, a bromine atom, or an iodine atom is preferable, and the fluorine atom is more preferable.

In General Formula (1), the alkyl group as R₁ is not particularly limited and examples thereof include a methyl group, an ethyl group, a propyl group, an isopropyl group, an n-butyl group, a sec-butyl group, a hexyl group, a 2-ethylhexyl group, an octyl group, and a dodecyl group, each of which may contain a substituent.

The number of carbon atoms of the alkyl group is not particularly limited and generally, it is preferably 20 or less, more preferably 8 or less, and still more preferably 3 or less.

In General Formula (1), the cycloalkyl group as R₁ is not particularly limited and examples thereof include known cycloalkyl groups. The cycloalkyl group may be either monocyclic or polycyclic. Examples of the cycloalkyl group include a cyclopropyl group, a cyclopentyl group, and a cyclohexyl group, each of which may contain a substituent, and among those, a cycloalkyl group which has 3 to 8 carbon atoms and is monocyclic is preferable.

In General Formula (1), the alkyl group contained in the alkoxycarbonyl group of R₁ is the same as one described above as the alkyl group of R₁.

In General Formula (1), R₂ represents a substituent. The substituent is not particularly limited and examples thereof include known substituents. Examples of the substituent include a linear or branched alkyl group having 1 to 20 carbon atoms, such as a methyl group, an ethyl group, a propyl group, an isopropyl group, an n-butyl group, an isobutyl group, a t-butyl group, a pentyl group, a hexyl group, an octyl group, and a dodecyl group; an alkoxy group having the alkyl group moiety; a cycloalkyl group such as a cyclopentyl group and a cyclohexyl group; a cycloalkoxy group containing the cycloalkyl group moiety; a halogen atom, an aryl group, a cyano group, a nitro group, an acyl group, an acyloxy group, an acylamino group, a sulfonylamino group, an alkylthio group, an arylthio group, an aralkylthio group, a thiophenecarbonyloxy group, and a thiophenemethylcarbonyloxy group; and a hetero ring residue such as a pyrrolidone residue.

As the substituent, the linear or branched alkyl group having 1 to 5 carbon atoms or the alkoxy group containing the alkyl group moiety is preferable, and the methyl group or the methoxy group is more preferable.

In General Formula (1), n is an integer of 2 to 5, and more preferably an integer of 2 or 3.

General Formula (1), m is an integer of 0 to 3, and more preferably 0.

In General Formula (1), X represents a single bond, —COO—, or —CONR₃—, and R₃ represents a hydrogen atom or an alkyl group. Examples of the alkyl group of R₃ include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, each of which may contain a substituent, and an alkyl group having 8 or less carbon atoms is preferable.

As X, a single bond, —COO—, or —CONH— is preferable, and a single bond or COO— is more preferable.

<Repeating Unit (b)>

The resin (A) contains the repeating unit (b) containing a group that decomposes by the action of an acid to generate a polar group. The repeating unit (b) is a repeating unit other than the repeating unit (a).

The content of the repeating unit (b) in the resin (A) is not particularly limited and generally, it is preferably 5% to 90% by mole, and more preferably 10% to 70% by mole, with respect to all the repeating units in the resin. The repeating units (b) may be used alone or in combination of two or more kinds thereof. In a case where two or more kinds of the repeating units (b) are used in combination, the total content thereof is preferably within the range.

Examples of the polar group include a carboxyl group, an alcoholic hydroxyl group, a phenolic hydroxyl group, and a sulfonic acid group.

As the acid-decomposable group, a group having the polar group protected with a protective group (preferably a group in which a hydrogen atom of the polar group is substituted with a protective group) is preferable.

As the repeating unit (b), a repeating unit having a group that decomposes by the action of an acid to generate a carboxyl group is preferable. The repeating unit having a group that decomposes by the action of an acid to generate a carboxyl group is a repeating unit having a group in which a hydrogen atom of the carboxyl group is substituted with a group (protective group) that decomposes by the action of an acid to leave.

The repeating unit (b) preferably contains a repeating unit (b) containing an acid-decomposable group formed only of carbon atoms and hydrogen atoms, in which a polar group is protected with a protective group P having a number of carbon atoms of 5 to 12 (having 5 to 12 carbon atoms).

By using the repeating unit (a) represented by General Formula (1), having 2 or more hydroxyl group, and the repeating unit (b) having an acid-decomposable group formed by the protection with the protective group P in combination, the resist film has more excellent resolution.

The effect is significant, particularly in a case where the protective group P is a group represented by —C(Rx₁)(Rx₂)(Rx₃). A reason therefor is that the reactivity of the resist composition can be adjusted to a preferred range, and both of high sensitivity and high resolution can be satisfied. Here, the symbols represented by Rx₁, Rx₂, and Rx₃, respectively, have the same definitions as Rx₁, Rx₂, and Rx₃ in General Formula (A1) which will be described below, respectively.

It is preferable that the resin (A) contains a repeating unit represented by General Formula (A1) as the repeating unit (b).

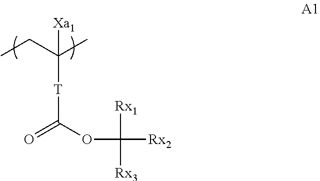

In General Formula (A1),

Xa₁ represents a hydrogen atom, a halogen atom, an alkyl group, a cycloalkyl group, a cyano group, or an alkoxycarbonyl group.

T represents a single bond or a divalent linking group.

Rx₁, Rx₂, and Rx₃ each independently represent an (linear or branched) alkyl group, a (monocyclic or polycyclic) cycloalkyl group, or a phenyl group, provided that in a case where all of Rx₁, Rx₂, and Rx₃ are (linear or branched) alkyl groups, it is preferable that at least two of Rx₁, Rx₂, or Rx₃ are methyl groups.

Two of Rx₁, Rx₂, and Rx₃ may be bonded to form a ring (for example, a (monocyclic or polycyclic) cycloalkyl group).

It is preferable that Rx₁, Rx₂, and Rx₃ are each constituted only with carbon atoms and hydrogen atoms, and it is more preferable that a total number of carbon atoms included in Rx₁, Rx₂, and Rx₃ is from 4 to 11.

Examples of the alkyl group represented by Xa₁ include a methyl group and a group represented by —CH₂—R₁₁. R₁₁ represents a halogen atom (a fluorine atom or the like), a hydroxyl group, or a monovalent organic group, and examples thereof include an alkyl group having 5 or less carbon atoms and an acyl group having 5 or less carbon atoms. R₁ is preferably an alkyl group having 3 or less carbon atoms, and more preferably a methyl group. In one aspect, Xa₁ is preferably a hydrogen atom, a methyl group, a trifluoromethyl group, or a hydroxymethyl group.

Examples of the divalent linking group of T include an alkylene group, an arylene group, a —COO-Rt- group, and an —O-Rt- group. In the formulae, Rt represents an alkylene group or a cycloalkylene group.

T is preferably a single bond, an arylene group, or a —COO-Rt- group, and more preferably a single bond or an arylene group. As the arylene group, an arylene group having 6 to 10 carbon atoms is preferable, and a phenylene group is more preferable. Rt is preferably an alkylene group having 1 to 5 carbon atoms, and more preferably a —CH₂— group, a —(CH₂)₂— group, or a —(CH₂)₃— group.

As the alkyl group of each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group is preferable.

As the cycloalkyl group of each of Rx₁ to Rx₃, a monocyclic cycloalkyl group such as a cyclopentyl group and a cyclohexyl group; or a polycyclic cycloalkyl group such as a norbornyl group is preferable.

Examples of a ring formed by the bonding of two of Rx₁ to Rx₃ include a cycloalkyl group. As the cycloalkyl group, a monocyclic cycloalkyl group such as a cyclopentyl group and a cyclohexyl group; or a polycyclic cycloalkyl group such as a norbornyl group, a tetracyclodecanyl group, and an adamantyl group is preferable. Among those, a monocyclic cycloalkyl group having 5 or 6 carbon atoms is more preferable.

With regard to the repeating unit represented by General Formula (A1), for example, an aspect in which Rx₁ is a methyl group or an ethyl group, and Rx₂ and Rx₃ are bonded to form the above-mentioned cycloalkyl group is preferable.

Each of the groups may have a substituent and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), among which the groups having 4 or less carbon atoms are preferable.

As the repeating unit (b), a repeating unit represented by General Formula (3) is more preferable.

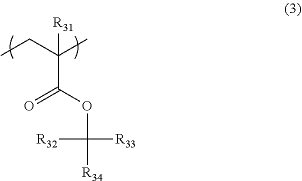

In General Formula (3), R₃₁ represents a hydrogen atom, a halogen atom, an alkyl group, a cycloalkyl group, a cyano group, or an alkoxycarbonyl group, R₃₂, R₃₃, and R₃₄ each independently represent an alkyl group or a cycloalkyl group, and R₃₃ and R₃₄ may be bonded to each other to form a ring.

In General Formula (3), the definitions of the respective groups in R₃₁ are the same as those of the respective groups in Xa₁ in General Formula (A1). In addition, the definitions of the respective groups in R₃₂, R₃₃, and R₃₄ in General Formula (3) are the same as those of the respective groups in Rx₁, Rx₂, and Rx₃ in General Formula (A1), respectively.

As the repeating unit represented by General Formula (3), an acid-decomposable tertiary alkyl (meth)acrylate ester-based repeating unit (R₃₁ represents a hydrogen atom or a methyl group) is preferable. Among those, the repeating unit in which R₃₂ to R₃₄ are each independently a linear or branched alkyl group is preferable, and the repeating unit in which R₃₂ to R₃₄ are each independently a linear alkyl group is more preferable. Further, the repeating unit in which two of R₃₂ to R₃₄ are bonded to form a ring is preferable, and the repeating unit in which R₃₂ to R₃₄ are bonded to form a monocyclic cycloalkyl group having 5 or 6 carbon atoms is more preferable.

Moreover, with regard to specific examples of the repeating unit (b), reference can be made to the specific examples of described in paragraphs 0227 to 0233 of JP2014-232309A, the contents of which are incorporated herein by reference.

Specific examples of the monomer that forms the repeating unit (b) are shown below, but specific examples of the monomer that forms the repeating unit (b) contained in the resin (A) are not limited to the following ones.

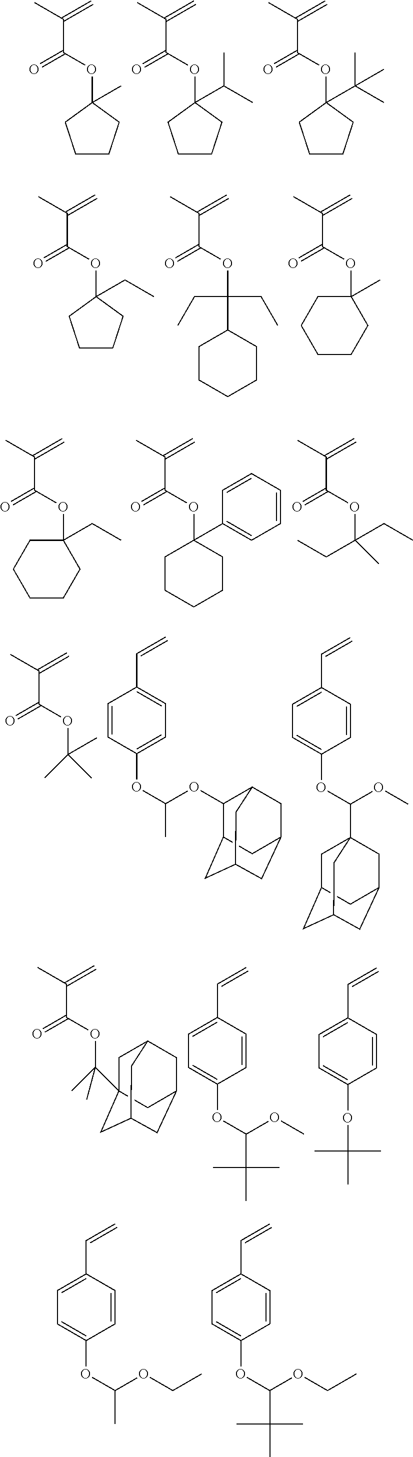

<Repeating Unit (c)>

The resin (A) preferably contains another repeating unit (c), in addition to the repeating unit (a) and the repeating unit (b). Such another repeating unit (c) is intended to mean a repeating unit which is different from the repeating unit (a) and the repeating unit (b).

The content of the repeating unit (c) in the resin (A) is not particularly limited and generally, it is preferably 1% to 50% by mole with respect to all the repeating units of the resin. The repeating units (c) may be used alone or in combination of two or more kinds thereof. In a case where two or more kinds of the repeating units (c) are used in combination, the total content thereof is preferably within the range.

As the repeating unit (c), a repeating unit containing a lactone structure is preferable. By incorporation of the repeating unit containing a lactone structure, the resist film has more excellent sensitivity.

The lactone group is not particularly limited as long as it contains a lactone structure, and is preferably a group having a 5- to 7-membered ring lactone structure, and more preferably a group in which another ring structure is fused to the 5- to 7-membered ring lactone structure in an aspect of forming a bicyclo structure or a spiro structure.

The repeating unit containing a lactone structure preferably contains at least one structure selected from the group consisting of General Formulae (LC1-1) to (LC1-17), and more preferably contains at least one structure selected from the group consisting of General Formula (LC1-1), General Formula (LC1-4), General Formula (LC1-5), General Formula (LC1-6), General Formula (LC1-13), and General Formula (LC1-14).

In addition, the group having a lactone structure may be directly bonded to the main chain.

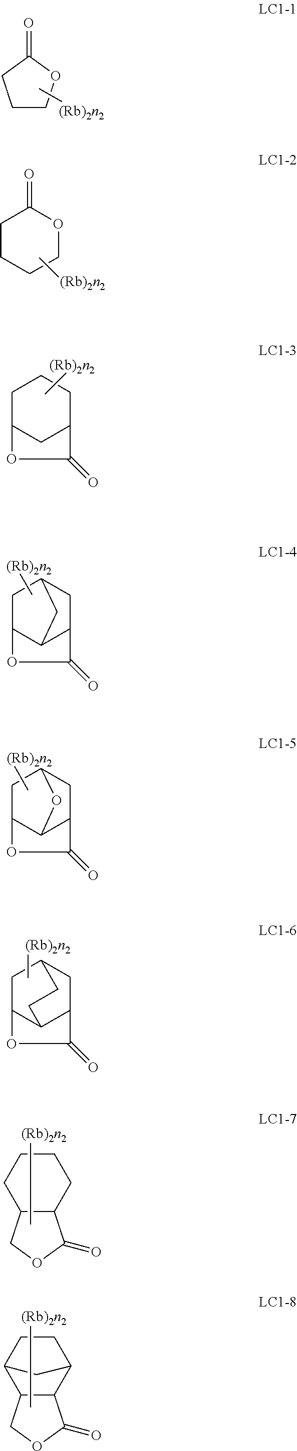

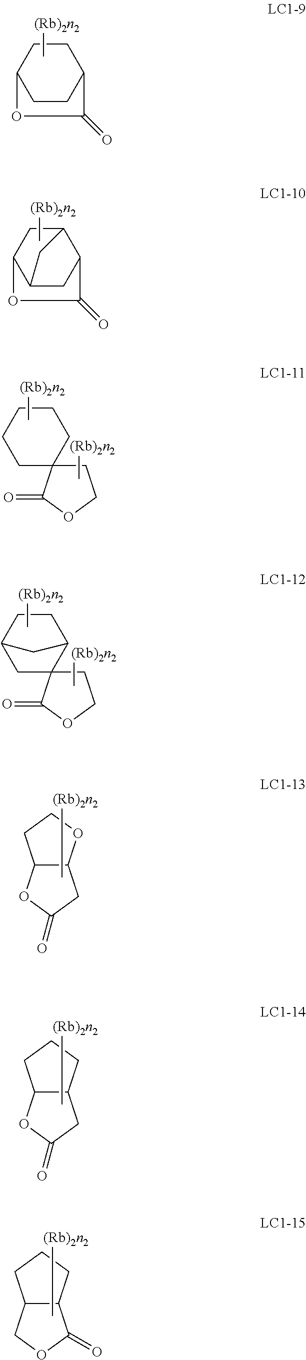

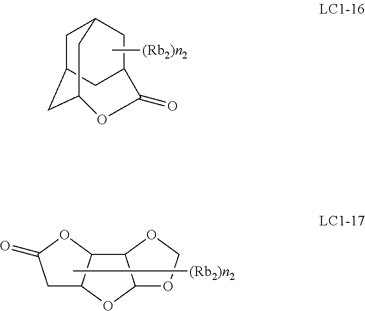

The lactone structure moiety may or may not contain a substituent (Rb₂). As the substituent (Rb₂), an alkyl group having 1 to 8 carbon atoms (a hydrogen atom in the alkyl group may be substituted with a fluorine atom), a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, an acid-decomposable group, or the like is preferable. n₂ represents an integer of 0 to 4. In a case where n₂ is 2 or more, Rb₂'s which are present in plural number may be the same as or different from each other and Rb₂'s which are present in plural number may be bonded to each other to form a ring.

Examples of the repeating unit that contains a group containing a lactone structure represented by any one of General Formula (LC1-1), . . . , or General Formula (LC1-17) include a repeating unit represented by General Formula (AII).

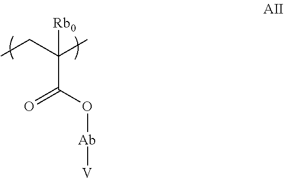

### In General Formula (AII),

Rb₀ represents a hydrogen atom, a halogen atom, or an alkyl group having 1 to 4 carbon atoms.

The alkyl group as Rb₀ may contain a substituent, and examples of the substituent include a hydroxyl group and a halogen atom. Examples of the halogen atom include a fluorine atom, a chlorine atom, a bromine atom, and an iodine atom. Among those, as Rb₀, a hydrogen atom or a methyl group is preferable.

Ab represents a single bond or a divalent linking group. Examples of the divalent linking group include an alkylene group, a divalent linking group containing a monocyclic or polycyclic alicyclic hydrocarbon structure, an ether bond, an ester bond, a carbonyl group, a carboxyl group, and a group formed by combination thereof.

Among those, a single bond or a group represented by -Ab₁-CO₂— is preferable. Ab₁ represents a linear or branched alkylene group, or a monocyclic or polycyclic cycloalkylene group, and is preferably a methylene group, an ethylene group, a cyclohexylene group, an adamantylene group, or a norbornylene group.

V is a group having a structure represented by any one of General Formula (LC1-1), . . . , or General Formula (LC1-17).

The repeating unit that contains a group containing a lactone structure usually has optical isomers, but any of the optical isomers may be used. Further, one kind of optical isomer may be used alone or a plurality of optical isomers may be mixed and used. In a case where one kind of optical isomer is mainly used, the optical purity (ee) thereof is preferably 90% or more, and more preferably 95% or more.

Specific examples of the repeating unit that contains a group containing a lactone structure are shown below, but the repeating unit that contains a group containing a lactone structure is not limited thereto. Further, Rx in the following formulae represents a hydrogen atom, a halogen atom, an alkyl group, a cycloalkyl group, a cyano group, or an alkoxycarbonyl group.

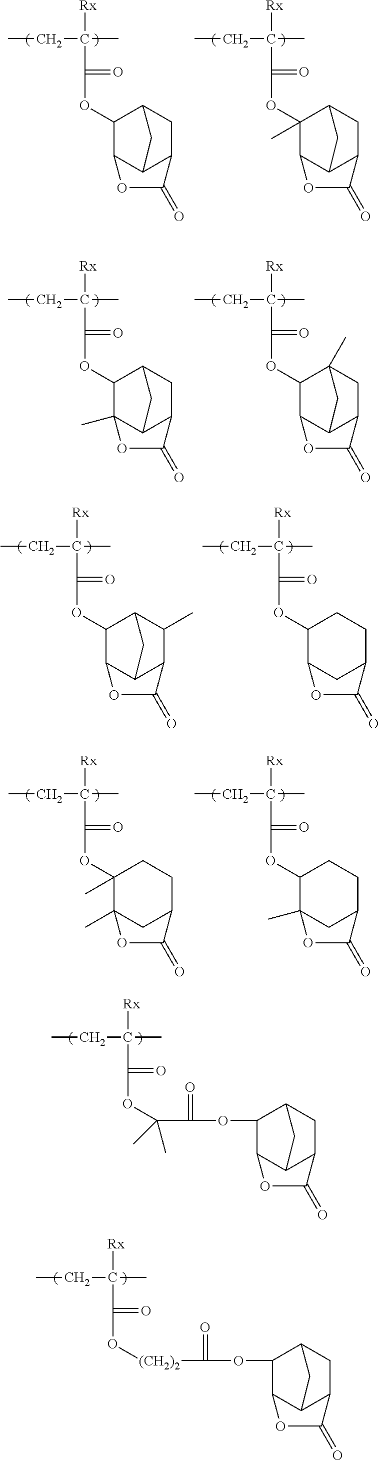

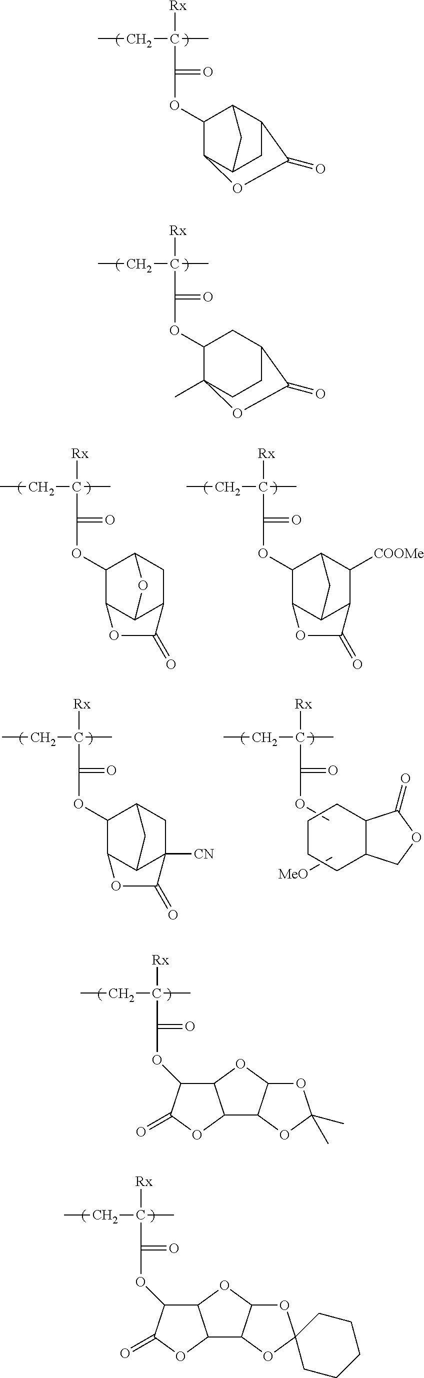

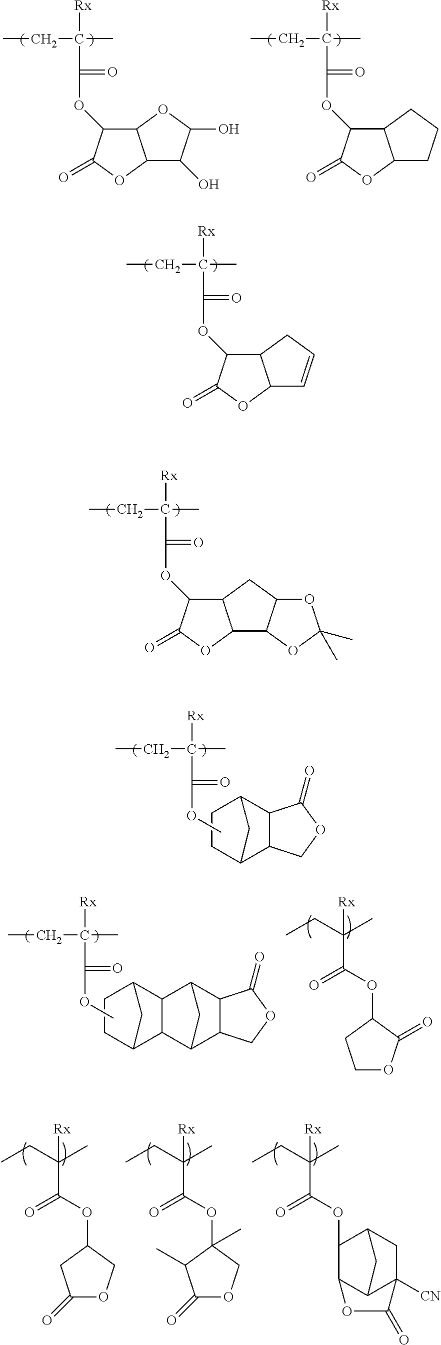

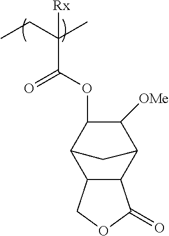

Examples of the repeating unit (c) include a repeating unit that contains an organic group containing a polar group, in addition to the above-mentioned repeating units, in particular, a repeating unit containing an alicyclic hydrocarbon structure substituted with a polar group. A resist film formed from a resist composition that contains a resin containing the repeating unit has more excellent adhesiveness to a substrate and more excellent affinity with a developer. As the alicyclic hydrocarbon structure substituted with a polar group, an adamantyl group, a diadamantyl group, or a norbornane group is preferable. As the polar group, a hydroxyl group or a cyano group is preferable.

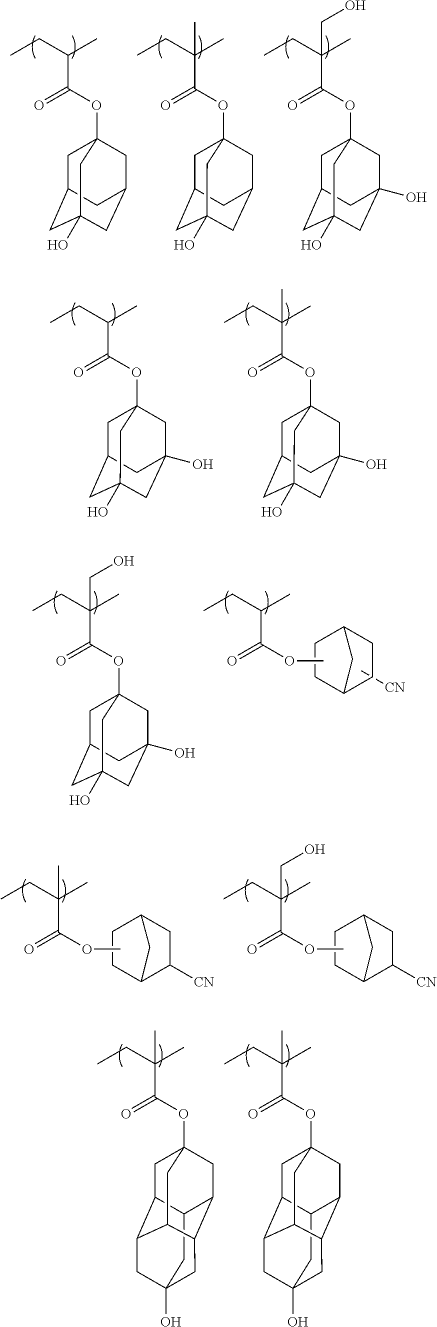

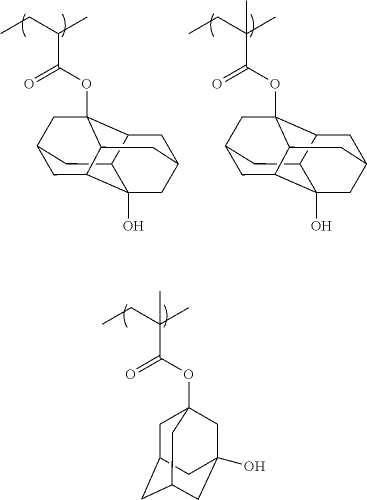

In a case where the resin (A) contains a repeating unit that contains an organic group containing a polar group, the content of the repeating unit is preferably 1% to 30% by mole, more preferably 5% to 25% by mole, and still more preferably 5% to 20% by mole, with respect to all the repeating units in the resin (A).

As the repeating unit (c), a repeating unit containing a group that generates an acid upon irradiation with actinic rays or radiation (photoacid-generating group) may be contained, in addition to the above-mentioned repeating units.

Examples of such a repeating unit include a repeating unit represented by General Formula (4).

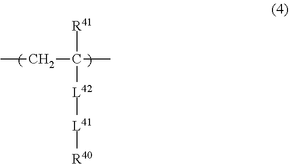

R⁴¹ represents a hydrogen atom or a methyl group. L⁴¹ represents a single bond or a divalent linking group. L⁴² represents a divalent linking group. R⁴⁰ represents a structural site that decomposes upon irradiation with actinic rays or radiation to generate an acid.

Examples of the repeating unit represented by General Formula (4) include the repeating units described in paragraphs 0094 to 0105 of JP2014-041327A, the contents of which are incorporated herein by reference.

In a case where the resin (A) contains a repeating unit having a photoacid-generating group, the content of the repeating unit having a photoacid-generating group is preferably 1% to 40% by mole, more preferably 5% to 35% by mole, and still more preferably 5% to 30% by mole, with respect to all the repeating units in the resin (A).

The weight-average molecular weight of the resin (A) as required as a value in terms of polystyrene by a gel permeation chromatography (GPC) method is preferably 1,000 to 200,000, more preferably 3,000 to 20,000, and still more preferably 5,000 to 15,000. In a case where the weight-average molecular weight of the resin (A) is 1,000 to 200,000, it is more difficult for the resist film to be deteriorated in heat resistance and/or dry etching resistance, and to be deteriorated in developing properties and/or film forming properties.

Moreover, in the present specification, the GPC method is intended to mean a measurement method at a flow rate of 1 mL/min, a sample concentration of 0.1% by mass, and an amount of a sample injected of 10 μL with TSK gel Multipore HXL-M (manufactured by Tosoh Corporation, 7.8 mmID×30.0 cm) as a column, a differential refractometer as a detector, and tetrahydrofuran (THF) as an eluent at a temperature of 40° C., using HLC-8120 (manufactured by Tosoh Corporation), or a method equivalent to the method.

Among those, the weight-average molecular weight of the resin (A) is particularly preferably 7,000 to 14,000. In a case where the weight-average molecular weight of the resin (A) is 7,000 to 14,000, it is easy to further suppress the generation of residues (hereinafter also referred to as “scum”) in the unexposed area upon development of the resist film formed from the resist composition containing the resin (A).

The dispersity (molecular weight distribution) of the resin (A) is not particularly limited and generally, it is preferably 1 to 5, more preferably 1 to 3, still more preferably 1.2 to 3.0, and particularly preferably 1.2 to 2.0. In a case where the molecular weight distribution is in the range of 1 to 5, the resist film has more excellent resolution.

[Method for Producing Resin: First Step]

Next, a first step in a method for producing the resin (A) will be described in detail. The first step is a step of obtaining a resin precursor containing the repeating unit represented by General Formula (2) and a repeating unit containing a group that decomposes by the action of an acid to generate a polar group.

<Resin Precursor>

The resin precursor is a polymer containing a repeating unit represented by General Formula (2) (hereinafter also referred to as a “repeating unit (a2)”) and the repeating unit containing a group that decomposes by the action of an acid to generate a polar group (the above-mentioned “repeating unit (b)”). The resin precursor may contain another repeating unit, in addition to than the repeating units, and such another repeating unit contained in the resin precursor is the same as one described above as the repeating unit (c) in the resin (A).

A method for producing the resin precursor is not particularly limited and a known production method can be used. Examples of the method for producing (synthesizing) the resin precursor include a radical polymerization method. Examples of the radical polymerization method include a bulk polymerization method in which polymerization is performed by dissolving monomer species, an initiator, and the like in a solvent and heating the solution, and a dropwise addition polymerization method in which a solution of monomer species and an initiator is added dropwise to a heating solvent for 1 to 10 hours, with the dropwise addition polymerization method being preferable.

The monomer species may be any monomer that will serve as the repeating unit (a2) and the repeating unit (b), which will be described later, after polymerization.

Examples of the reaction solvent include ethers such as tetrahydrofuran, 1,4-dioxane, and diisopropyl ether; ketones such as methyl ethyl ketone and methyl isobutyl ketone; esters such as ethyl acetate; amides such as dimethyl formamide and dimethyl acetamide; and propylene glycol monomethyl ether acetate, propylene glycol monomethyl ether, and cyclohexanone.

Among those, it is preferable to perform polymerization using a resist solvent which will be described later in view that the solid contents are hardly precipitated during storage of the resist composition.

It is preferable that the polymerization reaction is performed in an inert gas atmosphere such as nitrogen and/or argon. As the polymerization initiator, a commercially available radical initiator (an azo-based initiator, a peroxide, or the like) can be used. As the radical initiator, an azo-based initiator is preferable, and the azo-based initiator having an ester group, a cyano group, or a carboxyl group is more preferable. Specific examples of the polymerization initiator include azobisisobutyronitrile, azobisdimethylvaleronitrile, and dimethyl 2,2′-azobis(2-methyl propionate). The polymerization initiator is added or added in portionwise, as desired, and a resin precursor is recovered after the reaction is completed. The concentration of the reactant is preferably 5% to 50% by mass, and more preferably 10% to 30% by mass. The reaction temperature is not particularly limited and generally, it is preferably 10° C. to 150° C., more preferably 30° C. to 120° C., and still more preferably 60° C. to 100° C.

As a purification method, an ordinary method such as a liquid-liquid extraction method in which residual monomers and/or oligomer components are removed by water washing or by the use of a combination of appropriate solvents; a purification method in a solution state, such as ultrafiltration capable of extraction removal of only compounds of a specific molecular weight or less; a re-precipitation method in which a solution containing a resin precursor is added dropwise to a poor solvent to coagulate the resin precursor in the poor solvent and thus remove residual monomers and the like; and a purification method in a solid state, such as washing of a resin precursor slurry separated by filtration with a poor solvent can be used.

Examples of the monomer which will serve as the repeating unit (a2) after polymerization include a monomer represented by General Formula (6a).

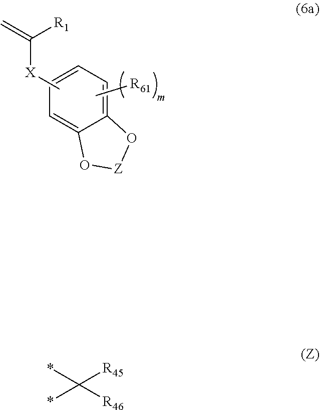

In General Formula (6a), R₆₁ represents a substituent, Z represents a group represented by General Formula (Z), and R₁, X, and m have the same definitions as R₁, X, and m in General Formula (1), respectively. In General Formula (Z), R₄₅ and R₄₆ each independently represent a hydrogen atom, an alkyl group, or an alkoxy group, provided that at least one selected from the group consisting of R₄₅ and R₄₆ is an alkyl group or an alkoxy group. Further, * represents a bonding position with an oxygen atom. In addition, suitable aspects of the respective groups will be described later as suitable aspects of the repeating unit (a2).

Moreover, examples of the monomer which will serve as the repeating unit (a2) after polymerization include a monomer represented by General Formula (7a).

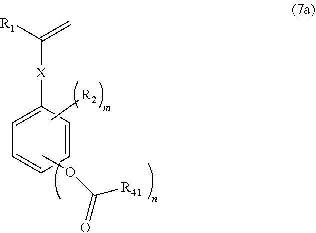

In General Formula (7a), R₄₁ represents an alkyl group, a cycloalkyl group, or an aryl group, and R₁, R₂, X, m, and n have the same definitions as R₁, R₂, X, m, and n in General Formula (1), respectively. In addition, suitable aspects of the respective groups will be described later as suitable aspects of the repeating unit (a2).

In a case where the monomer represented by General Formula (7a) is a monomer represented by General Formula (7b), it is preferably synthesized by a method including (1) a first step in which a compound represented by General Formula (8) and a malonic acid or malonic acid ester are heated in an organic solvent under a basic condition, (2) a second step in which a decarboxylation reaction is performed by heating at a temperature that is 20° C. or higher than the heating temperature in the first step, and (3) a third step in which an acylating agent is further added while not performing a post-treatment, thereby obtaining a monomer represented by General Formula (7b).

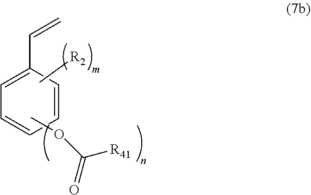

In General Formula (7b), R₄₁, R₂, m, and n have the same definitions as R₄₁, R₂, m, and n in General Formula (7a), respectively.

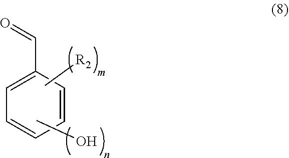

In General Formula (8), R₂, m, and n have the same definitions as R₂, m, and n in General Formula (7a), respectively.

The synthesis method is industrially highly excellent and preferable since a one-pot protected polyhydric hydroxystyrene monomer can be synthesized from inexpensive aldehyde raw materials.

As the organic solvent to be used in the first step in the method for synthesizing the monomer, an organic solvent having a boiling point of 100° C. or higher is preferable, and examples thereof include pyridine. As the base to be used, a secondary amine is preferable and examples thereof include piperidine. The base is preferably used in the amount of 0.1 to 1 equivalent with respect to the raw material aldehyde, and the reaction temperature is preferably 50° C. to 100° C.

In the second step in the method for synthesizing the monomer, heating is preferably performed at a temperature that is 20° C. or higher than that in the first step, and the reaction temperature is preferably 100° C. to 180° C. In a case where the second step is performed at the same temperature (for example, 50° C. to 90° C.) as in the first step, the decarboxylation reaction hardly proceeds and the yield is lowered. On the other hand, in a case where the first step is performed at the same temperature (for example, 100° C. to 140° C.) as in the second step, the decomposition of the raw material malonic acid competes, leading to a lowered yield.

Preferred examples of the acylating agent in the third step in the method for synthesizing the monomer include acetic anhydride and acetyl chloride.

In the method for synthesizing the monomer, it is preferable that a polymerization inhibitor such as 4-methoxyphenol and 2,6-di-tert-butyl-4-methylphenol is added to a reaction solution in the amount of 50 to 2,000 ppm with respect to the monomer.

Hereinafter, the respective repeating units contained in the resin precursor will be described.

(Repeating Unit (a2))

The repeating unit (a2) is the repeating unit represented by General Formula (2). The repeating unit (a2) contains a protective group Y The repeating unit represented by General Formula (2) is deprotected with an acid or a base in the second step which will be described later, and as a result, converted to the repeating unit (a) as described above.

The content of the repeating unit (a2) in the resin precursor is not particularly limited and generally, a lower limit value thereof is preferably 1% by mole or more, more preferably 15% by mole or more, and still more preferably 25% by mole or more, with respect to all the repeating units in the resin. Further, the upper limit value is not particularly limited, and is preferably 80% by mole or less, and more preferably 70% by mole or less. The repeating units (a2) may be used alone or in combination of two or more kinds thereof. In a case where two or more kinds of the repeating units (a2) are used in combination, the total content thereof is preferably within the range.

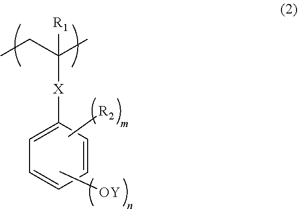

In General Formula (2), —OY is a group that is deprotected by the action of an acid or a base to generate a hydroxyl group, and Y represents a protective group (hereinafter also referred to as a “protective group Y”). Further, in a case where two —OY's are present in ortho positions with respect to each other, two Y's may be bonded to each other to form a ring. Further, R₁, R₂, X, m, and n have the same definitions as R₁, R₂, X, m, and n in General Formula (1), respectively.

In General Formula (2), Y is not particularly limited and a known protective group can be used.

With respect to the protective group, reference can be made to the descriptions in, for example, Green et al., Protective Groups in Organic Synthesis, 3rd Edition, 1999, John Wiley&Sons, Inc.

Examples of the protective group Y include —C(R₃₆)(R₃₇)(R₃₈), —C(R₃₆)(R₃₇)(OR₃₉), —C(R₀₁)(R₀₂)(OR₃₉), an acyl group, and a silyl group.

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

Specific examples of the protective group Y are shown below, but the protective group Y is not limited thereto. Further, in the formulae, * represents a bonding position with an oxygen atom (which is hereinafter the same in the present specification).

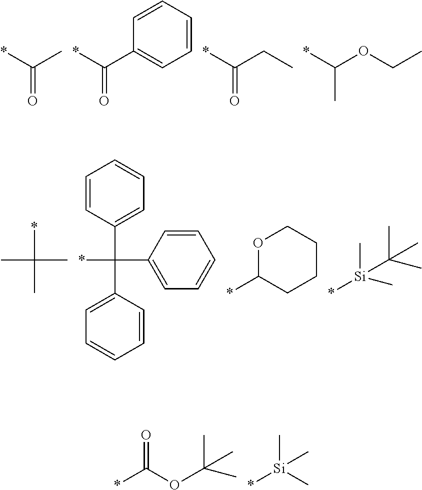

Furthermore, specific examples of the protective group Y in a case where the groups represented by —OY in the ortho positions with respect to each other form a ring are shown below, but the protective group Y is not limited thereto. Further, * represents a bonding position with an oxygen atom.

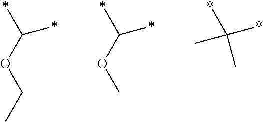

Among those, in a simpler manner, the protective group Y is preferably represented by General Formula (4) in view that the resin (A) can be produced.

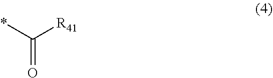

In General Formula (4), R₄₁ represents an alkyl group, a cycloalkyl group, or an aryl group. Further, * represents a bonding position with an oxygen atom.

Aspects of the alkyl group and the cycloalkyl group of R₄₁ are the same as those described above as the alkyl group and the cycloalkyl group of R₁ in General Formula (1).

The aryl group is not particularly limited and is preferably an aryl group having 6 to 12 carbon atoms.

In a case where the protective group Y is a group represented by General Formula (4), the group represented by —OY is more easily deprotected by the action of a base in the second step which will be described later, and therefore, it becomes easier that the group represented by —OY is protected more selectively deprotected with respect to the resin precursor that further contains the repeating unit (b) containing an acid-decomposable group.

Specific examples of the protective group Y represented by General Formula (4) are shown below, but the protective group Y is not limited thereto.

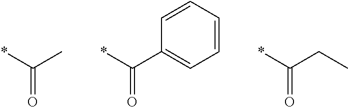

Furthermore, in view that the resin (A) can be more simply produced, it is also preferable that the protective group is represented by General Formula (5).

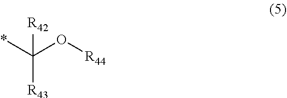

In General Formula (5), R₄₂ represents an alkyl group, and R₄₃ and R₄₄ each independently represent a hydrogen atom or an alkyl group. R₄₂ and R₄₄ may be bonded to each other to form a ring. Further, * represents a bonding position with an oxygen atom.

Aspects of the alkyl group of each of R₄₂, R₄₃, and R₄₄ are the same as those described above as the alkyl group of R₁ of General Formula (1).

Specific examples of the protective group Y represented by General Formula (5) are shown below, but the protective group Y is not limited thereto.

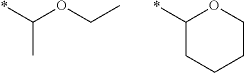

In a case where the protective group Y is a group represented by General Formula (5), the group represented by —OY is more easily deprotected by the action of a base in the second step which will be described later, and therefore, it becomes easier that the group represented by —OY is protected more selectively deprotected with respect to the resin precursor that further contains the repeating unit (b) containing an acid-decomposable group.

Furthermore, in view that the resin (A) can be more simply produced, it is also preferable that the repeating unit (a2) is a repeating unit represented by General Formula (6).

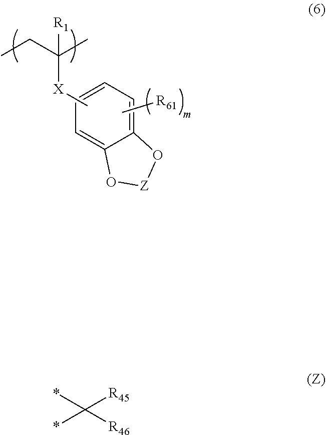

In General Formula (6), R₆₁ represents a substituent, Z represents a group represented by General Formula (Z), and R₁, X, and m have the same definitions as R₁, X, and m in General Formula (1), respectively. In General Formula (Z), R₄₅ and R₄₆ each independently represent a hydrogen atom, an alkyl group, or an alkoxy group, provided that at least one selected from the group consisting of R₄₅ and R₄₆ is an alkyl group or an alkoxy group. Further, * represents a bonding position with an oxygen atom.

The alkyl group and the alkoxy group as each of R₄₅ and R₄₆ are the same as those described above as the alkyl group and the alkoxy group of R₂ in General Formula (1), respectively.

Specific examples of the repeating unit (a2) represented by General Formula (6) are shown below, but the repeating unit (a2) is not limited thereto.

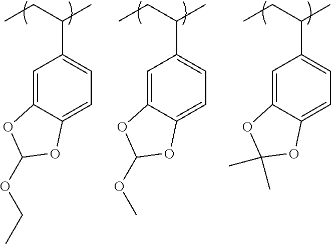

In a case where the repeating unit (a2) is a repeating unit represented by General Formula (6), the group represented by —OY is more easily deprotected by the action of a base in the second step which will be described later, and therefore, it becomes easier that the group represented by —OY is protected more selectively deprotected with respect to the resin precursor that further contains the repeating unit (b) containing an acid-decomposable group.

(Repeating Unit (b))

The resin precursor contains the repeating unit (b). The repeating unit (b) is the same as described above.

The content of the repeating unit (b) in the resin precursor is not particularly limited and generally, it is preferably 5% to 90% by mole, and more preferably 10% to 70% by mole, with respect to all the repeating units of the resin precursor. The repeating units (b) may be used alone or in combination of two or more kinds thereof. In a case where two or more kinds of the repeating units (b) are used in combination, the total content thereof is preferably within the range.

(Repeating Unit (c))

The resin precursor preferably contains the repeating unit (c). Aspects of the repeating unit (c) are the same as those described above as the repeating unit (c) contained in the resin (A).

The content of the repeating unit (c) in the resin precursor is not particularly limited and generally, it is preferably 1% to 60% by mole, and more preferably 1% to 50% by mole, with respect to all the repeating units of the resin precursor. The repeating units (c) may be used alone or in combination of two or more kinds thereof. In a case where two or more kinds of the repeating units (c) are used in combination, the total content thereof is preferably within the range.

[Method for Producing Resin: Second Step]

The second step is a step in which the group represented by —OY of the repeating unit (a2) represented by General Formula (2) of the resin precursor is deprotected with an acid or a base to obtain the repeating unit (a) represented by General Formula (1).

By the second step, it is possible to produce the resin (A) by selectively deprotecting the repeating unit (a2) with an acid or a base for conversion into a constitutional unit (a) containing a plurality of hydroxyl groups.

(Method for Deprotection)

A method for deprotection is not particularly limited and a known method can be used.

A method for deprotecting the group represented by —OY with an acid or a base is not particularly limited and can be selected from known methods, depending on the type of the protective group Y With regard to the method for deprotection, reference can be made to Protecting Groups, 3^{rd} Edition, and the like. In addition, with regard to a compound for which a pKa cannot be calculated by the method, a pKa value described in Handbook of Chemistry: Pure Chemistry, 5^{th} Edition (edited by The Chemical Society of Japan) is adopted.

Examples of an acid to be used for the deprotection reaction include sulfonic acid (sulfuric acid, methanesulfonic acid, p-toluenesulfonic acid, trifluoromethanesulfonic acid, and the like), halogenated hydrogen (fluorinated hydrogen, hydrogen chloride, hydrogen bromide, and hydrogen iodide), perfluorocarboxylic acid (trifluoroacetic acid, perfluorobutanecarboxylic acid, and the like), and nitric acid.

These acids may be used alone or in mixture.

The acid dissociation constant (pKa) of the acid to be used for the deprotection reaction is not particularly limited, and in view of obtaining a resist composition having a resist film having more excellent resolution, the acid dissociation constant (pKa) is preferably −1.0 or more, and more preferably 0.5 or more. The upper limit is preferably 3.0 or less, and more preferably 2.0 or less. Examples of the acid having an acid dissociation constant of −1.0 or more include, but are not limited to, 10-camphorsulfonic acid (1.2), p-toluenesulfonic acid (−0.43), and trifluoroacetic acid (0.53).

The deprotection reaction can also be performed by a base.

Examples of the base to be used for the deprotection reaction include triethylamine, ethyldiisopropylamine, N-methylmorpholine, pyridine, 4-dimethylaminopyridine, diisopropylethylamine, sodium carbonate, potassium carbonate, cesium carbonate, tert-butoxysodium, tert-butoxypotassium, sodium hydroxide, potassium hydroxide, potassium methoxide, diazabicycloundecene, and sodium methoxide.

The acid dissociation constant (pKa) of the conjugate acid of a base to be used for the deprotection reaction is not particularly limited, and in view of obtaining a resist composition having a resist film having more excellent resolution, the acid dissociation constant (pKa) is preferably 6.0 or more, and more preferably 9.0 or more. The upper limit is preferably 16.0 or less, and more preferably 14.0 or less. Examples of the base having an acid dissociation constant of the conjugate acid of 6.0 or more include, but are not limited to, triethylamine (10.6), 4-dimethylaminopyridine (9.5), morpholine (8.9), and diazabicycloundecene (13.3).

With regard to an amount of the acid or the base to be used for deprotection, the acid or the base is preferably used in the amount of 0.1 to 10 molar equivalents with respect to the protective group Y.

The temperature for the deprotection reaction is not particularly limited and generally, the deprotection reaction is preferably performed at 0° C. to 100° C. The period for the deprotection reaction is not particularly limited, but is preferably 20 hours or less. In addition, with regard to the condition for the deprotection, a known method can be used, and reference can be made to Protecting Groups 3^{rd} Edition.

<Suitable Aspect 1 of Second Step>

A suitable aspect of the second step may include a step in which the protective group Y is represented by General Formula (4) and the group represented by —OY contained in the repeating unit (a2) is deprotected with a base. By the method, a resist composition capable of forming a resist film having more excellent resolution is obtained.

Among those, in a case where the acid dissociation constant of the conjugate acid of the base is 6.0 or more, a resist composition capable of forming a resist film having more excellent resolution is obtained, and in a case where the acid dissociation constant of the conjugate acid of the base is 9.0 or more, a resist composition capable of forming a resist film having more excellent resolution is obtained.

<Suitable Aspect 2 of Second Step>

A suitable aspect of the second step may include a step in which the protective group Y is represented by General Formula (5) and the group represented by —OY is deprotected with an acid in the second step, or a step in which the repeating unit represented by General Formula (2) is represented by General Formula (6) and the group represented by —O—Z—O— is deprotected with an acid in the second step.

Among those, in a case where the acid dissociation constant of the acid is −1.0 or more, a resist composition capable of forming a resist film having more excellent resolution is obtained, and in a case where the acid dissociation constant is 1.0 or more, a resist composition capable of forming a resist film having still more excellent resolution is obtained.

[Method for Producing Actinic Ray-Sensitive or Radiation-Sensitive Composition]

A method for producing the actinic ray-sensitive or radiation-sensitive (resist) composition according to an embodiment of the present invention includes a step of mixing the resin (A) produced by the production method as described above and a compound (B) that generates an acid upon irradiation with actinic rays or radiation.

A method for mixing the resin (A) and the compound (B) that generates an acid upon irradiation with actinic rays or radiation is not particularly limited and a known method can be used. That is, a method in which the resin (A), the compound (B) that generates an acid upon irradiation with actinic rays or radiation, and optional components described later are mixed by a mixer or the like may be mentioned. Hereinafter, the respective components contained in the resist composition will be described.

[Resin (A)]

The resist composition contains the resin (A). Aspects of the resin (A) are the same as those described above as for the method for producing the resin (A).

The content of the resin (A) in the resist composition is not particularly limited and generally, it is preferably 50% to 99% by mass with respect to the total solid content of the resist composition. The resins (A) may be used alone or in combination of two or more kinds thereof. In a case where two or more kinds of the resins (A) are used in combination, the total content thereof is preferably within the range.

[Compound (B) that Generates Acid Upon Irradiation with Actinic Rays or Radiation]

The resist composition contains a compound (B) that generates an acid upon irradiation with actinic rays or radiation (hereinafter also referred to as a “photoacid generator” or “PAG” in the present specification, and PAG is an abbreviation of “Photo Acid Generator”).

The content of the photoacid generator in the resist composition is not particularly limited and generally, it is preferably 0.1% to 50% by mass, more preferably 5% to 50% by mass, and still more preferably 8% to 40% by mass, with respect to the total solid content of the resist composition. The photoacid generators may be used alone or in combination of two or more kinds thereof. In a case where two or more kinds of the photoacid generators are used in combination, the total content thereof is preferably within the range.

In addition, in a case where a resist film formed from the resist composition is exposed to electron beams and/or extreme ultraviolet rays, the content of the photoacid generator in the resist composition is preferably 10% to 40% by mass, and more preferably 10% to 35% by mass, with respect to the total solid content of the resist composition. In a case where the content of the photoacid generator is in the range and exposure is performed with electron beams and/or extreme ultraviolet rays, the resist film has more excellent sensitivity and resolution.

The photoacid generator is not particularly limited and a known photoacid generator can be used.

The photoacid generator may be in a form of a low-molecular-weight compound or a form incorporated into a part of a polymer. Further, a combination of the form of a low-molecular-weight compound and the form incorporated into a part of a polymer may also be used.

In a case where the photoacid generator is in the form of the low-molecular-weight compound, the molecular weight is preferably 3,000 or less, more preferably 2,000 or less, and still more preferably 1,000 or less.

Among those, as the photoacid generator, a low-molecular-weight compound is preferable.

The photoacid generator may contain a fluorine atom.

It is preferable that the number of fluorine atoms contained in the photoacid generator is appropriately adjusted. In a case where the number of fluorine atoms contained in the photoacid generator is adjusted, it is possible to control the uneven distribution on the surface of the photoacid generator in the resist film. As the number of fluorine atoms contained in the photoacid generator is larger, it is easier for the photoacid generator to be unevenly distributed on the surface of the resist film.

The photoacid generator is not particularly limited and is preferably a compound that generates an organic acid upon irradiation with actinic rays or radiation, and preferably electron beams or extreme ultraviolet rays.

The organic acid thus generated is not particularly limited and examples thereof include sulfonic acid, bis(alkylsulfonyl)imide, and tris(alkylsulfonyl)methide. As the photoacid generator, a compound that generates at least any one of the organic acids is preferable.

As the photoacid generator, a compound represented by General Formula (ZI), General Formula (ZII), or General Formula (ZIII) is preferable.

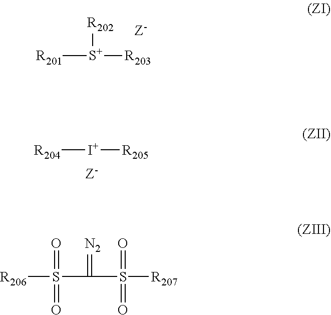

In General Formula (ZI), R₂₀₁, R₂₀₂, and R₂₀₃ each independently represent an organic group.

The number of carbon atoms of the organic group as R₂₀₁, R₂₀₂, and R₂₀₃ is not particularly limited and generally, it is preferably 1 to 30, and more preferably 1 to 20. Furthermore, two of R₂₀₁, R₂₀₂, and R₂₀₃ may be bonded to each other to form a ring structure, and an oxygen atom, a sulfur atom, an ester bond, an amide bond, or a carbonyl group may be contained in the ring structure. Examples of the group formed by the bonding of two of R₂₀₁, R₂₀₂, and R₂₀₃ include an alkylene group (for example, a butylene group and a pentylene group).

In General Formula (ZI), Z⁻ represents a non-nucleophilic anion (anion having an extremely low ability of causing a nucleophilic reaction).

The non-nucleophilic anion is not particularly limited and examples thereof include a sulfonate anion (an aliphatic sulfonate anion, an aromatic sulfonate anion, a camphor sulfonate anion, and the like); a carboxylate anion (an aliphatic carboxylate anion, an aromatic carboxylate anion, an aralkyl carboxylate anion, and the like); a sulfonylimide anion; a bis(alkylsulfonyl)imide anion; and a tris(alkylsulfonyl)methide anion.

The aliphatic moiety in the aliphatic sulfonate anion and the aliphatic carboxylate anion may be an alkyl group or a cycloalkyl group, and is preferably a linear or branched alkyl group having 1 to 30 carbon atoms, a cycloalkyl group having 3 to 30 carbon atoms, or the like.

As the aromatic group in the aromatic sulfonate anion and the aromatic carboxylate anion, an aryl group having 6 to 14 carbon atoms is preferable, and examples thereof include a phenyl group, a tolyl group, and a naphthyl group.

From the viewpoint of the acid strength, the pKa of the acid generated is preferably −1 or less so as to improve the sensitivity.

In addition, an anion represented by General Formula (AN1) may also be mentioned as a preferred aspect of the non-nucleophilic anion.

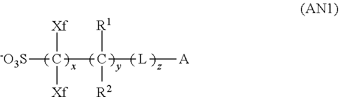

In Formula (AN1), Xf's each independently represent a fluorine atom or an alkyl group substituted with at least one fluorine atom.

R¹ and R² each independently represent a hydrogen atom, a fluorine atom, or an alkyl group, and in a case where R¹'s and R²'s are each present in plural number, they may be the same as or different from each other.

L represents a divalent linking group, and in a case where L's are present in plural number, they may be the same as or different from each other.

A represents a cyclic organic group. x represents an integer of 1 to 20, y represents an integer of 0 to 10, and z represents an integer of 0 to 10.

General Formula (AN1) will be described in more detail.

In an alkyl group substituted with a fluorine atom in Xf, the number of carbon atoms of the alkyl group is preferably 1 to 10, and more preferably 1 to 4. Further, as the alkyl group substituted with a fluorine atom of Xf, a perfluoroalkyl group is preferable.

As Xf, a fluorine atom or a perfluoroalkyl group having 1 to 4 carbon atoms is preferable. Examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, the fluorine atom or CF₃ is preferable. In particular, it is preferable that both Xf's are fluorine atoms.

The alkyl group of each of R¹ and R² may contain a substituent (preferably a fluorine atom), and the number of carbon atoms is preferably 1 to 4. Among those, a perfluoroalkyl group having 1 to 4 carbon atoms is more preferable. In a case where R¹ and R² are each an alkyl group containing a substituent, examples thereof include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

As R¹ and R², a fluorine atom or CF₃ is more preferable.

x is preferably 1 to 10, and more preferably 1 to 5.

y is preferably 0 to 4, and more preferably 0.

z is preferably 0 to 5, and more preferably 0 to 3.

The divalent linking group of L is not particularly limited and examples thereof include —COO—, —OCO—, —CO—, —O—, —S—, —SO—, —SO₂—, an alkylene group, a cycloalkylene group, an alkenylene group, and a linking group formed by combining a plurality thereof. A linking group having a total number of carbon atoms of 12 or less is preferable. Among these, —COO—, —OCO—, —CO—, or —O— is preferable, and —COO— or —OCO— is more preferable.

The cyclic organic group of A is not particularly limited as long as it has a cyclic structure, and examples thereof include an alicyclic group, an aryl group, and a heterocyclic group (including not only those having aromaticity but also those having no aromaticity).

The alicyclic group may be monocyclic or polycyclic and is preferably a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, and an adamantyl group, is preferable in view that the diffusibility of the photoacid generator in the resist film in a heating step after exposure can be suppressed and mask error enhancement factor (MEEF) is further improved.

Examples of the aryl group include a benzene ring, a naphthalene ring, a phenanthrene ring, and an anthracene ring.

Examples of the heterocyclic group include those derived from a furan ring, a thiophene ring, a benzofuran ring, a benzothiophene ring, a dibenzofuran ring, a dibenzothiophene ring, and a pyridine ring. Among these, heterocyclic groups derived from a furan ring, a thiophene ring and a pyridine ring are preferable.

Moreover, examples of the cyclic organic group include a lactone structure, and specific examples thereof include lactone structures represented by General Formulae (LC1-1) to (LC1-17).

The cyclic organic group may have a substituent, and examples of the substituent include an alkyl group (which may be in any one of linear, branched, and cyclic forms, and preferably has 1 to 12 carbon atoms), a cycloalkyl group (which may be in any one of monocyclic, polycyclic, and spirocyclic forms, and preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be a carbonyl carbon.

Examples of the organic group of each of R₂₀₁, R₂₀₂, and R₂₀₃ include an aryl group, an alkyl group, and a cycloalkyl group.

It is preferable that at least one of three members R₂₀₁, R₂₀₂, or R₂₀₃ is an aryl group, and it is more preferable that all of these three members are an aryl group. Examples of the aryl group include a heteroaryl group such as indole residue and pyrrole residue, in addition to a phenyl group, a naphthyl group, and the like. As the alkyl group and the cycloalkyl group of each of R₂₀₁, R₂₀₂, and R₂₀₃, a linear or branched alkyl group having 1 to 10 carbon atoms and a cycloalkyl group having 3 to 10 carbon atoms are preferable, respectively.

Examples of the alkyl group include a methyl group, an ethyl group, an n-propyl group, an i-propyl group, and an n-butyl group. Examples of the cycloalkyl group include a cyclopropyl group, a cyclobutyl group, a cyclopentyl group, a cyclohexyl group, and a cycloheptyl group. These groups may further have a substituent.

Examples of the substituent include, but are not limited to, a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Preferred examples of the anion represented by General Formula (AN1) include the following ones. In the following examples, A represents a cyclic organic group.

SO₃⁻—CF₂—CH₂—OCO-A, SO₃⁻—CF₂—CHF—CH₂—OCO-A, SO₃⁻—CF₂—COO-A, SO₃⁻—CF₂—CF₂—CH₂-A, SO₃⁻—CF₂—CH(CF₃)—OCO-A

In General Formula (ZII) and General Formula (ZIII), R₂₀₄ to R₂₀₇ each independently represent an aryl group, an alkyl group, or a cycloalkyl group.

The aryl group, the alkyl group, and the cycloalkyl group of R₂₀₄ to R₂₀₇ are each the same as the groups mentioned as the aryl group, the alkyl group, and the cycloalkyl group of R₂₀₁ to R₂₀₃ in the compound (ZI), respectively.

The aryl group, the alkyl group, and the cycloalkyl group of R₂₀₄ to R₂₀₇ may contain a substituent. Examples of the substituent include the substituents described as the substituents which may be included in the aryl group, the alkyl group, or the cycloalkyl group of R₂₀₁ to R₂₀₃ in the compound (ZI).

Z⁻ represents a non-nucleophilic anion and examples thereof include the same ones as the non-nucleophilic anions of Z⁻ in General Formula (ZI).

From the viewpoint of suppressing an acid generated by exposure from diffusing to an unexposed area and thus improving the resolution, the photoacid generator is preferably a compound that generates an acid in a size with a volume of 130 Å³ (10 Å=1 nm) or more (more preferably a sulfonic acid), more preferably a compound that generates an acid in a size with a volume of 190 Å³ or more (more preferably a sulfonic acid), still more preferably a compound that generates an acid in a size with a volume of 270 Å³ or more (more preferably sulfonic acid), and particularly preferably a compound that generates an acid in a size with a volume of 400 Å³ or more (more preferably sulfonic acid), upon irradiation with electron beams or extreme ultraviolet rays. However, from the viewpoint of the sensitivity or the solubility in the coating solvent, the volume is preferably 2,000 Å³ or less, and more preferably 1,500 Å³ or less.

In addition, the value of the volume was determined using “WinMOPAC” produced by Fujitsu Limited. That is, first, the chemical structure of the acid in each compound is input, next, using this structure as an initial structure, the most stable steric conformation of each acid is determined by molecular force field calculation according to an MM3 (MM is an abbreviation of Molecular Mechanics) method, and then, molecular orbital calculation using a PM3 (PM is an abbreviation of Parameterized Model) method is performed with respect to the most stable steric conformation, whereby the “accessible volume” of each acid can be calculated. The volume is intended to mean an “accessible volume”.

With regard to the photoacid generator, reference can be made to paragraphs 0368 to 0377 of JP2014-041328A, and paragraphs 0240 to 0262 of JP2013-228681A (paragraph 0339 of the corresponding US2015/004533A), the contents of which are incorporated herein. Further, preferred specific examples thereof include the following compounds, but are not limited thereto.

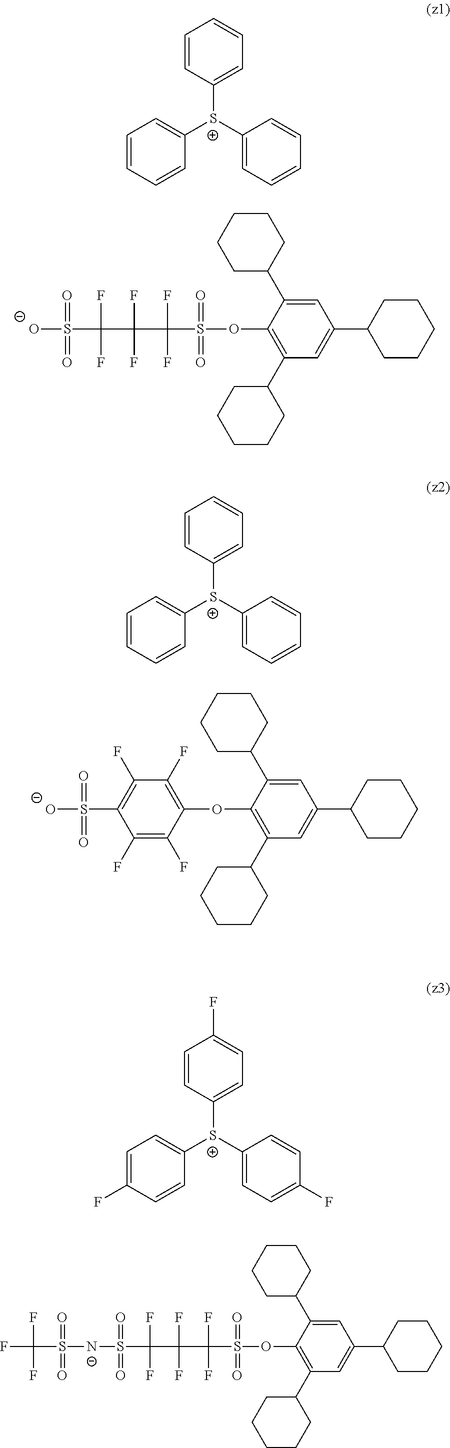 [SMILES: c1ccc([S+](c2ccccc2)c2ccccc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; Fc1ccc([S+](c2ccc(F)cc2)c2ccc(F)cc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

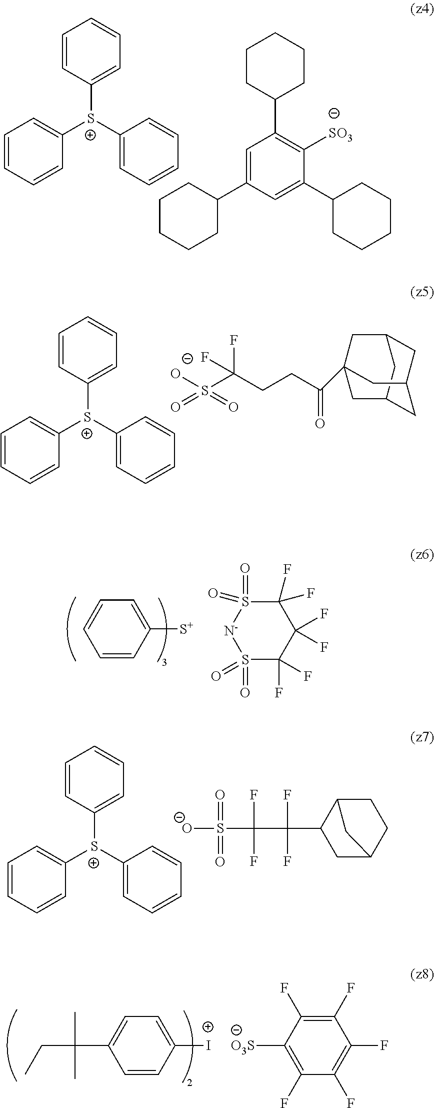

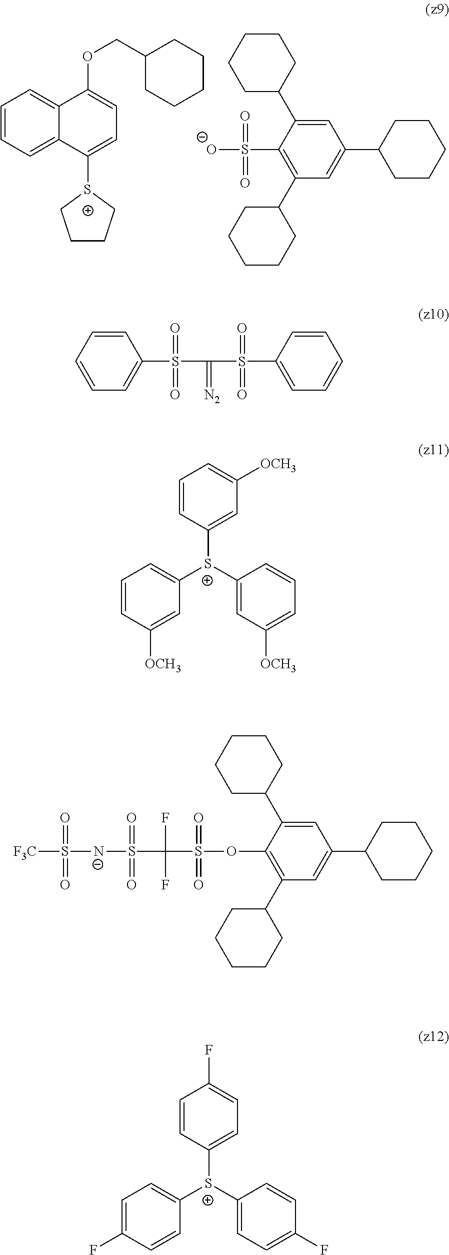

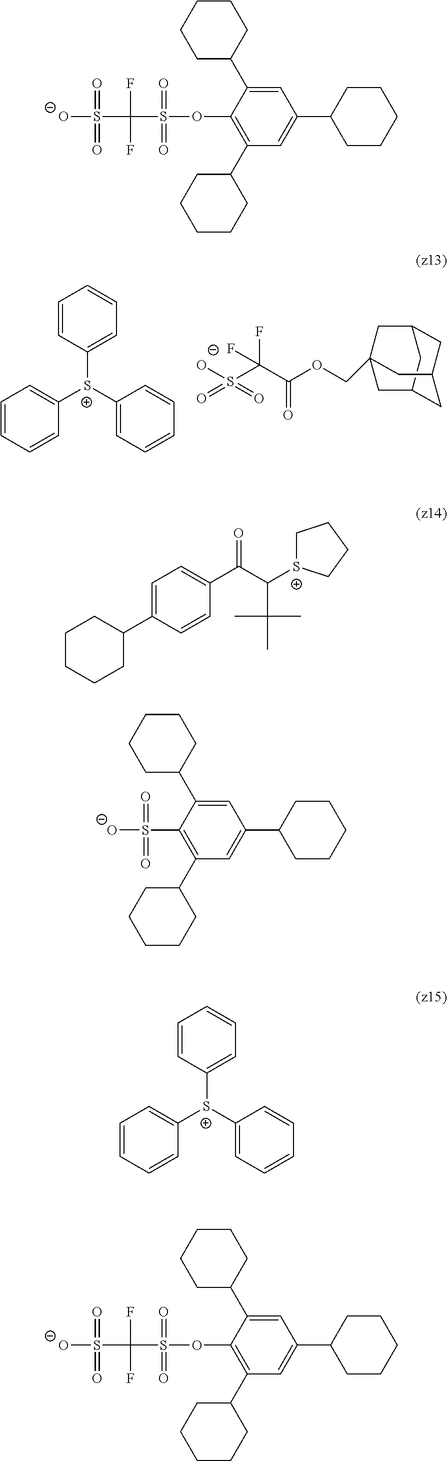

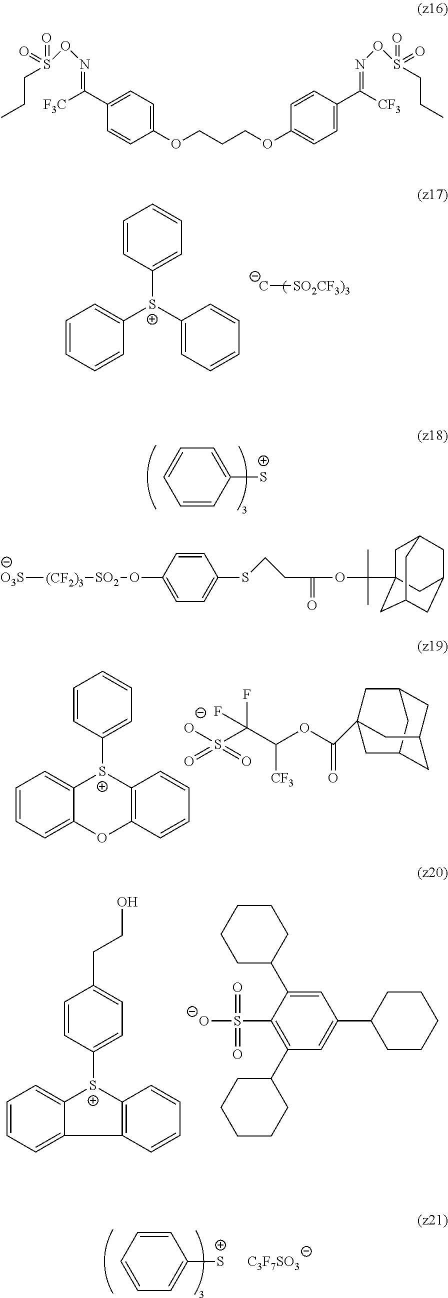

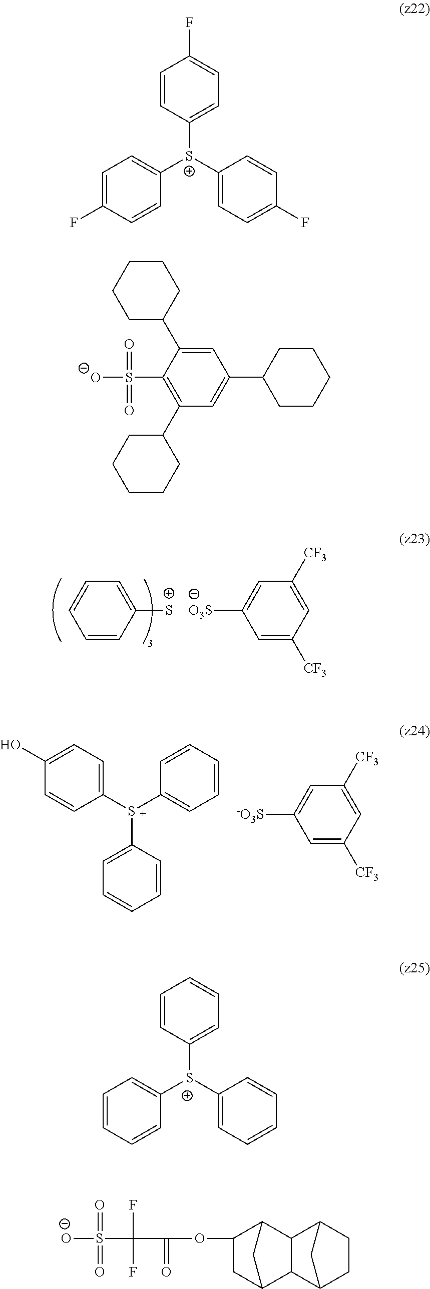

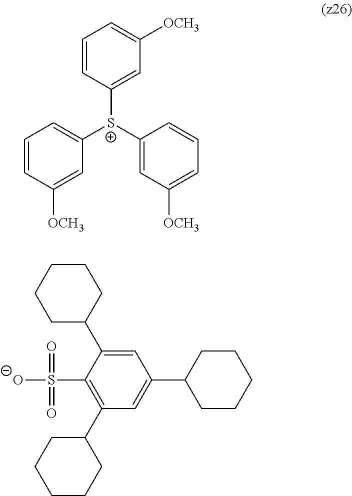 [SMILES: COc1cccc([S+](c2cccc(OC)c2)c2cccc(OC)c2)c1 ; O=S(=O)([O-])c1c(C2CCCCC2)cc(C2CCCCC2)cc1C1CCCCC1]

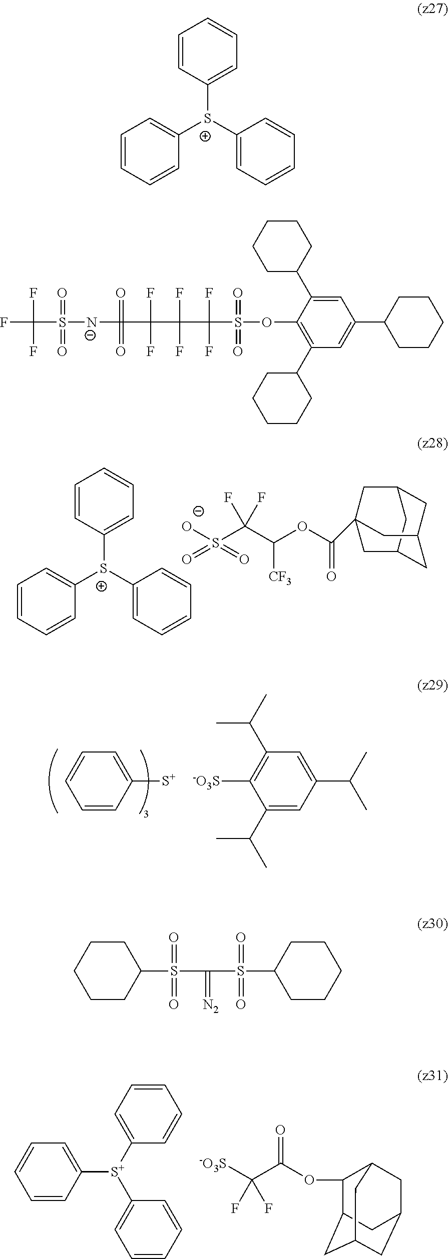

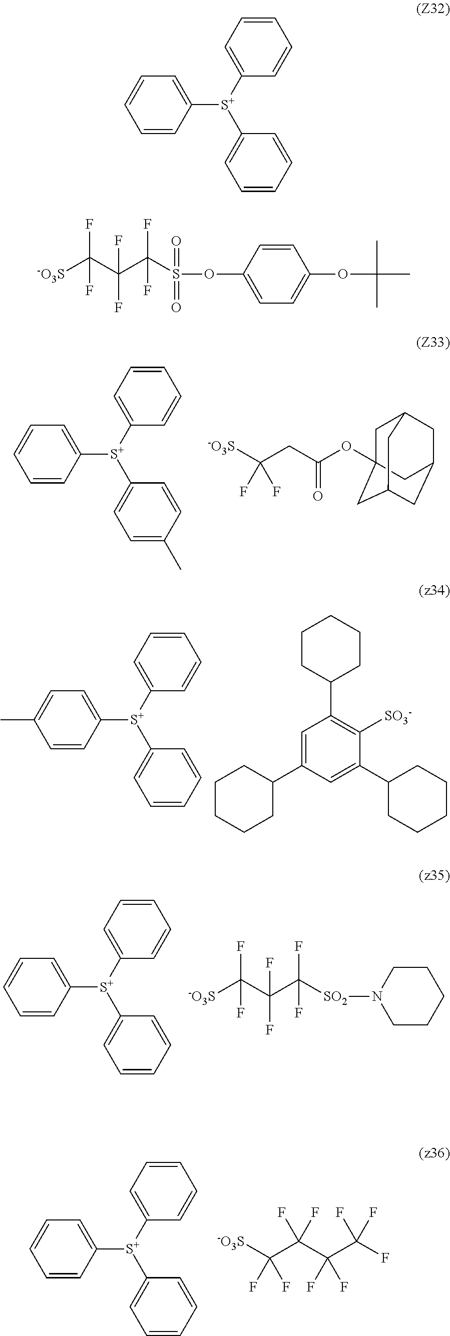

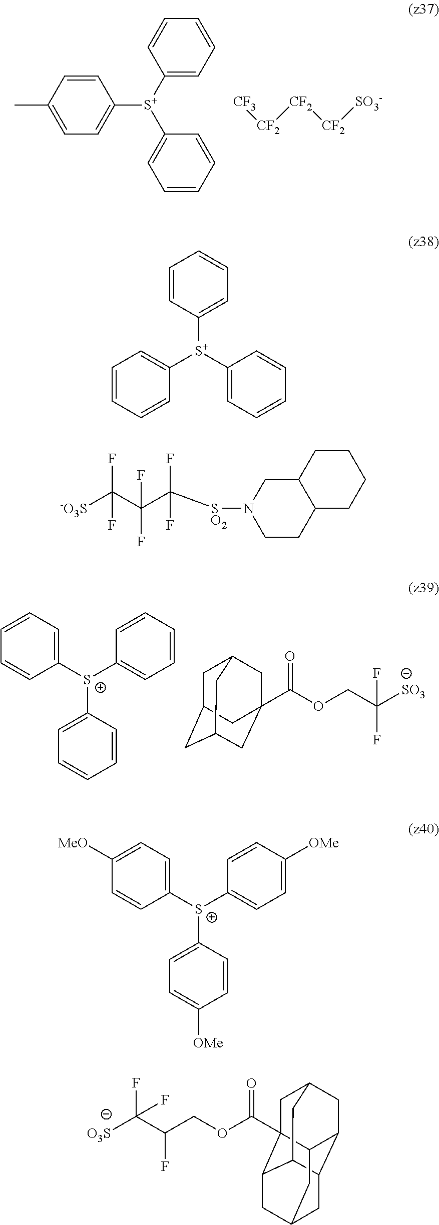

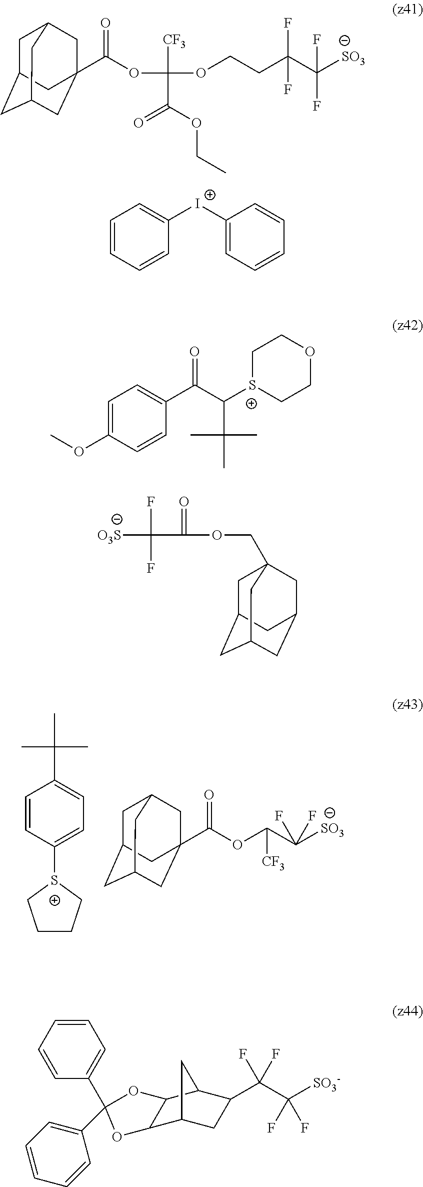

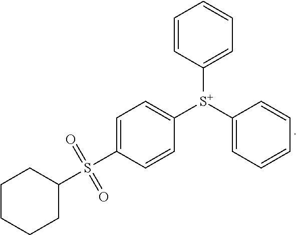 [SMILES: O=S(=O)(c1ccc([S+](c2ccccc2)c2ccccc2)cc1)C1CCCCC1]

[Optional Components]

It is preferable that the resist composition contains optional components, in addition to the resin (A) and the photoacid generator. Examples of the optional components include a solvent, a basic compound, a hydrophobic resin, a surfactant, and other additives. Hereinafter, each of the optional components will be described in detail.

<Solvent>

The resist composition preferably contains a solvent (hereinafter also referred to as the “resist solvent” in the present specification).

The content of the solvent in the resist composition is not particularly limited and generally, the solid content of the resist composition is preferably adjusted to 0.5% to 30% by mass, and more preferably adjusted to 1% to 20% by mass. In a case where the solid content of the resist composition is 0.5% to 30% by mass, the resist composition has more excellent coatability.

The solvents may be used alone or in combination of two or more kinds thereof. In a case where two or more kinds of the solvents are used in combination, the total content thereof is preferably within the range.

Furthermore, by adjusting the solid content of the resist composition, it is possible to adjust the thickness of the resist film which will be described later.

The solvent is not particularly limited and a known solvent can be used.

The solvent may contain an isomer (a compound having the same number of atoms and different structures). Incidentally, only one kind or a plurality of kinds of the isomers may be contained.

The resist composition preferably contains at least one of a component (M1): at least one selected from the group consisting of propylene glycol monoalkyl ether carboxylate or a component (M2): at least one selected from the group consisting of propylene glycol monoalkyl ether, lactic acid ester, acetic acid (or butyric acid) ester, alkoxypropionic acid ester, chained ketone, cyclic ketone, lactone, and alkylene carbonate as a solvent. The resist composition may further contain solvents other than the component (M1) and/or the component (M2).

As the component (M1), at least one selected from the group consisting of propylene glycol monomethyl ether acetate, propylene glycol monomethyl ether propionate, and propylene glycol monoethyl ether acetate is preferable, and propylene glycol monomethyl ether acetate is more preferable.

As the component (M2), the following ones are preferable.

As the propylene glycol monoalkyl ether, propylene glycol monomethyl ether or propylene glycol monoethyl ether is preferable.

As the lactic acid ester, preferably ethyl lactate, butyl lactate, or propyl lactate is preferable.

The acetic acid ester is preferably methyl acetate, ethyl acetate, butyl acetate, isobutyl acetate, propyl acetate, isoamyl acetate, methyl formate, ethyl formate, butyl formate, propyl formate, or 3-methoxybutyl acetate.

As the butyric acid ester, butyl butyrate is preferable.

As the alkoxypropionic acid ester, methyl 3-methoxypropionate (MMP) or ethyl 3-ethoxypropionate (EEP) is preferable.

As the chain ketone, 1-octanone, 2-octanone, 1-nonanone, 2-nonanone, acetone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As the cyclic ketone, methyl cyclohexanone, isophorone, or cyclohexanone is preferable.

As the lactone, γ-butyrolactone is preferable.

As the alkylene carbonate, propylene carbonate is preferable.

As the component (M2), propylene glycol monomethyl ether, ethyl lactate, ethyl 3-ethoxypropionate, methyl amyl ketone, cyclohexanone, butyl acetate, pentyl acetate, γ-butyrolactone, or propylene carbonate is more preferable.

In addition to the components, it is preferable to use an ester-based solvent having 7 or more carbon atoms (preferably 7 to 14 carbon atoms, more preferably 7 to 12 carbon atoms, and still more preferably 7 to 10 carbon atoms) and 2 or less heteroatoms.

Preferred examples of the ester-based solvent having 7 or more carbon atoms and 2 or less heteroatoms include amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and among these, isoamyl acetate is preferable.

As the component (M2), a component having a flash point (hereinafter also referred to as fp) of 37° C. or higher is preferably used. As such a component (M2), propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl 2-hydroxyisobutyrate (fp: 45° C.), γ-butyrolactone (fp: 101° C.), or propylene carbonate (fp: 132° C.) is preferable. Among these, propylene glycol monomethyl ether, ethyl lactate, pentyl acetate, or cyclohexanone is more preferable, and propylene glycol monomethyl ether or ethyl lactate is still more preferable. In addition, the “flash point” in the present specification is intended to mean the value described in a reagent catalog of Tokyo Chemical Industry Co., Ltd. or Sigma-Aldrich Co. LLC.

The solvent preferably contains the component (M1). It is more preferable that the solvent is formed of substantially only the component (M1) or is formed by a combined use of the component (M1) and other components (a mixed solvent). In a case where the solvent is the mixed solvent, the solvent still more preferably contains both the component (M1) and the component (M2).

The mass content ratio of the content of the component (M2) to the content of the component (M1) in the resist composition is preferably 0 to 85/15, more preferably 0 to 60/40, and still more preferably 0 to 40/60. Incidentally, a case where the mass content ratio is 0 indicates that the resist composition does not contain the component (M2). In a case where the mass content ratio is in the range of 0 to 85/15, the resist film has more excellent defect suppression performance.

Moreover, in a case where the resist composition includes the component (M1) and the component (M2), the mass content ratio of the content of the component (M2) to the content of the component (M1) in the resist composition is preferably 99/1 or more.

As described above, the resist composition may further contain a solvent other than the components (M1) and (M2) as the solvent. In this case, the content of the solvent other than the components (M1) and (M2) is preferably in the range of 5% to 30% by mass with respect to the total mass of the respective solvents.

<Basic Compound>

It is preferable that the resist composition contains a basic compound. In a case where the resist composition contains the basic compound, it is possible to further reduce a change in the performance of the resist film with aging after exposure of the resist film until heating.

The content of the basic compound in the resist composition is not particularly limited and generally, it is preferably 0.001% to 10% by mass, and more preferably 0.01% to 5% by mass, with respect to the total solid content of the resist composition. The basic compounds may be used alone or in combination of two or more kinds thereof. In a case where two or more kinds of the basic compounds are used in combination, the total content thereof is preferably within the range.

The basic compound is not particularly limited and a known basic compound can be used. Examples of the basic compound include compounds containing structures represented by Formulae (A) to (E).

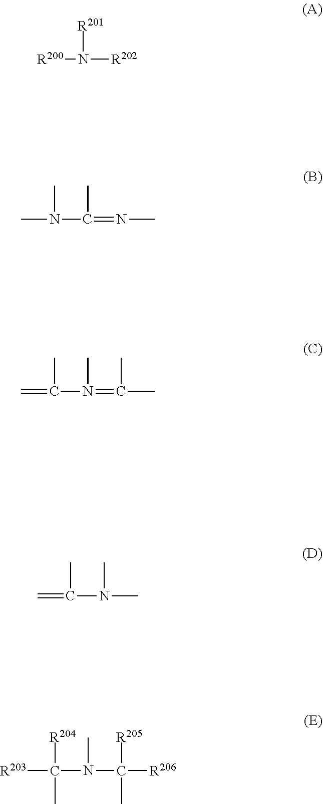

In General Formulae (A) and (E), R²⁰⁰, R²⁰¹, and R²⁰² may be the same as or different from each other, and each represent a hydrogen atom, an alkyl group (preferably having 1 to 20 carbon atoms), a cycloalkyl group (preferably having 3 to 20 carbon atoms), or an aryl group (preferably having 6 to 20 carbon atoms), in which R²⁰¹ and R²⁰² may be bonded to each other to form a ring.

With regard to the alkyl group, as the alkyl group containing a substituent, an aminoalkyl group having 1 to 20 carbon atoms, a hydroxyalkyl group having 1 to 20 carbon atoms, or a cyanoalkyl group having 1 to 20 carbon atoms is preferable.

R²⁰³, R²⁰⁴, R²⁰⁵, and R²⁰⁶ may be the same as or different from each other, and each represent an alkyl group having 1 to 20 carbon atoms.

The alkyl groups in General Formulae (A) and (E) are more preferably unsubstituted.

Examples of the basic compound include guanidine, aminopyrrolidine, pyrazole, pyrazoline, piperazine, aminomorpholine, aminoalkylmorpholine, and piperidine. Among these, a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; an aniline derivative having a hydroxyl group and/or an ether bond; or the like is preferable.

As the basic compound, an amine compound having a phenoxy group or an ammonium salt compound having a phenoxy group is preferable.

As the amine compound, a primary, secondary, or tertiary amine compound can be used, and an amine compound in which at least one alkyl group is bonded to a nitrogen atom is preferable. The amine compound is more preferably a tertiary amine compound. Any amine compound is available as long as at least one alkyl group (preferably having 1 to 20 carbon atoms) is bonded to a nitrogen atom, and a cycloalkyl group (preferably having 3 to 20 carbon atoms) or an aryl group (preferably having 6 to 12 carbon atoms) may be bonded to the nitrogen atom, in addition to the alkyl group.

Moreover, the amine compound preferably contains an oxygen atom in the alkyl chain to form an oxyalkylene group. The number of the oxyalkylene groups contained in the amine compounds is preferably 1 or more, more preferably 3 to 9, and still more preferably 4 to 6, within the molecule. Among those, as the oxyalkylene group, an oxyethylene group (—CH₂CH₂O—) or an oxypropylene group (—CH(CH₃)CH₂O— or —CH₂CH₂CH₂O—) is preferable, and an oxyethylene group is more preferable.

As the ammonium salt compound, a primary, secondary, tertiary, or quaternary ammonium salt compound can be used, and an ammonium salt compound in which at least one alkyl group is bonded to a nitrogen atom is preferable. Any ammonium salt compound is available as long as at least one alkyl group (preferably having 1 to 20 carbon atoms) is bonded to a nitrogen atom, and a cycloalkyl group (preferably having 3 to 20 carbon atoms) or an aryl group (preferably having 6 to 12 carbon atoms) may be bonded to the nitrogen atom, in addition to the alkyl group.

It is preferable that the ammonium salt compound contains an oxygen atom in the alkyl chain to form an oxyalkylene group. The number of the oxyalkylene groups contained in the ammonium salt compound is preferably 1 or more, more preferably 3 to 9, and still more preferably 4 to 6 within the molecule. Among those, as the oxyalkylene group, an oxyethylene group (—CH₂CH₂O—) or an oxypropylene group (—CH(CH₃)CH₂O— or —CH₂CH₂CH₂O—) is preferable, and the oxyethylene group is more preferable.

Examples of the anion of the ammonium salt compound include a halogen atom, a sulfonate, a borate, and a phosphate. Among those, the halogen atom or the sulfonate is preferable. As the halogen atom, a chloride, a bromide, or an iodide is preferable. As the sulfonate, an organic sulfonate having 1 to 20 carbon atoms is preferable.

The amine compound containing a phenoxy group can be obtained by heating a primary or secondary amine containing a phenoxy group with a haloalkyl ether to perform a reactant, then adding an aqueous solution of a strong base such as sodium hydroxide, potassium hydroxide, and tetraalkylammonium to the reactant to obtained a mixed liquid, and then adding an organic solvent such as ethyl acetate and chloroform to the mixed liquid to perform extraction.

As another method for preparing the amine compound containing a phenoxy group, a method in which a primary or secondary amine is heated and reacted with a haloalkyl ether having a phenoxy group at a terminal thereof to perform a reactant, then an aqueous solution of a strong base such as sodium hydroxide, potassium hydroxide, and tetraalkylammonium is added to the reactant to obtain a mixed liquid, and then an organic solvent such as ethyl acetate and chloroform is added to the mixed liquid can also be used.

With regard to specific examples of the basic compound, reference can be made to those described in paragraphs 0237 to 0294 of WO2015/178375A can be used, the contents of which are incorporated herein by reference.
Compound (PA) Which Has Proton-Accepting Functional Group and Generates Compound That Decomposes upon Irradiation with Actinic Rays or Radiation to Exhibit Deterioration in Proton-Accepting Properties, No Proton-Accepting Properties, or Change from Proton-Accepting Properties to Acidic Properties.

The resist composition may further contain a compound (hereinafter also referred to as a “compound (PA)” in the present specification) which has a proton-accepting functional group and generates a compound that decomposes upon irradiation with actinic rays or radiation to exhibit deterioration in proton-accepting properties, no proton-accepting properties, or a change from the proton-accepting properties to acidic properties as the basic compound.

The proton-accepting functional group is a functional group having a group or an electron which is capable of electrostatically interacting with a proton. Examples of the proton-accepting functional group include a functional group with a macrocyclic structure, such as a cyclic polyether, and a functional group containing a nitrogen atom containing an unshared electron pair not contributing to n-conjugation. The nitrogen atom containing an unshared electron pair not contributing to i-conjugation is intended to mean, for example, a nitrogen atom containing a partial structure represented by the following general formula.

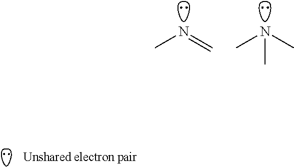

Preferred examples of the partial structure of the proton-accepting functional group include crown ether, azacrown ether, primary to tertiary amines, pyridine, imidazole, and pyrazine structures.

The compound (PA) generates a compound which decomposes upon irradiation with actinic rays or radiation to exhibit deterioration in proton-accepting properties, no proton-accepting properties, or a change from the proton-accepting properties to acidic properties. Here, an expression of generating a compound which exhibits deterioration in proton-accepting properties, no proton-accepting properties, or a change from the proton-accepting properties to acidic properties” means a change of proton-accepting properties due to the proton being added to the proton-accepting functional group, and specifically a decrease in the equilibrium constant at chemical equilibrium in a case where a proton adduct is generated from the compound (PA) having the proton-accepting functional group and the proton.

Examples of the compound (PA) include the following compounds. Incidentally, with regard to the compound (PA), reference can be made to those described in paragraphs 0421 to 0428 of JP2014-041328A or paragraphs 0108 to 0116 of JP2014-134686A can be used, the contents of which are incorporated herein by reference.

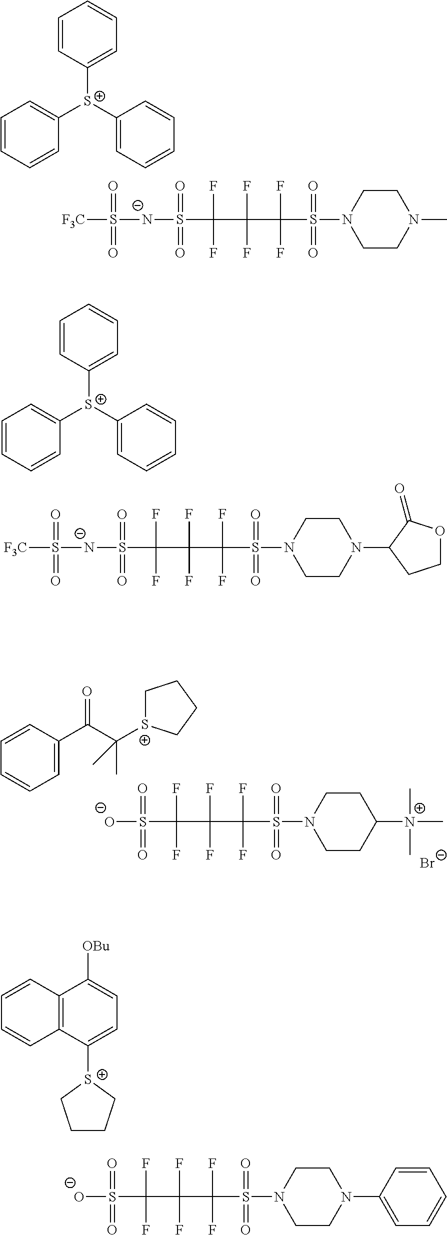

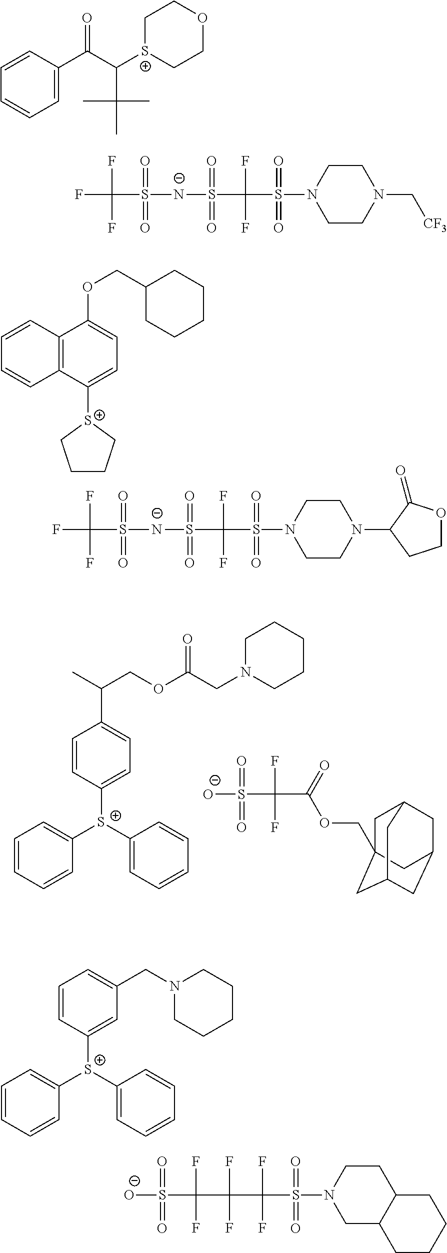

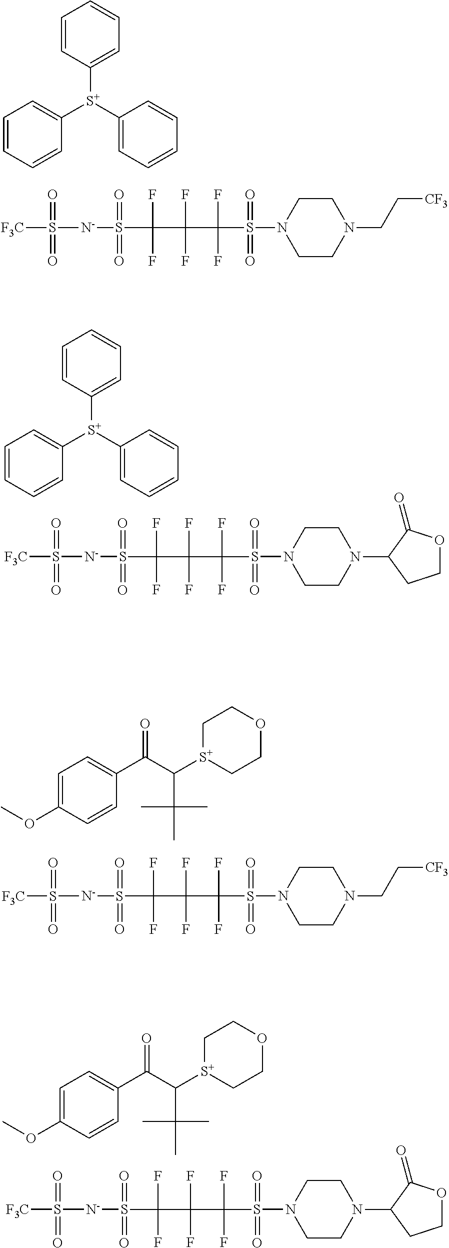

The molar content ratio of the content (molar amount) of the photoacid generator to the content (molar amount) of the basic compound in the resist composition is not particularly limited, and is preferably 2.5 to 300, more preferably 5.0 to 200, and still more preferably 7.0 to 150. In a case where the molar content ratio is 2.5 or more, the resist film has more excellent sensitivity and more excellent resolution, and in a case where the molar content ratio is 300 or less, it is possible to further suppress the thickening of the resist pattern with aging after exposure until the heating treatment, and as a result, the resist film has more excellent resolution.

As the basic compound, for example, the compounds (amine compounds, amido group-containing compounds, urea compounds, nitrogen-containing heterocyclic compounds, and the like) described in paragraphs 0140 to 0144 of JP2013-011833A, the contents of which are incorporated herein by reference, can be used.

<Hydrophobic Resin>

The resist composition preferably contains a hydrophobic resin. The hydrophobic resin is intended to mean a resin other than the resin (A) as described above.

The content of the hydrophobic resin in the resist composition is not particularly limited and generally, it is preferably 0.01% to 20% by mass, more preferably 0.01% to 10% by mass, still more preferably 0.05% to 8% by mass, and particularly preferably 0.5% to 5% by mass, with respect to the total solid content of the resist composition. The hydrophobic resins may be used alone or in combination of two or more kinds thereof. In a case where two or more kinds of the hydrophobic resins are used in combination, the total content thereof is preferably within the range.

The hydrophobic resin is not particularly limited and a known hydrophobic resin can be used.

Although the hydrophobic resin is preferably designed to be unevenly distributed on a surface of the resist film, it does not necessarily have to have a hydrophilic group in its molecule unlike the surfactant, and does not need to contribute to uniform mixing of polar/nonpolar materials.

By incorporating the hydrophobic resin into the resist composition, it is possible to more easily control the control of the static/dynamic contact angle of the surface of the resist film with respect to water, and further suppress generation of out gas.

The hydrophobic resin preferably contains at least one selected from the group consisting of a fluorine atom, a silicon atom, and a CH₃ partial structure contained in a side chain moiety of the resin in view of further uneven distribution on the surface layer of the resist film, and more preferably contains two or more of the group.

Furthermore, the hydrophobic resin preferably contains a hydrocarbon group having 5 or more carbon atoms. Those groups may be contained in the main chain or a side chain of the hydrophobic resin.

In a case where the hydrophobic resin contains a fluorine atom and/or a silicon atom, the fluorine atom and/or the silicon atom may be contained in the main chain or a side chain of the hydrophobic resin.

In a case where the hydrophobic resin contains a fluorine atom, an alkyl group containing a fluorine atom, a cycloalkyl group containing a fluorine atom, or an aryl group containing a fluorine atom is preferably contained as a partial structure having a fluorine atom.

The alkyl group containing a fluorine atom (preferably having 1 to 10 carbon atoms, and more preferably having 1 to 4 carbon atoms) is a linear or branched alkyl group in which at least one hydrogen atom is substituted with a fluorine atom, and may further contain a substituent other than the fluorine atom.

The cycloalkyl group containing a fluorine atom is a monocyclic or polycyclic cycloalkyl group in which at least one hydrogen atom is substituted with a fluorine atom, and may further contain a substituent other than a fluorine atom.

The aryl group containing a fluorine atom is an aryl group such as a phenyl group and a naphthyl group, in which at least one hydrogen atom is substituted with a fluorine atom, and may further contain a substituent other than a fluorine atom.

As the repeating unit containing a fluorine atom and/or a silicon atom, those described in paragraph 0519 of US2012/0251948A1, the contents of which are incorporated herein by reference, can also be used.

Moreover, the hydrophobic resin preferably contains a CH₃ partial structure in a side chain.

The CH₃ partial structure contained in the side chain in the hydrophobic resin encompasses a CH₃ partial structure contained in an ethyl group, a propyl group, and the like.

On the other hand, since a methyl group (for example, an α-methyl group in the repeating unit having a methacrylic acid structure) directly bonded to the main chain of the hydrophobic resin makes a small contribution to uneven distribution on the surface of the hydrophobic resin due to the effect of the main chain, it is not included in the CH₃ partial structure.

With regard to the hydrophobic resin, reference can be made to the descriptions in paragraphs 0348 to 0415 of JP2014-010245A, the contents of which are incorporated herein by reference.

In addition, as the hydrophobic resin, the resins described in JP2011-248019A, JP2010-175859A, and JP2012-032544A, the contents of which are incorporated herein by reference, can be used.

<Surfactant>

It is preferable that the resist composition contains a surfactant.

In a case for using an exposure light source at a wavelength of 250 nm or less, and particularly 220 nm or less of a resist film formed from the resist composition containing a surfactant, it is possible to form a resist pattern which has more excellent sensitivity, more excellent resolution, excellent adhesiveness, and less developing defects.

The content of the surfactant in the resist composition is not particularly limited and generally, it is preferably 0.0001% to 2% by mass, and more preferably 0.0005% to 1% by mass, with respect to the total solid content of the resist composition. The surfactants may be used alone or in combination of two or more kinds thereof. In a case where two or more kinds of the surfactants are used in combination, the total content thereof is preferably within the range.

The surfactant is not particularly limited and a known surfactant can be used.

As the surfactant, for example, the surfactants described in paragraph 0280 of US2008/0248425A, the contents of which are incorporated herein by reference, can also be used.

As the surfactant, fluorine- and/or silicon-based surfactants are preferable.

Examples of the fluorine- and/or silicon-based surfactants include the surfactants described in paragraph 0276 of US2008/0248425A, the contents of which are incorporated herein by reference.

Examples of a commercially available product of the surfactant include, but are not limited to, EFTOP EF301, EF303, and the like (manufactured by Shin-Akita Chemical Co., Ltd.); FLORAD FC430, 431, 4430, and the like (manufactured by Sumitomo 3M Inc.); MEGAFACE F171, F173, F176, F189, F113, F110, F177, F120, R08, and the like (manufactured by DIC Corp.); SURFLON S-382, SC101, 102, 103, 104, 105, 106, and the like (manufactured by Asahi Glass Co., Ltd.); TROYSOL S-366 (manufactured by Troy Chemical Corp.); GF-300, GF-150, and the like (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, EF601, and the like (manufactured by JEMCO Inc.); PF636, PF656, PF6320, PF6520, and the like (manufactured by OMNOVA Solutions Inc.); FTX-204G, 208G, 218G, 230G, 204D, 208D, 212D, 218D, 222D, and the like (manufactured by NEOS COMPANY LIMITED); and Polysiloxane Polymer KP-341 (manufactured by Shin-Etsu Chemical Co., Ltd.).

Furthermore, examples of the surfactant include a compound synthesized a fluoroaliphatic compound which is produced by a telomerization method (also referred to as a telomer method) or an oligomerization method (also referred to as an oligomer method). Specifically, a polymer containing a fluoroaliphatic group derived from a fluoroaliphatic compound which is produced by a telomerization method (also referred to as a telomer method) or an oligomerization method (also referred to as an oligomer method) may also be used as the surfactant. The fluoroaliphatic compound can be synthesized in accordance with the method described in JP2002-090991A.

(Other Additives)

The resist composition may further contain, in addition to the components, a dissolution inhibiting compound, a dye, a plasticizer, a photosensitizer, a light absorber, a compound promoting a solubility in a developer (for example, a phenol compound having a molecular weight of 1,000 or less or an alicyclic or aliphatic compound containing a carboxyl group), or the like.

The resist composition may further contain a dissolution inhibiting compound. Here, the “dissolution inhibiting compound” is intended to mean a compound having a molecular weight of 3,000 or less, whose solubility in an organic developer decreases by decomposition by the action of an acid.

[Pattern Forming Method]

Next, a pattern forming method using the resist composition will be described. The pattern forming method using the resist composition is not particularly limited and a known pattern forming method can be used. Hereinafter, suitable aspects of the pattern forming method using the resist composition will be described.

The suitable aspects of the pattern forming method using the resist composition include a pattern forming method including an actinic ray-sensitive or radiation-sensitive film (resist film) forming step in which an actinic ray-sensitive or radiation-sensitive film (resist film) containing an actinic ray-sensitive or radiation-sensitive composition (resist composition) is formed, an exposing step in which the actinic ray-sensitive or radiation-sensitive film is exposed, and a developing step in which the exposed actinic ray-sensitive or radiation-sensitive film is developed with a developer. Hereinafter, each of the steps will be described.

[Actinic Ray-Sensitive or Radiation-Sensitive Film Forming Step]

The actinic ray-sensitive or radiation-sensitive film forming step (hereinafter also referred to as a “resist film forming step”) is a step of forming a resist film using the resist composition. A method for forming a resist film using the resist composition is not particularly limited and known method can be used.

Examples of the method for forming a resist film using the resist composition include a method in which a resist film is formed on a substrate using the resist composition.

The method for forming a resist film using the resist composition on a substrate is not particularly limited and a known method can be used.

Examples of the method for forming a resist film using the resist composition on a substrate include a method in which a resist composition containing a solvent is applied onto a substrate to form a resist composition layer, and the resist composition layer is dried and/or heated, as desired, to form a resist film. The resist composition is preferably applied onto a substrate formed of known materials for use in the manufacture of an integrated circuit element by an application method such as use of a spinner.

The resist composition may be filtered over a filter before application.

A filter for use in filtering over a filter is not particularly limited and the pore size of the filter is preferably 0.1 μm or less, more preferably 0.05 μm or less, and still more preferably 0.03 μm or less.

A material of the filter is not particularly limited and is preferably, for example, polytetrafluoroethylene, polyethylene, or nylon.

Furthermore, various underlying films (inorganic films, organic films, or antireflection films) may be formed between the substrate and the resist film.

The drying method is not particularly limited and a method of performing drying by heating is preferable. Heating can be performed using a means comprised in an ordinary exposure or a development device, and may also be performed using a hot plate or the like. The heating temperature is preferably 80° C. to 150° C., more preferably 80° C. to 140° C., and still more preferably 80° C. to 130° C.

The heating time is preferably 30 to 1,000 seconds, more preferably 60 to 800 seconds, and still more preferably 60 to 600 seconds.

The thickness of the resist film is preferably 5 to 80 nm, more preferably 5 to 60 nm, and still more preferably 15 to 45 nm. In a case where the thickness of the resist film is in the range of 5 to 80 nm, the resist film has more excellent resist performance.

Here, the “thickness” is intended to mean the thickness of a resist film after drying a resist composition layer which has been formed by applying a resist composition onto a substrate. Accordingly, it is intended to mean the thickness of resist film measured before subjecting the resist film to additional treatments such as exposure.

<Upper Layer Film Forming Step>

Furthermore, the pattern forming method may contain an upper layer film forming step in which an upper layer film (topcoat) is further formed on the upper layer of the resist film.

A method for further forming an upper layer film on the upper layer of the resist film is not particularly limited and a known method can be used. Among those, a method in which a composition layer for forming an upper layer film is formed on a resist film using a composition for forming an upper layer film, and the composition layer for forming an upper layer film is dried, heated, and/or cured, as desired, to form an upper layer film is preferable.

Next, the composition for forming an upper layer film (composition for forming a topcoat) will be described.

The composition for forming an upper layer film is not particularly limited and a known composition for forming an upper layer film can be used. Further, as the composition for forming an upper layer film, a composition that can be uniformly applied onto the upper layer of a resist film while not mixing the resist film is preferable.

The thickness of the upper layer film is not particularly limited and is preferably 10 to 200 nm, more preferably 20 to 100 nm, and still more preferably 40 to 80 nm.

As a method for forming an upper layer film on the resist film, for example, the method described in paragraphs 0072 to 0082 of JP2014-059543A, the contents of which are incorporated herein by reference, can be used.

[Exposing Step]

The exposing step is a step of exposing the resist film. A method for exposing the resist film is not particularly limited and a known method can be used.

Examples of the method for exposing the resist film include a method in which the resist film is irradiated with actinic rays or radiation through a predetermined mask. Further, in a case of a method in which the resist film is irradiated with electron beams, a mask may not be used for the irradiation (direct lithography).

The actinic rays or radiation used for exposure is not particularly limited and examples thereof include KrF excimer laser, ArF excimer laser, extreme ultraviolet rays (EUV), and electron beams (EB), with the extreme ultraviolet rays or the electron beams being preferable. The exposure may be liquid immersion exposure.

<Post-Exposure Baking (PEB) Step>

It is preferable that the pattern forming method further includes a PEB step in which the exposed resist film is post-exposure baked before a developing step after the exposing step. By the baking, a reaction in the exposed areas is accelerated and thus, the sensitivity and/or the pattern shape is improved.

The heating temperature is preferably 80° C. to 150° C., more preferably 80° C. to 140° C., and still more preferably 80° C. to 130° C.

The heating time is preferably 30 to 1,000 seconds, more preferably 60 to 800 seconds, and still more preferably 60 to 600 seconds.

The heating can be performed by a means equipped in a normal exposure or development device, and may also be performed using a hot plate or the like.

[Developing Step]

The developing step is a step of developing the exposed resist film (hereinafter also referred to as “the resist film after exposure”) with a developer.

The developing method is not particularly limited and a known developing method can be used. Examples of the developing method include a dip method, a puddle method, a spray method, and a dynamic dispense method.

Furthermore, the pattern forming method may further include a step in which the developer is replaced by another solvent to stop the development after the developing step.

The development time is not particularly limited and generally, it is preferably 10 to 300 seconds, and more preferably 10 to 120 seconds. The temperature of the developer is preferably 0° C. to 50° C., and more preferably 15° C. to 35° C. The pattern forming method may only include at least one round of the developing step or a plurality of rounds of the developing step.

<Developer>

The developer is not particularly limited and a known developer can be used. Examples of the developer include an alkali developer or a developer containing an organic solvent (organic developer).

(Alkali Developer)

Examples of the alkali developer include, but are not limited to, an aqueous alkaline solution of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-n-butylamine; tertiary amines such as triethylamine and methyldiethylamine; alcohol amines such as dimethylethanolamine and triethanolamine; tetraalkylammonium hydroxides such as tetramethylammonium hydroxide, tetraethylammonium hydroxide, tetrapropylammonium hydroxide, tetrabutylammonium hydroxide, tetrapentylammonium hydroxide, tetrahexylammonium hydroxide, tetraoctylammonium hydroxide, ethyltrimethylammonium hydroxide, butyltrimethylammonium hydroxide, methyltriamylammonium hydroxide, and dibutyldipentylammonium hydroxide; quaternary ammonium salts such as dimethylbis(2-hydroxyethyl)ammonium hydroxide, trimethylphenylammonium hydroxide, trimethylbenzylammonium hydroxide, and triethylbenzylammonium hydroxide; cyclic amines such as pyrrole and piperidine; or the like.

Furthermore, the alkali developer may further contain alcohols, a surfactant, or the like.

The alkali concentration of the alkali developer is not particularly limited and generally, it is preferably 0.1% to 20% by mass. The pH of the alkali developer is not particularly limited and generally, it is preferably 10.0 to 15.0.

(Organic Developer)

Next, an organic solvent contained in the organic developer will be described.

A vapor pressure (in a case of a mixed solvent, the entire vapor pressure) of the organic solvent is not particularly limited, and is preferably 5 kPa or less, more preferably 3 kPa or less, and still more preferably 2 kPa or less at 20° C.

The organic solvent is not particularly limited and examples thereof include an ester-based solvent, a ketone-based solvent, an alcohol-based solvent, an amide-based solvent, an ether-based solvent, and a hydrocarbon-based solvent.

In a case where EUV or electron beams (EB) is used for the exposure, the number of carbon atoms of the organic solvent is preferably 7 or more, more preferably 7 to 14, still more preferably 7 to 12, and particularly preferably 7 to 10, in view of suppressing the swelling of the resist film. Further, the number of heteroatoms of the organic solvent is preferably 2 or less. The heteroatom is an atom other than a carbon atom and a hydrogen atom, and examples thereof include an oxygen atom, a nitrogen atom, and a sulfur atom. Among those, the ester-based solvent having the characteristics is preferable.

Examples of the ester-based solvent having 7 or more carbon atoms and having 2 or less heteroatoms include amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, with isoamyl acetate being preferable.

In a case where EUV or EB is used for the exposure, as the organic solvent contained in the organic developer, a mixed solvent of the ester-based solvent and the hydrocarbon-based solvent or a mixed solvent of the ketone-based solvent and the hydrocarbon-based solvent can also be used in place of the ester-based solvent having 7 or more carbon atoms and having 2 or less heteroatoms. Also in this case, it is effective in suppressing the swelling of the resist film.

In a case where an ester-based solvent and a hydrocarbon-based solvent are used in combination, it is preferable to use isoamyl acetate as the ester-based solvent. In addition, from the viewpoint of preparing the solubility of the resist film, a saturated hydrocarbon-based solvent (for example, octane, nonane, decane, dodecane, undecane, and hexadecane) is preferably used as the hydrocarbon-based solvent.

In a case where a ketone-based solvent and a hydrocarbon-based solvent are used in combination, it is preferable to use 2-heptanone as the ketone-based solvent. From the viewpoint of preparing the solubility of the resist film, a saturated hydrocarbon-based solvent (for example, octane, nonane, decane, dodecane, undecane, and hexadecane) is preferably used as the hydrocarbon-based solvent.

In a case where the mixed solvent is used, since the content of the hydrocarbon-based solvent depends on solvent solubility of the resist film, it is not particularly limited. Therefore, a necessary amount of the hydrocarbon-based solvent may be determined as appropriate.

The organic solvent may be used as a mixture of a plurality of solvents or may be used in admixture with a solvent other than those described above and/or with water. It is preferable that the moisture content in the developer is less than 10% by mass with respect to the total mass of the developer, and it is more preferred that the developer is substantially free of moisture. The content of the organic solvent (total concentration of organic solvents in a case of mixing a plurality of the organic solvents) in the developer is preferably 50% by mass or more, more preferably 50% to 100% by mass, still more preferably 85% to 100% by mass, particularly preferably 90% to 100% by mass, and most preferably 95% to 100% by mass, with respect to the total mass of the developer. Among those, the developer is preferably formed of substantially only an organic solvent. Further, the developer formed of substantially only an organic solvent may contain a surfactant, an antioxidant, a stabilizer, an anti-foaming agent, or the like.

It is preferable that the developer contains an antioxidant. The antioxidant is not particularly limited and examples thereof include an amine-based antioxidant and a phenol-based antioxidant.

The content of the antioxidant in the developer is not particularly limited and is preferably 0.0001% to 1% by mass, more preferably 0.0001% to 0.1% by mass, and still more preferably 0.0001% to 0.01% by mass, with respect to the total mass of the developer. In a case where the content of the antioxidant is 0.0001% by mass or more, a superior antioxidant effect is obtained, and in a case where the content of the antioxidant is 1% by mass or less, it is possible to further suppress the generation of development residues.

The developer may contain a basic compound. The basic compound is not particularly limited and examples thereof include a known basic compound. Specific examples of the basic compound are the same as those described above for the basic compound contained in the resist composition.

The developer may contain a surfactant. The developer containing a surfactant has more excellent wettability for the resist film and enables the development to proceed more effectively.

The surfactant is not particularly limited and a known surfactant can be used. Specific examples of the surfactant are the same as those described above for the surfactant contained in the resist composition.

The content of the surfactant in the developer is preferably 0.001% to 5% by mass, more preferably 0.005% to 2% by mass, and still more preferably 0.01% to 0.5% by mass, with respect to the total mass of the developer.

Furthermore, in the developing step, both of development using a developer containing an organic solvent and development with an alkali developer may be performed (so-called double development).

<Rinsing Step>

It is preferable that the pattern forming method further includes a rinsing step after the developing step.

The rinsing step is a step in which a wafer comprising the resist film after the development is washed using a rinsing liquid.

The washing method is not particularly limited and a known washed method can be used. Examples of the washing method include a rotation ejecting method, a dip method, and a spray method.

Among these, a method in which washing is performed by a rotation ejecting method, and the wafer is rotated at a rotation speed of 2,000 to 4,000 rpm after washing, thereby removing the rinsing liquid from the substrate, is preferable.

Generally, the rinsing time is preferably 10 to 300 seconds, more preferably 10 to 180 seconds, and still more preferably 20 to 120 seconds. The temperature of the rinsing liquid is preferably 0° C. to 50° C., and more preferably 15° C. to 35° C.

(Rinsing Liquid)

In a case where a wafer comprising the resist film is rinsed after the development using an alkali developer, the rinsing liquid is preferably pure water and may be pure water containing a surfactant.

In a case where a wafer comprising the resist film is rinsed after the development using an organic developer, the rinsing liquid is preferably a rinsing liquid containing an organic solvent. As the rinsing liquid containing an organic solvent, at least one organic solvent selected from the group consisting of a hydrocarbon-based solvent, a ketone-based solvent, an ester-based solvent, an alcohol-based solvent, an amide-based solvent, and an ether-based solvent is preferable, at least one organic solvent selected from the group consisting of the hydrocarbon-based solvent, the ether-based solvent, and the ketone-based solvent is more preferable, and at least one organic solvent selected from the group consisting of the hydrocarbon-based solvent and the ether-based solvent is still more preferable.

The rinsing liquid may contain an ether-based solvent. Examples of the ether-based solvent include glycol ether-based solvents containing a hydroxyl group; glycol ether-based solvents containing no hydroxyl group, such as dipropylene glycol dimethyl ether, dipropylene glycol diethyl ether, diethylene glycol dimethyl ether, and diethylene glycol diethyl ether; aromatic ether solvents such as anisole and phenetole; cyclic aliphatic ether-based solvents such as dioxane, tetrahydrofuran, tetrahydropyran, perfluoro-2-butyltetrahydrofuran, perfluorotetrahydrofuran, 1,4-dioxane, cyclopentylisopropyl ether, cyclopentyl sec-butyl ether, cyclopentyl tert-butyl ether, cyclohexylisopropyl ether, cyclohexyl sec-butyl ether, and cyclohexyl tert-butyl ether; acyclic aliphatic ether-based solvents having a linear alkyl group, such as di-n-propyl ether, di-n-butyl ether, di-n-pentyl ether, and di-n-hexyl ether; and acyclic aliphatic ether-based solvents containing a branched alkyl group, such as diisohexyl ether, methylisopentyl ether, ethylisopentyl ether, propylisopentyl ether, diisopentyl ether, methylisobutyl ether, ethylisobutyl ether, propylisobutyl ether, diisobutyl ether, diisopropyl ether, ethylisopropyl ether, and methylisopropyl ether. Among those, from the viewpoint of uniformity in the wafer plane, an acyclic aliphatic ether-based solvents having 8 to 12 carbon atoms is preferable, an acyclic aliphatic ether-based solvent having a branched alkyl group having 8 to 12 carbon atoms is more preferable, and diisobutyl ether, diisopentyl ether, or diisohexyl ether is still more preferable.

In addition, other specific examples of the organic solvent contained in the rinsing liquid are the same as those described as the organic solvent contained in the developer.

The vapor pressure of the rinsing liquid is not particularly limited and is preferably 0.05 kPa or more, more preferably 5.0 kPa or less, and still more preferably 0.1 to 5.0 kPa, and particularly preferably 0.12 to 3 kPa at 20° C. In a case where the rinsing liquid contains a plurality of solvents, it is preferable that the entire vapor pressure is in the range. In a case where the vapor pressure of the rinsing liquid is 0.05 to 5.0 kPa, the temperature uniformity in a wafer plane comprising the resist film is improved, and the dimensional uniformity in the wafer plane comprising the resist film is enhanced by suppression of the swelling due to the permeation of the rinsing liquid.

The organic solvents contained in the rinsing liquid may be used alone or in combination of two or more kinds thereof. In a case where two or more kinds of the organic solvents are used in combination, the total content thereof is preferably within the range. In a case where a combination of the organic solvents is used, examples of the rinsing liquid include a rinsing liquid containing undecane and diisobutyl ketone.

The rinsing liquid may contain a surfactant. The rinsing liquid containing the surfactant has more excellent wettability for the resist film and thus, generation of foreign matters on the resist film and/or the wafer after rinsing is suppressed.

The surfactant is not particularly limited and a known surfactant can be used. Specific examples of the surfactant are the same as those described above for the surfactant contained in the resist composition.

The content of the surfactant in the rinsing liquid is not particularly limited and is preferably 0.001% to 5% by mass, more preferably 0.005% to 2% by mass, and still more preferably 0.01% to 0.5% by mass, with respect to the total mass of the rinsing liquid.

The rinsing liquid may contain an antioxidant. The antioxidant is not particularly limited and a known antioxidant can be used. Specific examples of the antioxidant are the same as those described above for the antioxidant contained in the developer.

The content of the antioxidant in the rinsing liquid is not particularly limited and is preferably 0.0001% to 1% by mass, more preferably 0.0001% to 0.1% by mass, and still more preferably 0.0001% to 0.01% by mass, with respect to the total mass of the rinsing liquid.

In a case where a developer containing an organic solvent is used in the developing step, the rinsing step may be included after the developing step. The pattern forming method may include the rinsing step after the developing step, and from the viewpoint of a throughput (productivity), the rinsing step may not be included.

With regard to the pattern forming method not including a rinsing step, reference can be made to, for example, the descriptions in paragraphs 0014 to 0086 of JP2015-216403A, the contents of which are incorporated herein by reference.

Moreover, as the rinsing liquid, methyl isobutyl carbinol (MIBC) or the same liquid (particularly butyl acetate) as the developer is also preferable.

<Other Steps>

The pattern forming method may further include other steps, in addition to the steps as described above. Examples of such other steps include a washing step with a supercritical fluid and a heating step.

(Removing Step with Supercritical Fluid)

A removing step with a supercritical fluid is a step of removing the developer and/or the rinsing liquid adhering to the pattern with a supercritical fluid after the developing treatment and/or the rinsing treatment.

(Heating Step)

A heating step is a step of heating the resist film so as to remove the solvent remaining in the pattern after the developing step, the rinsing step, or the removing step with a supercritical fluid.

The heating temperature is not particularly limited and generally, it is preferably 40° C. to 160° C., more preferably 50° C. to 150° C., and still more preferably 50° C. to 110° C.

The heating time is not particularly limited but generally, it is preferably 15 to 300 seconds, and more preferably 15 to 180 seconds.

By using a pattern obtained by the pattern forming method as a mask and appropriately performing an etching treatment, ion injection, or the like, a semiconductor fine circuit, a mold structure for imprints, a photomask, or the like can be produced.

The pattern formed by the method can also be used for a guide pattern formation in a directed self-assembly (DSA) (see, for example, ACS Nano Vol. 4 No. 8 Pages 4815-4823). In addition, a pattern formed by the method can be used as, for example, a core material (core) of the spacer process disclosed in JP1991-270227A (JP-H03-270227A) and JP2013-164509A.

In addition, a process of a case where a mold for imprints is manufactured using the pattern forming method of the embodiment of the present invention is described in, for example, JP4109085B, JP2008-162101A, and “Fundamentals of Nanoimprint and Technical Development/Application Deployment-Substrate Technique of Nanoimprint and Latest Application Deployment”, edited by Yoshihiko Hirai (Frontier Publishing).

A photomask produced using the pattern forming method of the embodiment of the present invention may be a light transmissive type mask used in ArF excimer laser or the like, or may be a light reflective type mask used in reflection system lithography using EUV as a light source.

In addition, the pattern forming method and/or a pattern formed by the pattern forming method can be used for the manufacture of an electronic device.

Examples of an electronic device manufactured by the method for manufacturing an electronic device of the embodiment of the present invention include electric or electronic equipment (home appliances, office appliance (OA)-related or media-related equipment, optical equipment, telecommunication equipment, and the like).

### EXAMPLES

Hereinbelow, the present invention will be described in more detail with reference to Examples. The materials, the amounts of the materials used, the proportions, the treatment details, the treatment procedure, and the like shown in Examples below may be modified, as appropriate, as long as the modifications do not depart from the spirit of the present invention. Therefore, the scope of the present invention should not be construed as being limited to Examples shown below.

<Synthesis 1 of Monomer (1)>

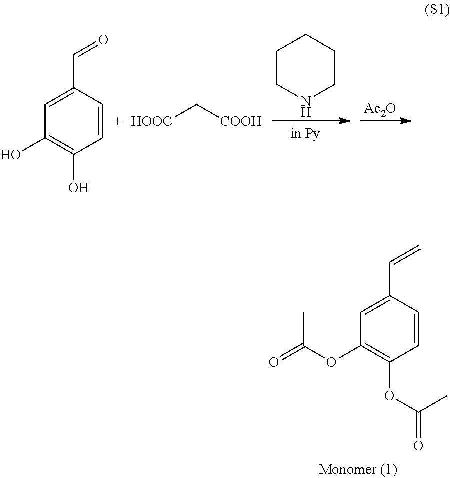 [SMILES: "Ac2O" ; O=Cc1ccc(O)c(O)c1 ; O=C(O)CC(=O)O ; C1CCNCC1 ; C=Cc1ccc(OC(C)=O)c(OC(C)=O)c1]

50.0 g of 3,4-dihydroxybenzaldehyde, 5.6 g of piperidine, and 283 g of pyridine were mixed, and 37.7 g of malonic acid was added thereto to obtain a mixed liquid. This mixed liquid was heated to a liquid temperature of 95° C. and stirred for 1.5 hours. 37.7 g of malonic acid was further added to the stirred mixed liquid, and the mixture was stirred for 1.5 hours under heating while the liquid temperature was kept at 95° C. Thereafter, 37.7 g of malonic acid was further added thereto and the mixture was stirred for 3 hours to obtain a reaction liquid. After confirming that 3,4-dihydroxybenzaldehyde as a raw material in the reaction liquid was consumed, the reaction liquid was warmed to 120° C. The reaction liquid was stirred for 2 hours while the liquid temperature was kept, and then the stirred reaction liquid was cooled to 5° C. or lower in an ice bath. 110.9 g of acetic anhydride was added dropwise to the cooled reaction liquid with carefulness not to cause extreme heat generation and the mixture was stirred at room temperature for 2 hours. After completing the reaction, 600 mL of ethyl acetate and 600 mL of a saturated aqueous ammonium chloride solution were added to the reaction liquid to perform a liquid separation operation and the organic layer was recovered. Next, the organic layer was twice washed with a saturated aqueous ammonium chloride solution and then three times washed with water. After dehydration over magnesium sulfate, the magnesium sulfate was filtered and separated, a filtrate thus obtained was concentrated under reduced pressure, and the residual solvent was distilled off to obtain a residue. The residue was distilled and purified (2.5 Torr, a boiling point of 132° C.) to obtain 38.6 g of a monomer (1). Further, the method for synthesizing the monomer (1) is schematically shown in Scheme (S1). Further, NMR is an abbreviation of nuclear magnetic resonance.

¹H-NMR (Acetone-d6: ppm) δ: 7.36 (d, 1H), 7.33 (s, 1H), 7.19 (d, 1H), 6.74 (dd, 1H), 5.80 (d, 1H), 5.27 (d, 1H), 2.26 (s, 3H), 2.25 (s, 3H)

<Synthesis 2 of Monomer (1)>

150.0 g of 3,4-dihydroxybenzaldehyde, 46.2 g of piperidine, 0.03 g of 4-methoxyphenol, and 850 g of pyridine were mixed, and 113.0 g of malonic acid was added thereto to obtain a mixed liquid. This mixed liquid was heated to a liquid temperature of 70° C. and stirred for 1.5 hours. 113.0 g of malonic acid was further added to the stirred mixed liquid, the mixture was stirred for 1.5 hours under heating while the liquid temperature was kept at 70° C., and then it was confirmed that 3,4-dihydroxybenzaldehyde as a raw material in the reaction liquid was consumed. The reaction liquid was warmed to 110° C. and stirred for 2 hours while the liquid temperature was kept, and then the stirred reaction liquid was cooled to 5° C. or lower in an ice bath. 332.6 g of acetic anhydride was added dropwise to the cooled reaction liquid with carefulness not to cause extreme heat generation and the mixture was stirred at room temperature for 2 hours. After completing the reaction, 1,800 mL of ethyl acetate, 900 mL of a saturated aqueous ammonium chloride solution, and 600 mL of water were added to the reaction liquid to perform a liquid separation operation and the organic layer was recovered. Next, the organic layer was twice washed with 900 mL of a saturated aqueous ammonium chloride solution and then three times washed with 900 mL of saturated saline. After dehydration over magnesium sulfate, the magnesium sulfate was filtered and separated, and 0.15 g of 4-methoxyphenol was added to a filtrate thus obtained, the mixture was concentrated under reduced pressure, and then the residual solvent was distilled off to obtain a residue. The residue was distilled and purified (2.5 Torr, a boiling point of 132° C.) to obtain 123.0 g of the monomer (1) by the same scheme as in Synthesis 1 of Monomer (1).

¹H-NMR (Acetone-d6: ppm) δ: 7.36 (d, 1H), 7.33 (s, 1H), 7.19 (d, 1H), 6.74 (dd, 1H), 5.80 (d, 1H), 5.27 (d, 1H), 2.26 (s, 3H), 2.25 (s, 3H)

<Synthesis of Monomer (2)>

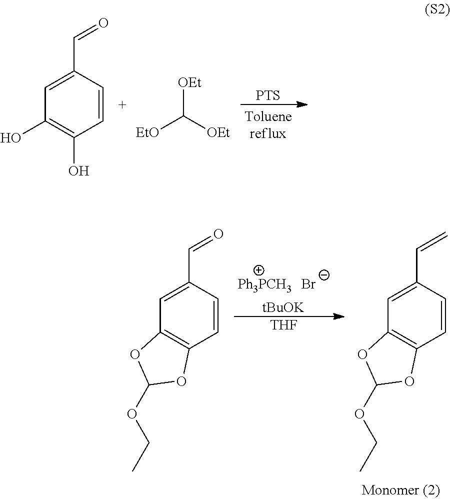

(Synthesis of Intermediate (2-1))

25.0 g of 3,4-dihydroxybenzaldehyde, 1.8 g of paratoluenesulfonic acid monohydrate, and 500 mL of toluene were mixed to obtain a mixed liquid. Next, the mixed liquid was heated and refluxed for 30 minutes, and then 52.7 g of ethyl orthoformate was added to the mixed liquid thus heated and refluxed, and the mixture was further heated and refluxed for 3 hours while ethanol by-produced was removed. Next, 30 g of ethyl orthoformate was added to the mixed liquid thus heated and refluxed, and the mixture was further heated and refluxed for 2 hours to obtain a reaction liquid. After confirming that 3,4-dihydroxybenzaldehyde as a raw material in the reaction liquid was consumed, the reaction liquid was left to stand to room temperature. Next, the reaction liquid left to be cooled was added to 500 mL of a 2% aqueous sodium hydrogen carbonate solution to perform a liquid separation operation and the organic layer was recovered. Next, the organic layer was three times washed with water and then concentrated under reduced pressure, and the residual solvent was distilled off to obtain 36.2 g of an intermediate 2-1. The purity of the intermediate 2-1 thus obtained was 98% by mass (2% by mass of ethyl orthoformate was contained). The intermediate (2-1) was not further purified and used for the next reaction.

¹H-NMR (Acetone-d6: ppm) δ: 9.88 (s, 1H), 7.59 (d, 1H), 7.39 (s, 1H), 7.14 (s, 1H), 7.12 (d, 1H), 3.78 (q, 2H), 1.23 (s, 3H)

(Synthesis of Monomer (2))

70.9 g of methyltriphenylphosphonium bromide, 0.02 g of 2,6-di-tert-butyl-p-cresol, and 350 mL of tetrahydrofuran were mixed to obtain a mixed liquid. Next, the mixed liquid was ice-cooled to 5° C. or lower in a nitrogen atmosphere. Next, 23.4 g of tert-butoxypotassium was added to the mixed liquid thus ice-cooled with carefulness not to cause extreme heat generation, and the mixture was returned to room temperature and then stirred for 1 hour to obtain a reaction liquid. Next, the reaction liquid was ice-cooled to 5° C. or lower, and a solution formed by mixing 26.2 g of the intermediate 2-1 (a purity of 98%) and 15 mL of tetrahydrofuran was added dropwise to the reaction liquid with carefulness not to cause extreme heat generation. Next, the liquid temperature of the reaction liquid was returned to room temperature, further stirred for 3 hours to obtain a reaction liquid, and then ice-cooled to 5° C. or lower. Next, 350 mL of water was added dropwise to the reaction liquid thus ice-cooled with carefulness not to cause extreme heat generation. Next, 350 mL of ethyl acetate was further added to the reaction liquid to perform a liquid separation operation and the organic layer was recovered. Next, the organic layer was five times washed with water and dehydrated over sodium sulfate. Next, sodium sulfate was filtered and separated to obtain a filtrate. Next, the filtrate was concentrated under reduced pressure and the solvent was distilled off to obtain a residue. A mixed solution of n-hexane and ethyl acetate (n-hexane/ethyl acetate=95/5 (mass ratio)) was added to the residue, and the precipitated crystal was filtered and separated. The obtained solution was concentrated under reduced pressure, and then distilled and purified (2.8 Torr, a boiling point of 98° C.) to obtain 16.5 g of a monomer (2). Further, the method for synthesizing the monomer (2) is schematically shown in Scheme (S2).

¹H-NMR (Acetone-d6: ppm) δ: 7.10 (d, 1H), 6.98 (s, 1H), 6.95 (d, 1H), 6.86 (d, 1H), 6.68 (dd, 1H), 5.67 (d, 1H), 5.12 (d, 1H), 3.72 (q, 2H), 1.21 (s, 3H)

<Synthesis of Resin (A-1)>

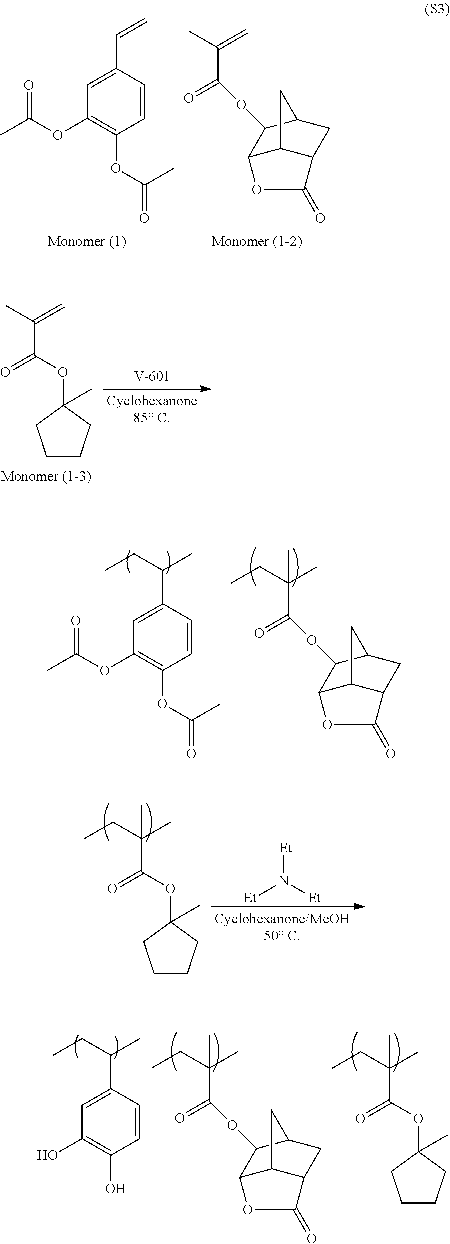

11.9 g of the monomer (1), 8.0 g of the monomer (1-2), 15.1 g of the monomer (1-3), and 1.12 g of a polymerization initiator V-601 (manufactured by Wako Pure Chemical Industries, Co., Ltd.) were dissolved in 129.0 g of cyclohexanone to obtain a mixed liquid. Next, 69.5 g of cyclohexanone was put into a reaction vessel, and the mixed liquid was added dropwise to cyclohexanone in the reaction vessel kept to 85° C. for 4 hours in a nitrogen gas atmosphere to obtain a reaction liquid. The reaction liquid was stirred under heating over 2 hours and then left to be cooled to room temperature. Next, 49.6 g of methanol and 4.9 g of triethylamine were added to the reaction liquid, and the reaction liquid was heated and stirred at 50° C. for 18 hours, and then left to be cooled to room temperature. Next, 200 g of ethyl acetate and 200 g of water were added to the reaction liquid to perform a liquid separation operation and the organic layer was recovered. The organic layer was three times washed with water and then the solvent was distilled off under reduced pressure. The residual solid was dissolved in 200 g of propylene glycol monomethyl ether acetate (PGMEA), the solvent was distilled off under reduced pressure for azeotropic dehydration, and then 198.5 g of cyclohexanone was added thereto to obtain a solution. Next, the solution was added dropwise to a mixed solution of 2,336 g of n-heptane and ethyl acetate (n-heptane/ethyl acetate=9/1 (mass ratio)), and the solid was precipitated and filtered. Next, the filtered solid was washed with a mixed solution of 701 g of n-heptane and ethyl acetate (n-heptane/ethyl acetate=9/1 (mass ratio)). Thereafter, the washed solid was dried under reduced pressure to obtain 23.8 g of a resin (A-1). As seen from ¹H-NMR and ¹³C-NMR, the compositional ratio in the resin was calculated as follows: the repeating unit (a)/the repeating unit (c)/the repeating unit (b)=30/20/50 (molar ratio). Further, the weight-average molecular weight and the dispersity as determined by means of GPC are the values described in Table 1. Further, the method for synthesizing the resin (A-1) is schematically shown in Scheme (S3). Furthermore, DMSO is an abbreviation of dimethyl sulfoxide.

¹H-NMR (DMSO-d6: ppm) δ: 8.76-8.29, 6.88-5.80, 4.71-2.84, 2.63-0.21 (peaks are all broad)

<Synthesis of Resin (A-38)>

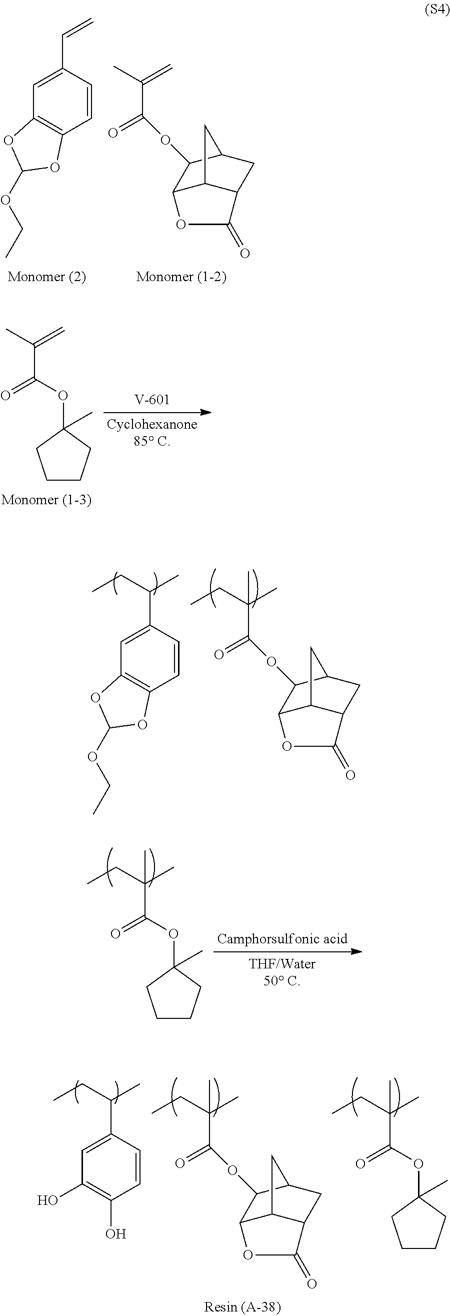

5.8 g of the monomer (2), 4.4 g of the monomer (1-2), 8.4 g of the monomer (1-3), and 0.69 g of a polymerization initiator V-601 (manufactured by Wako Pure Chemical Industries, Co., Ltd.) were dissolved in 67.2 g of cyclohexanone to obtain a mixed liquid. Next, 36.9 g of cyclohexanone was put into a reaction vessel and the mixed liquid was added dropwise to cyclohexanone in the reaction vessel kept to 85° C. for 4 hours in a nitrogen gas atmosphere to obtain a reaction solution. The reaction solution was stirred under heating over 2 hours and then left to be cooled to room temperature. Next, the reaction solution was added dropwise to a mixed solution of 1,242 g of methanol and water (methanol/water=9/1 (mass ratio)), and the solid was precipitated and filtered. Next, the filtered solid was washed with a mixed solution of 372 g of methanol and water (methanol/water=9/1 (mass ratio)). Thereafter, the washed solid was dried under reduced pressure to obtain 14.3 g of a resin A-38 precursor. Next, 14 g of the resin A-38 precursor was dissolved in 189 g of tetrahydrofuran to obtain a dissolution liquid. Next, a solution formed by dissolving 1.6 g of (±)-10-camphorsulfonic acid in 8.0 g of water was added dropwise to the dissolution liquid, and the mixture was heated and stirred at 50° C. for 10 hours to obtain a reaction liquid. Next, 200 g of ethyl acetate and 200 g of water were added to the reaction liquid to perform a liquid separation operation and the organic layer was recovered. Next, the organic layer was three times washed with water, and then the solvent was distilled off by concentration under reduced pressure to obtain a residue. The residue was dissolved in 61.2 g of ethyl acetate, and added dropwise to a mixed solution of 720 g of n-heptane and ethyl acetate (n-heptane/ethyl acetate=9/1 (mass ratio)), and the solid was precipitated and filtered. The filtered solid was washed with a mixed solution of 216 g of n-heptane and ethyl acetate (n-heptane/ethyl acetate=9/1 (mass ratio)). Thereafter, the washed solid was dried under reduced pressure to obtain 10.8 g of a resin A-38. As seen from ¹H-NMR and ¹³C-NMR, the compositional ratio in the resin was calculated as follows: the repeating unit (a)/the repeating unit (c)/the repeating unit (b)=30/20/50 (molar ratio). Further, the weight-average molecular weight and the dispersity as determined by means of GPC are the values described in Table 1. Further, the method for synthesizing the resin (A-38) is schematically shown in Scheme (S4).

¹H-NMR (DMSO-d6: ppm) δ: 8.76-8.29, 6.88-5.80, 4.71-2.84, 2.63-0.21 (peaks are all broad)

By performing the same operation as in Synthesis Examples, the resin (A-1) to the resin (A-75), the resin (R-1), and the resin (R-2) as the resin (A) shown in Table 1 were synthesized.

Furthermore, the resin (R-2) is a resin synthesized using dihydroxystyrene as a monomer. That is, it is a resin synthesized by a process not including the first step and the second step. These cases are described as “Unprotected” in the table.

Furthermore, the weight-average molecular weight and the dispersity in Table 1 represent a weight-average molecular weight and a dispersity of each of the resins finally obtained. Further, the weight-average molecular weight and the dispersity are values in terms of polystyrene as determined by a GPC method.

TABLE 1
Table 1-2

| | | | | Composition | | | | |
|---|---|---|---|---|---|---|---|---|
| | | | | (molar ratio) | | | | |
| | | | | of | | | | Acid |
| | | | | respective | | | | dissociation |
| | | | | repeating | | | | coefficient |
| | Monomer that | | | units in resin | | | | of |
| | forms repeating unit | | | (A) (repeating | | | | acid or acid |
| | (a-2), and forms | | | unit | | | | dissociation |
| | repeating unit (a) | Monomer | | (a)/repeating | Weight- | | | coefficient |
| | through | that forms | Monomer that | unit | average | | Type of | of |
| | deprotection with | repeating | forms repeating | (c)/repeating | molecular | Dis- | acid or | conjugate |
| Resin | acid or base | unit (b) | unit (c) | unit (b)) | weight | persity | base | acid of base |
| A-1 | 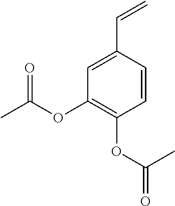 [SMILES: C=Cc1ccc(OC(C)=O)c(OC(C)=O)c1] | 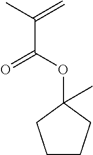 | 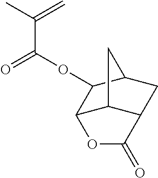 [SMILES: C=C(C)C(=O)OC1C2CC3C(=O)OC1C3C2] | 30/20/50 | 12,800 | 1.51 | Triethyl- amine | 10.6 |
| A-2 | 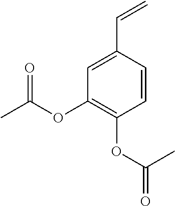 [SMILES: C=Cc1ccc(OC(C)=O)c(OC(C)=O)c1] | 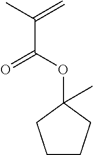 | 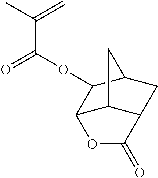 [SMILES: C=C(C)C(=O)OC1C2CC3C(=O)OC1C3C2] | 30/20/50 | 12,800 | 1.51 | DMAP | 9.5 |
| A-3 | 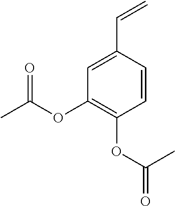 [SMILES: C=Cc1ccc(OC(C)=O)c(OC(C)=O)c1] | 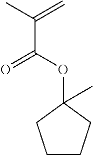 | 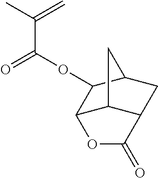 [SMILES: C=C(C)C(=O)OC1C2CC3C(=O)OC1C3C2] | 30/20/50 | 12,800 | 1.51 | Morpho- line | 8.9 |
| A-4 | 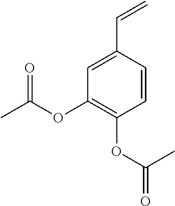 [SMILES: C=Cc1ccc(OC(C)=O)c(OC(C)=O)c1] | 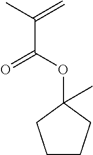 | 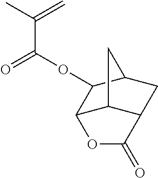 [SMILES: C=C(C)C(=O)OC1C2CC3C(=O)OC1C3C2] | 30/20/50 | 12,800 | 1.51 | Pyridine | 5.2 |
| A-5 | 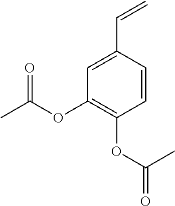 [SMILES: C=Cc1ccc(OC(C)=O)c(OC(C)=O)c1] | 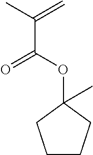 | 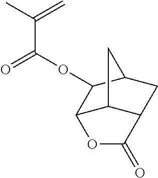 [SMILES: C=C(C)C(=O)OC1C2CC3C(=O)OC1C3C2] | 30/20/50 | 12,800 | 1.51 | HCI | −3.7 |
| A-6 | 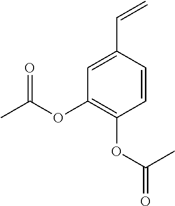 [SMILES: C=Cc1ccc(OC(C)=O)c(OC(C)=O)c1] | 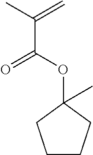 | 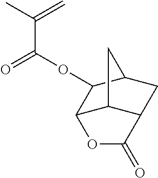 [SMILES: C=C(C)C(=O)OC1C2CC3C(=O)OC1C3C2] | 30/10/60 | 13,000 | 1.50 | Triethyl- amine | 10.6 |
| A-7 | 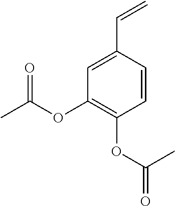 [SMILES: C=Cc1ccc(OC(C)=O)c(OC(C)=O)c1] | 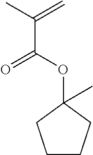 | 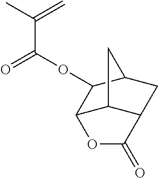 [SMILES: C=C(C)C(=O)OC1C2CC3C(=O)OC1C3C2] | 10/20/70 | 13,100 | 1.53 | Triethyl- amine | 10.6 |
| A-8 | 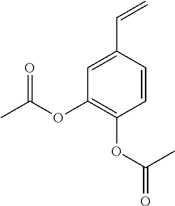 [SMILES: C=Cc1ccc(OC(C)=O)c(OC(C)=O)c1] | 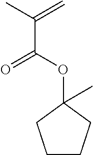 | 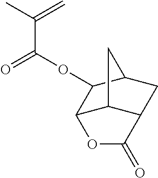 [SMILES: C=C(C)C(=O)OC1C2CC3C(=O)OC1C3C2] | 30/30/40 | 8,100 | 1.48 | Triethyl- amine | 10.6 |
| A-9 | 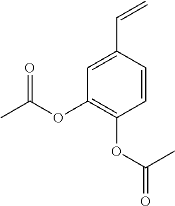 [SMILES: C=Cc1ccc(OC(C)=O)c(OC(C)=O)c1] | 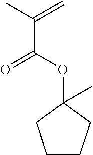 | | 50/0/50 | 7,700 | 1.46 | Triethyl- amine | 10.6 |
| A-10 | 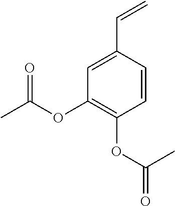 [SMILES: C=Cc1ccc(OC(C)=O)c(OC(C)=O)c1] | 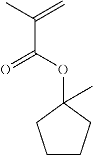 | | 50/0/50 | 7,700 | 1.46 | DBU | 13.3 |
| A-11 | 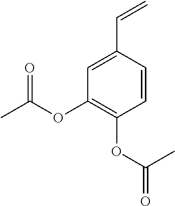 [SMILES: C=Cc1ccc(OC(C)=O)c(OC(C)=O)c1] | 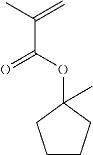 | 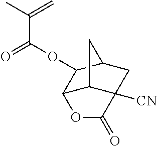 [SMILES: C=C(C)C(=O)OC1C2CC3C1OC(=O)C3(C#N)C2] | 30/30/40 | 8,100 | 1.48 | Triethyl- amine | 10.6 |
| A-12 | 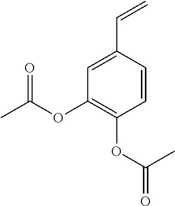 [SMILES: C=Cc1ccc(OC(C)=O)c(OC(C)=O)c1] | 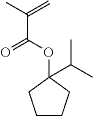 | 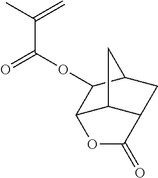 [SMILES: C=C(C)C(=O)OC1C2CC3C(=O)OC1C3C2] | 20/10/70 | 12,300 | 1.53 | Triethyl- amine | 10.6 |
| A-13 | 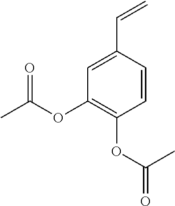 [SMILES: C=Cc1ccc(OC(C)=O)c(OC(C)=O)c1] | 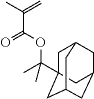 [SMILES: C=C(C)C(=O)OC(C)(C)C12CC3CC(CC(C3)C1)C2] | 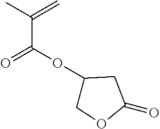 | 30/20/50 | 12,900 | 1.55 | Triethyl- amine | 10.6 |
| A-14 | 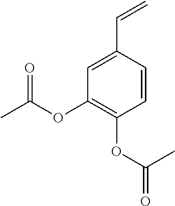 [SMILES: C=Cc1ccc(OC(C)=O)c(OC(C)=O)c1] | 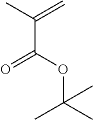 | | 70/0/30 | 7,700 | 1.46 | Triethyl- amine | 10.6 |

TABLE 2
Table 1-2

| | | | | Composition | | | | |
|---|---|---|---|---|---|---|---|---|
| | | | | (molar ratio) | | | | |
| | | | | of respective | | | | Acid |
| | | | | repeating | | | | dissociation |
| | | | | units in | | | | coefficient |
| | | | | resin (A) | | | | of acid or |
| | Monomer | | | (repeating | | | | acid |
| | that forms repeating | | | unit (a)/ | | | | dissociation |
| | unit (a-2), and forms | | | (repeating | Weight- | | | coefficient |
| | repeating unit (a) | | | unit (c)/ | average | | Type of | of |
| | through deprotection | Monomer that forms | Monomer that forms | repeating | molecular | | acid or | conjugate |
| Resin | with acid or base | repeating unit (b) | repeating unit (c) | unit (b)) | weight | Dispersity | base | acid of base |
| A-15 | 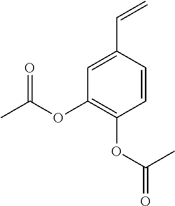 [SMILES: C=Cc1ccc(OC(C)=O)c(OC(C)=O)c1] | 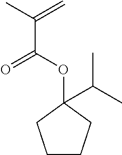 | 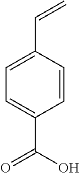 | 30/30/40 | 7,500 | 1.50 | Triethyl- amine | 10.6 |
| A-16 | 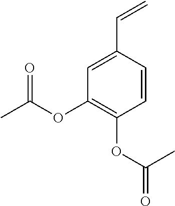 [SMILES: C=Cc1ccc(OC(C)=O)c(OC(C)=O)c1] | 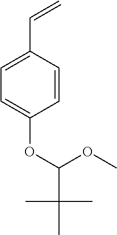 [SMILES: C=Cc1ccc(OC(OC)C(C)(C)C)cc1] | | 70/0/30 | 8,200 | 1.47 | Triethyl- amine | 10.6 |
| A-17 | 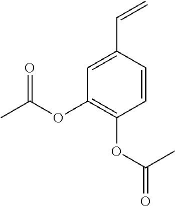 [SMILES: C=Cc1ccc(OC(C)=O)c(OC(C)=O)c1] | 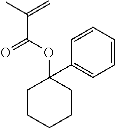 [SMILES: C=C(C)C(=O)OC1(c2ccccc2)CCCCC1] | 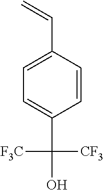 [SMILES: C=Cc1ccc(C(O)(C(F)(F)F)C(F)(F)F)cc1] | 30/30/40 | 7,900 | 1.51 | Triethyl- amine | 10.6 |
| A-18 | 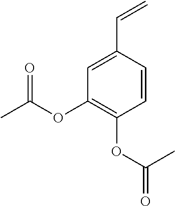 [SMILES: C=Cc1ccc(OC(C)=O)c(OC(C)=O)c1] | 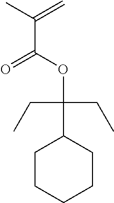 [SMILES: C=C(C)C(=O)OC(CC)(CC)C1CCCCC1] | 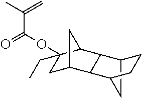 [SMILES: C=C(C)C(=O)OC1(CC)CC2CC1C1C3CCC(C3)C21] | 30/20/50 | 12,700 | 1.53 | Triethyl- amine | 10.6 |

TABLE 3
Table 1-3

| | | | | Composition | | | | Acid |
|---|---|---|---|---|---|---|---|---|
| | | | | (molar ratio) of | | | | dissociation |
| | | | | respective | | | | coefficient of |
| | | | | repeating units | | | | acid or acid |
| | | | | in resin (A) | Weight | | | dissociation |
| | Monomer that forms repeating unit (a-2), | | | (repeating unit | average | | | coefficient of |
| | and forms repeating unit (a) through | Monomer that forms | Monomer that forms | (a)/repeating unit | molecular | | | conjugate |
| Resin | deprotection with acid or base | repeating unit (b) | repeating unit (c) | (c)/repeating | weight | Dispersity | Type of acid or base | acid of base |
| A-19 | 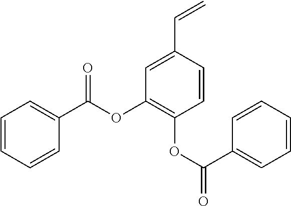 [SMILES: C=Cc1ccc(OC(=O)c2ccccc2)c(OC(=O)c2ccccc2)c1] | 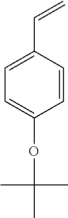 | | 50/0/50 | 8,500 | 1.49 | Triethylamine | 10.6 |
| A-20 | 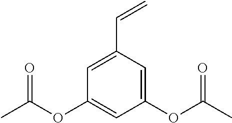 [SMILES: C=Cc1cc(OC(C)=O)cc(OC(C)=O)c1] | 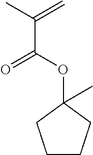 | 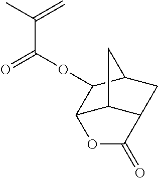 [SMILES: C=C(C)C(=O)OC1C2CC3C(=O)OC1C3C2] | 30/20/50 | 12,800 | 1.53 | Triethylamine | 10.6 |
| A-21 | 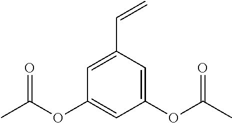 [SMILES: C=Cc1cc(OC(C)=O)cc(OC(C)=O)c1] | 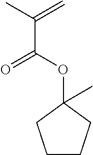 | 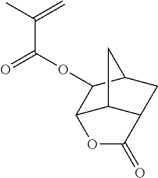 [SMILES: C=C(C)C(=O)OC1C2CC3C(=O)OC1C3C2] | 30/20/50 | 12,800 | 1.53 | Morpholine | 8.9 |
| A-22 | 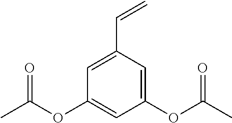 [SMILES: C=Cc1cc(OC(C)=O)cc(OC(C)=O)c1] | 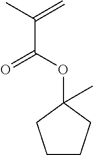 | 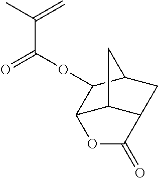 [SMILES: C=C(C)C(=O)OC1C2CC3C(=O)OC1C3C2] | 30/10/60 | 12,200 | 1.51 | Triethylamine | 10.6 |
| A-23 | 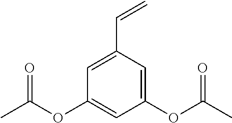 [SMILES: C=Cc1cc(OC(C)=O)cc(OC(C)=O)c1] | 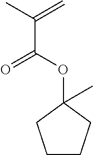 | 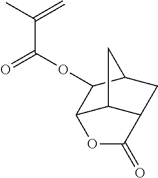 [SMILES: C=C(C)C(=O)OC1C2CC3C(=O)OC1C3C2] | 30/30/40 | 7,800 | 1.50 | Triethylamine | 10.6 |
| A-24 | 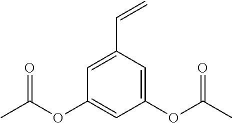 [SMILES: C=Cc1cc(OC(C)=O)cc(OC(C)=O)c1] | 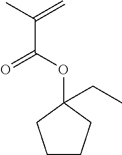 | | 50/0/50 | 7,200 | 1.47 | Triethylamine | 10.6 |
| A-25 | 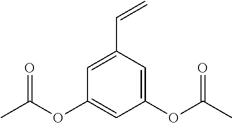 [SMILES: C=Cc1cc(OC(C)=O)cc(OC(C)=O)c1] | 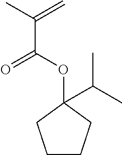 | 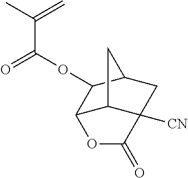 [SMILES: C=C(C)C(=O)OC1C2CC3C1OC(=O)C3(C#N)C2] | 30/30/40 | 7,600 | 1.53 | Triethylamine | 10.6 |
| A-26 | 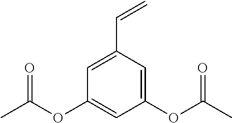 [SMILES: C=Cc1cc(OC(C)=O)cc(OC(C)=O)c1] | 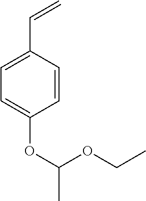 | | 70/0/30 | 8,000 | 1.49 | Triethylamine | 10.6 |
| A-27 | 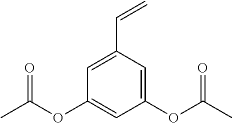 [SMILES: C=Cc1cc(OC(C)=O)cc(OC(C)=O)c1] | 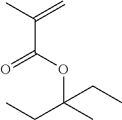 | | 50/0/50 | 8,200 | 1.46 | Triethylamine | 10.6 |
| A-28 | 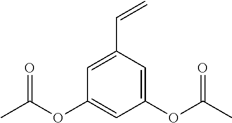 [SMILES: C=Cc1cc(OC(C)=O)cc(OC(C)=O)c1] | 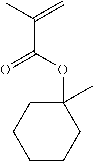 | 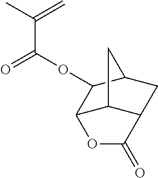 [SMILES: C=C(C)C(=O)OC1C2CC3C(=O)OC1C3C2] | 30/20/50 | 12,400 | 1.55 | Triethylamine | 10.6 |
| A-29 | 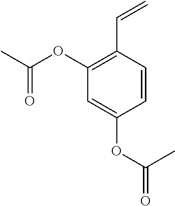 [SMILES: C=Cc1ccc(OC(C)=O)cc1OC(C)=O] | 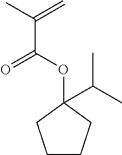 | | 70/0/30 | 7,900 | 1.50 | Triethylamine | 10.6 |
| A-30 | 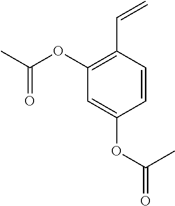 [SMILES: C=Cc1ccc(OC(C)=O)cc1OC(C)=O] | 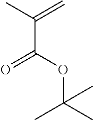 | 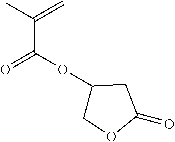 | 30/30/40 | 7,800 | 1.55 | Triethylamine | 10.6 |

TABLE 4
Table 1-4

| | | | | Composition | | | | Acid |
|---|---|---|---|---|---|---|---|---|
| | | | | (molar ratio) of | | | | dissociation |
| | | | | respective | | | | coefficient |
| | Monomer that | | | repeating units | | | | of acid or |
| | forms repeating | | | in resin (A) | | | | acid |
| | unit (a-2), and | | | (repeating unit | | | | dissociation |
| | forms repeating | Monomer | Monomer | (a)/repeating | Weight | | | coefficient |
| | unit (a) through | that forms | that forms | unit | average | | Type of | of |
| | deprotection with | repeating | repeating | (c)/repeating | molecular | Dis- | acid or | conjugate |
| Resin | acid or base | unit (b) | unit (c) | unit (b)) | weight | persity | base | acid of base |
| A-31 | 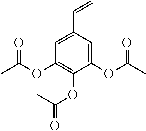 [SMILES: C=Cc1cc(OC(C)=O)c(OC(C)=O)c(OC(C)=O)c1] | 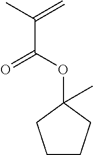 | 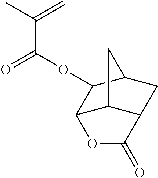 [SMILES: C=C(C)C(=O)OC1C2CC3C(=O)OC1C3C2] | 30/20/50 | 12,700 | 1.54 | Triethyl- amine | 10.6 |
| A-32 | 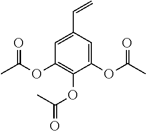 [SMILES: C=Cc1cc(OC(C)=O)c(OC(C)=O)c(OC(C)=O)c1] | 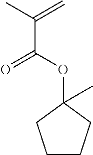 | 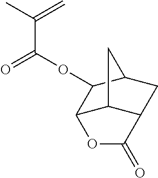 [SMILES: C=C(C)C(=O)OC1C2CC3C(=O)OC1C3C2] | 30/20/50 | 12,700 | 1.54 | Morpho- line | 8.9 |
| A-33 | 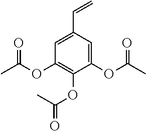 [SMILES: C=Cc1cc(OC(C)=O)c(OC(C)=O)c(OC(C)=O)c1] | 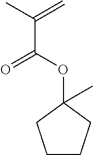 | 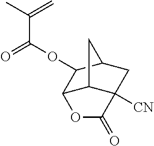 [SMILES: C=C(C)C(=O)OC1C2CC3C1OC(=O)C3(C#N)C2] | 30/30/40 | 8,000 | 1.48 | Triethyl- amine | 10.6 |
| A-34 | 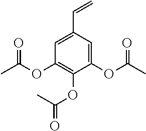 [SMILES: C=Cc1cc(OC(C)=O)c(OC(C)=O)c(OC(C)=O)c1] | 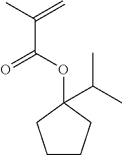 | | 50/0/50 | 7,800 | 1.50 | Triethyl- amine | 10.6 |
| A-35 | 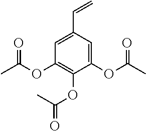 [SMILES: C=Cc1cc(OC(C)=O)c(OC(C)=O)c(OC(C)=O)c1] | 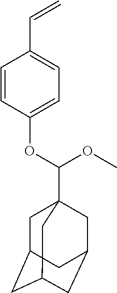 [SMILES: C=Cc1ccc(OC(OC)C23CC4CC(CC(C4)C2)C3)cc1] | | 70/0/30 | 7,600 | 1.45 | Triethyl- amine | 10.6 |
| A-36 | 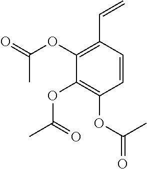 [SMILES: C=Cc1ccc(OC(C)=O)c(OC(C)=O)c1OC(C)=O] | 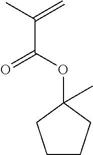 | 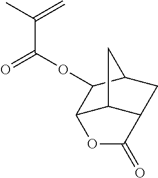 [SMILES: C=C(C)C(=O)OC1C2CC3C(=O)OC1C3C2] | 30/30/40 | 7,000 | 1.49 | Triethyl- amine | 10.6 |
| A-37 | 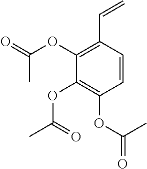 [SMILES: C=Cc1ccc(OC(C)=O)c(OC(C)=O)c1OC(C)=O] | 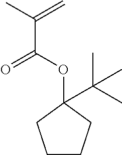 | | 50/0/50 | 6,400 | 1.51 | Triethyl- amine | 10.6 |
| A-38 | 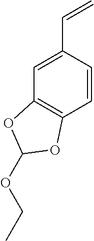 | 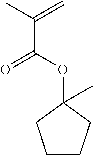 | 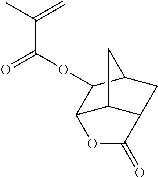 [SMILES: C=C(C)C(=O)OC1C2CC3C(=O)OC1C3C2] | 30/20/50 | 12,500 | 1.53 | CSA | 1.2 |
| A-39 | 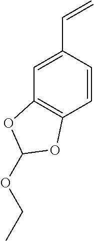 | 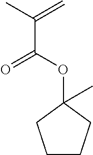 | 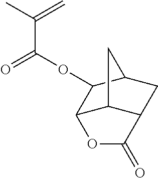 [SMILES: C=C(C)C(=O)OC1C2CC3C(=O)OC1C3C2] | 30/20/50 | 12,500 | 1.53 | PTS | −0.43 |
| A-40 | 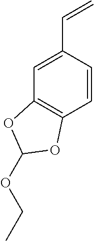 | 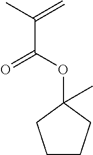 | 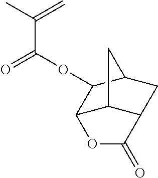 [SMILES: C=C(C)C(=O)OC1C2CC3C(=O)OC1C3C2] | 30/20/50 | 12,500 | 1.53 | HCI | −3.7 |
| A-41 | 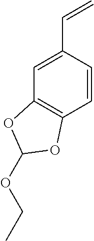 | 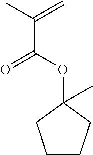 | 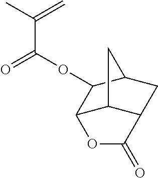 [SMILES: C=C(C)C(=O)OC1C2CC3C(=O)OC1C3C2] | 30/20/50 | 12,500 | 1.53 | CF₃COOH | 0.53 |

TABLE 5
Table 1-5

| | Monomer that | | | Composition | | | | |
|---|---|---|---|---|---|---|---|---|
| | forms | | | (mote ratio) of | | | | |
| | repeating unit | | | respective | | | | Acid |
| | (a-2), and | | | repeating units | | | | dissociation |
| | forms | | | in resin (A) | | | | coefficient of |
| | repeating unit | | | (repeating Unit | | | Type | acid or acid |
| | (a) through | Monomer | | (a)/repeating | Weight- | | of | dissociation |
| | deprotection | that forms | Monomer that | unit | average | | acid | coefficient of |
| | with acid or | repeating | forms repeating | (c)/repeating | molecular | | or | conjugate |
| Resin | base | unit (b) | unit (c) | unit (b)) | weight | Dispersity | base | acid of base |
| A-42 | 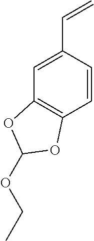 | 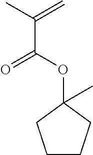 | 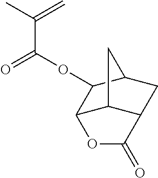 [SMILES: C=C(C)C(=O)OC1C2CC3C(=O)OC1C3C2] | 15/25/60 | 12,300 | 1.51 | CSA | 1.2 |
| A-43 | 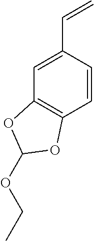 | 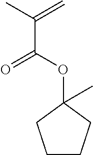 | 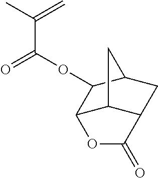 [SMILES: C=C(C)C(=O)OC1C2CC3C(=O)OC1C3C2] | 30/30/40 | 7,700 | 1.48 | CSA | 1.2 |
| A-44 | 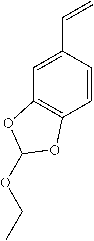 | 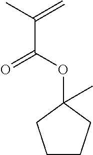 | | 50/0/50 | 7,300 | 1.49 | CSA | 1.2 |
| A-45 | 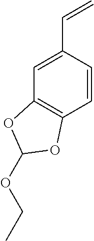 | 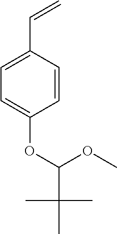 [SMILES: C=Cc1ccc(OC(OC)C(C)(C)C)cc1] | | 70/0/30 | 8,100 | 1.55 | CSA | 1.2 |
| A-46 | 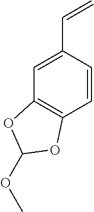 | 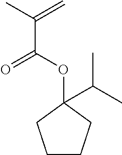 | 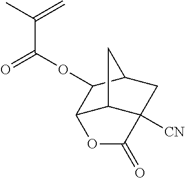 [SMILES: C=C(C)C(=O)OC1C2CC3C1OC(=O)C3(C#N)C2] | 30/30/40 | 7,100 | 1.54 | CSA | 1.2 |
| A-47 | 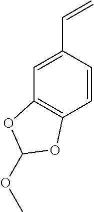 | 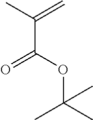 | 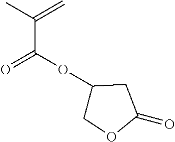 | 30/10/60 | 11,800 | 1.55 | CSA | 1.2 |
| A-48 | 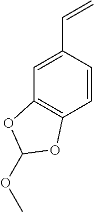 | 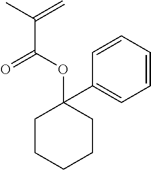 [SMILES: C=C(C)C(=O)OC1(c2ccccc2)CCCCC1] | 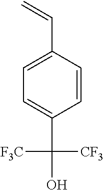 [SMILES: C=Cc1ccc(C(O)(C(F)(F)F)C(F)(F)F)cc1] | 30/30/40 | 7,600 | 1.52 | CSA | 1.2 |
| A-49 | 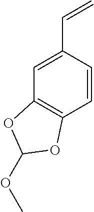 | 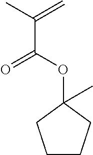 | 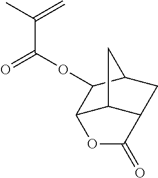 [SMILES: C=C(C)C(=O)OC1C2CC3C(=O)OC1C3C2] | 30/10/60 | 12,100 | 1.50 | CSA | 1.2 |
| A-50 | 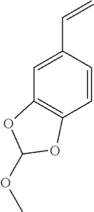 | 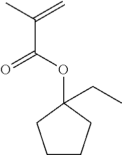 | 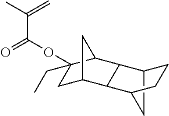 [SMILES: C=C(C)C(=O)OC1(CC)CC2CC1C1C3CCC(C3)C21] | 30/10/60 | 11,600 | 1.56 | CSA | 1.2 |
| A-51 | 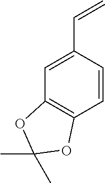 | 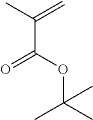 | 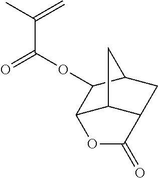 [SMILES: C=C(C)C(=O)OC1C2CC3C(=O)OC1C3C2] | 30/10/60 | 12,300 | 1.53 | CSA | 1.2 |

TABLE 6
Table 1-6

| | | | | Composition | | | | |
|---|---|---|---|---|---|---|---|---|
| | | | | (molar ratio) of | | | | |
| | | | | respective | | | | Acid |
| | | | | repeating units | | | | dissociation |
| | | | | in resin (A) | | | | coefficient of |
| | | | | (repeating Unit | | | | acid or acid |
| | | | | (a)/repeating | | | | dissociation |
| | Monomer that forms repeating unit (a-2), | | | unit | | | | coefficient of |
| | and forms repeating unit (a) through | Monomer that forms | Monomer that forms | (c)/repeating | Weight-average | | Type of | conjugate acid |
| Resin | deprotection with acid or base | repeating unit (b) | repeating unit (c) | unit (b)) | molecular weight | Dispersity | acid or base | of base |
| A-52 | 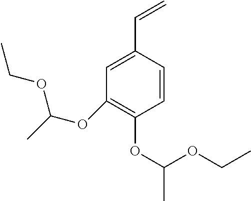 [SMILES: C=Cc1ccc(OC(C)OCC)c(OC(C)OCC)c1] | 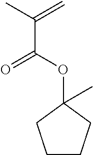 | 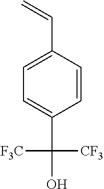 [SMILES: C=Cc1ccc(C(O)(C(F)(F)F)C(F)(F)F)cc1] | 30/30/40 | 7,100 | 1.54 | CSA | 1.2 |
| A-53 | 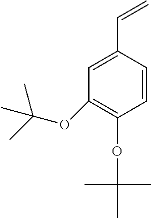 [SMILES: C=Cc1ccc(OC(C)(C)C)c(OC(C)(C)C)c1] | 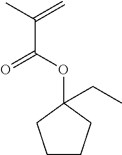 | 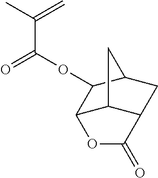 [SMILES: C=C(C)C(=O)OC1C2CC3C(=O)OC1C3C2] | 30/20/50 | 11,500 | 1.51 | CF₃COOH | 0.53 |
| A-54 | 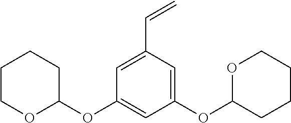 [SMILES: C=Cc1cc(OC2CCCCO2)cc(OC2CCCCO2)c1] | 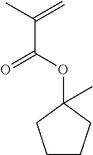 | 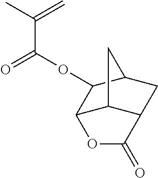 [SMILES: C=C(C)C(=O)OC1C2CC3C(=O)OC1C3C2] | 30/20/50 | 12,400 | 1.55 | CSA | 1.2 |
| A-55 | 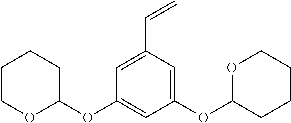 [SMILES: C=Cc1cc(OC2CCCCO2)cc(OC2CCCCO2)c1] | 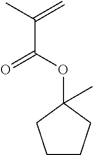 | 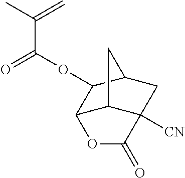 [SMILES: C=C(C)C(=O)OC1C2CC3C1OC(=O)C3(C#N)C2] | 30/30/40 | 7,700 | 1.54 | CSA | 1.2 |
| A-56 | 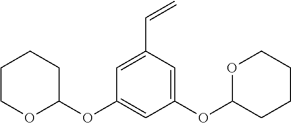 [SMILES: C=Cc1cc(OC2CCCCO2)cc(OC2CCCCO2)c1] | 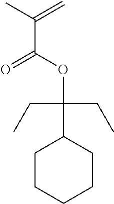 [SMILES: C=C(C)C(=O)OC(CC)(CC)C1CCCCC1] | | 70/0/30 | 7,500 | 1.50 | CSA | 1.2 |
| A-57 | 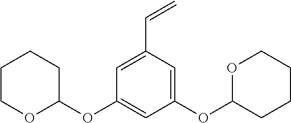 [SMILES: C=Cc1cc(OC2CCCCO2)cc(OC2CCCCO2)c1] | 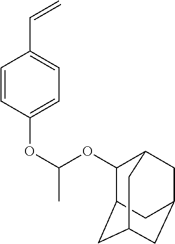 [SMILES: C=Cc1ccc(OC(C)OC2C3CC4CC(C3)CC2C4)cc1] | | 70/0/30 | 7,900 | 1.48 | CSA | 1.2 |
| A-58 | 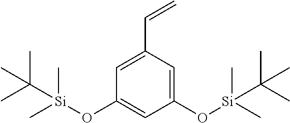 [SMILES: C=Cc1cc(O[Si](C)(C)C(C)(C)C)cc(O[Si](C)(C)C(C)(C)C)c1] | 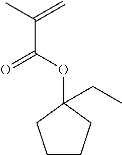 | 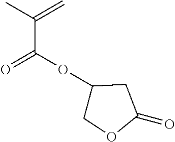 | 30/20/50 | 13,800 | 1.56 | PTS | −0.43 |
| A-59 | 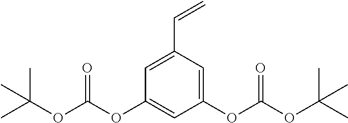 [SMILES: C=Cc1cc(OC(=O)OC(C)(C)C)cc(OC(=O)OC(C)(C)C)c1] | 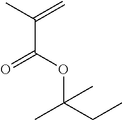 | 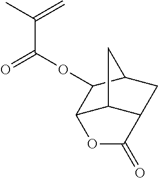 [SMILES: C=C(C)C(=O)OC1C2CC3C(=O)OC1C3C2] | 30/20/50 | 12,500 | 1.53 | CSA | 1.2 |
| A-60 | 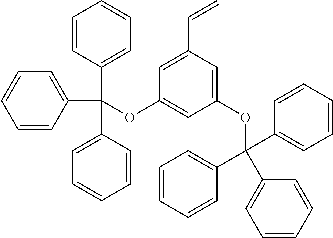 [SMILES: C=Cc1cc(OC(c2ccccc2)(c2ccccc2)c2ccccc2)cc(OC(c2ccccc2)(c2ccccc2)c2ccccc2)c1] | 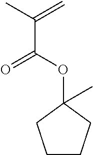 | 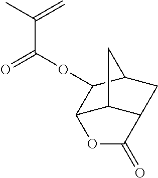 [SMILES: C=C(C)C(=O)OC1C2CC3C(=O)OC1C3C2] | 30/20/50 | 13,500 | 1.54 | HCI | −3.7 |
| A-61 | 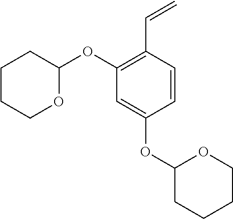 [SMILES: C=Cc1ccc(OC2CCCCO2)cc1OC1CCCCO1] | 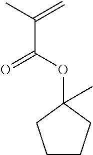 | 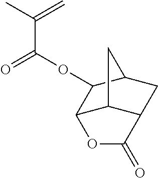 [SMILES: C=C(C)C(=O)OC1C2CC3C(=O)OC1C3C2] | 30/20/50 | 12,400 | 1.55 | CSA | 1.2 |
| A-62 | 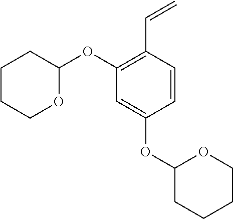 [SMILES: C=Cc1ccc(OC2CCCCO2)cc1OC1CCCCO1] | 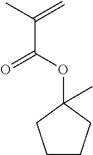 | | 70/0/30 | 7,800 | 1.53 | CSA | 1.2 |

TABLE 7
Table 1-7

| | | | | Composition | | | | |
|---|---|---|---|---|---|---|---|---|
| | | | | (molar ratio) of | | | | Acid |
| | | | | respective | | | | dissociation |
| | | | | repeating units | | | | coefficient of |
| | Monomer that forms | | | in resin (A) | | | | acid or acid |
| | repeating unit (a-2), | | | (repeating Unit | | | | dissociation |
| | and forms repeating | | | (a)/repeating | Weight- | | | coefficient of |
| | unit (a) through | | | unit | average | | Type of | conjugate |
| | deprotection with | Monomer that forms | Monomer that forms | (c)/repeating | molecular | Dis- | acid or | acid |
| Resin | acid or base | repeating unit (b) | repeating unit (c) | unit (b)) | weight | persity | base | of base |
| A-63 | 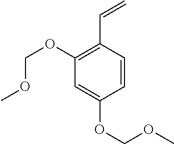 | 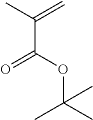 | | 70/0/30 | 7,800 | 1.48 | HCI | −3.7 |
| A-64 | 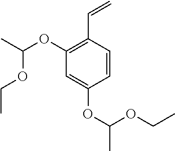 [SMILES: C=Cc1ccc(OC(C)OCC)cc1OC(C)OCC] | 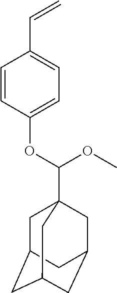 [SMILES: C=Cc1ccc(OC(OC)C23CC4CC(CC(C4)C2)C3)cc1] | | 70/0/30 | 7,300 | 1.50 | CSA | 1.2 |
| A-65 | 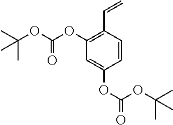 [SMILES: C=Cc1ccc(OC(=O)OC(C)(C)C)cc1OC(=O)OC(C)(C)C] | 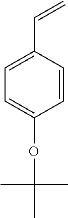 | | 70/0/30 | 8,100 | 1.49 | CSA | 1.2 |
| A-66 | 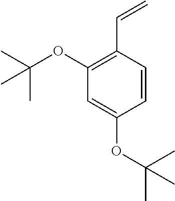 [SMILES: C=Cc1ccc(OC(C)(C)C)cc1OC(C)(C)C] | 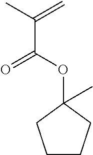 | 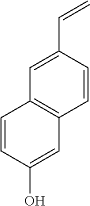 | 30/20/50 | 12,300 | 1.53 | CF₃COOH | 0.53 |
| A-67 | 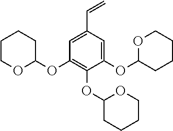 [SMILES: C=Cc1cc(OC2CCCCO2)c(OC2CCCCO2)c(OC2CCCCO2)c1] | 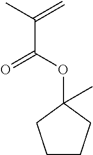 | 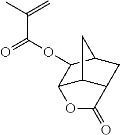 [SMILES: C=C(C)C(=O)OC1C2CC3C(=O)OC1C3C2] | 30/20/50 | 12,600 | 1.55 | CSA | 1.2 |
| A-68 | 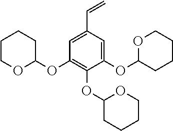 [SMILES: C=Cc1cc(OC2CCCCO2)c(OC2CCCCO2)c(OC2CCCCO2)c1] | 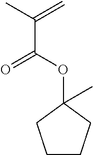 | 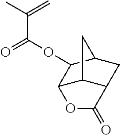 [SMILES: C=C(C)C(=O)OC1C2CC3C(=O)OC1C3C2] | 30/30/40 | 8,100 | 1.51 | CSA | 1.2 |
| A-69 | 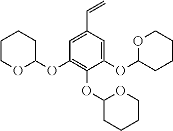 [SMILES: C=Cc1cc(OC2CCCCO2)c(OC2CCCCO2)c(OC2CCCCO2)c1] | 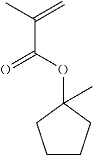 | 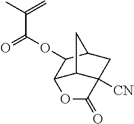 [SMILES: C=C(C)C(=O)OC1C2CC3C1OC(=O)C3(C#N)C2] | 30/30/40 | 7,900 | 1.56 | CSA | 1.2 |
| A-70 | 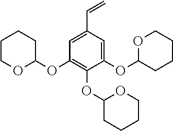 [SMILES: C=Cc1cc(OC2CCCCO2)c(OC2CCCCO2)c(OC2CCCCO2)c1] | 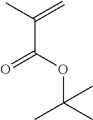 | | 50/0/50 | 7,700 | 1.47 | CSA | 1.2 |
| A-71 | 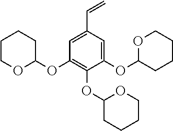 [SMILES: C=Cc1cc(OC2CCCCO2)c(OC2CCCCO2)c(OC2CCCCO2)c1] | 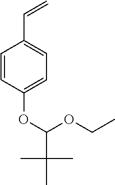 [SMILES: C=Cc1ccc(OC(OCC)C(C)(C)C)cc1] | | 70/0/30 | 8,400 | 1.49 | CSA | 1.2 |
| A-72 | 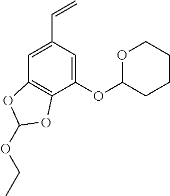 [SMILES: C=Cc1cc(OC2CCCCO2)c2c(c1)OC(OCC)O2] | 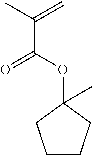 | 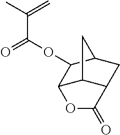 [SMILES: C=C(C)C(=O)OC1C2CC3C(=O)OC1C3C2] | 30/20/50 | 13,100 | 1.55 | CSA | 1.2 |
| A-73 | 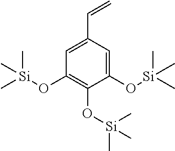 | 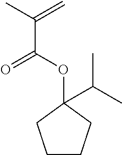 | 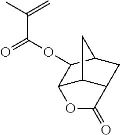 [SMILES: C=C(C)C(=O)OC1C2CC3C(=O)OC1C3C2] | 30/20/50 | 13,700 | 1.52 | HCI | −3.7 |

TABLE 8
Table 1-8

| | | | | Composition | | | | |
|---|---|---|---|---|---|---|---|---|
| | | | | (molar ratio) of | | | | |
| | | | | respective | | | | Acid |
| | | | | repeating units | | | | dissociation |
| | Monomer that forms | | | in resin (A) | | | | coefficient of |
| | repeating unit (a-2), | | | (repeating Unit | | | | acid or acid |
| | and forms repeating | | | (a)/repeating | Weight- | | | dissociation |
| | unit (a) through | | | unit | average | | Type of | coefficient of |
| | deprotection with | Monomer that forms | Monomer that forms | (c)/repeating | molecular | | acid or | conjugate |
| Resin | acid or base | repeating unit (b) | repeating unit (c) | unit (b)) | weight | Dispersity | base | acid of base |
| A-74 | 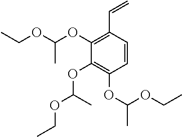 [SMILES: C=Cc1ccc(OC(C)OCC)c(OC(C)OCC)c1OC(C)OCC] | 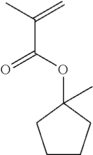 | 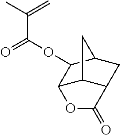 [SMILES: C=C(C)C(=O)OC1C2CC3C(=O)OC1C3C2] | 30/20/50 | 12,900 | 1.55 | CSA | 1.2 |
| A-75 | 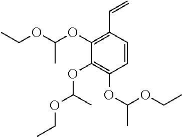 [SMILES: C=Cc1ccc(OC(C)OCC)c(OC(C)OCC)c1OC(C)OCC] | 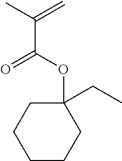 | | 70/0/30 | 8,300 | 1.48 | CSA | 1.2 |

TABLE 9
Table 1-9

| | | | | Composition | | | | |
|---|---|---|---|---|---|---|---|---|
| | | | | (molar ratio) of | | | | |
| | | | | respective | | | | Acid |
| | | | | repeating units | | | | dissociation |
| | | | | in resin (A) | | | | coefficient of |
| | | | | (repeating Unit | | | | acid or acid |
| | | | | (a)/repeating | Weight- | | | dissociation |
| | | | | unit | average | | Type of | coefficient of |
| | Comparative | Monomer that forms | Monomer that forms | (c)/repeating | molecular | | acid or | conjugate |
| Resin | monomer | repeating unit (b) | repeating unit (c) | unit (b)) | weight | Dispersity | base | acid of base |
| R-1 | 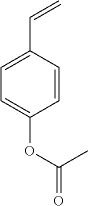 | 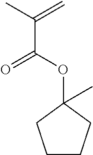 | 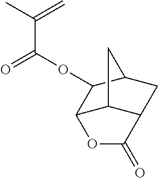 [SMILES: C=C(C)C(=O)OC1C2CC3C(=O)OC1C3C2] | 30/20/50 | 12,500 | 1.54 | Triethyl- amine | 10.6 |
| R-2 | 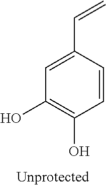 | 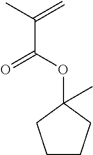 | 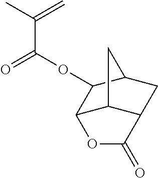 [SMILES: C=C(C)C(=O)OC1C2CC3C(=O)OC1C3C2] | 30/20/50 | 11,700 | 1.55 | Not used | Not used |

In the tables, the respective abbreviations represent the following compounds.
DMAP: 4-Dimethylaminopyridine
CSA: (±)-10-camphorsulfonic acid
PTS: p-Toluenesulfonic acid
HCl: Hydrochloric acid
CF₃COOH: Trifluoroacetic acid
DBU: Diazabicycloundecene

In addition, in the tables, pKa represents an acid dissociation constant and the pKa of a basic substance represents the pKa of the conjugate acid.

As components other than the resins used in the preparation of the resist composition, the photoacid generator, the basic compound, the surfactant, the hydrophobic resin, and the solvent are as follows.

[Photoacid Generator]

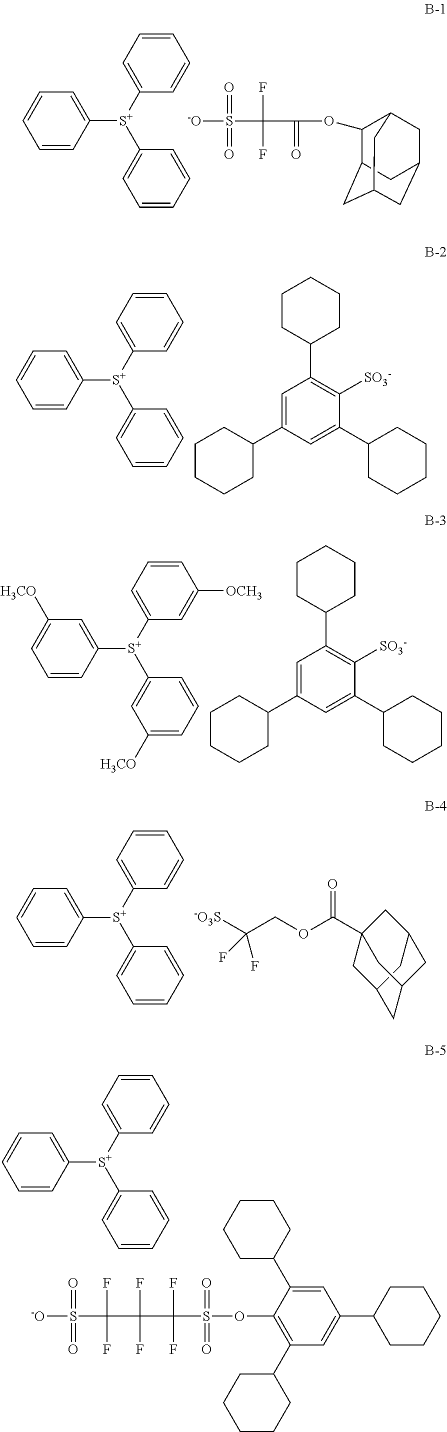

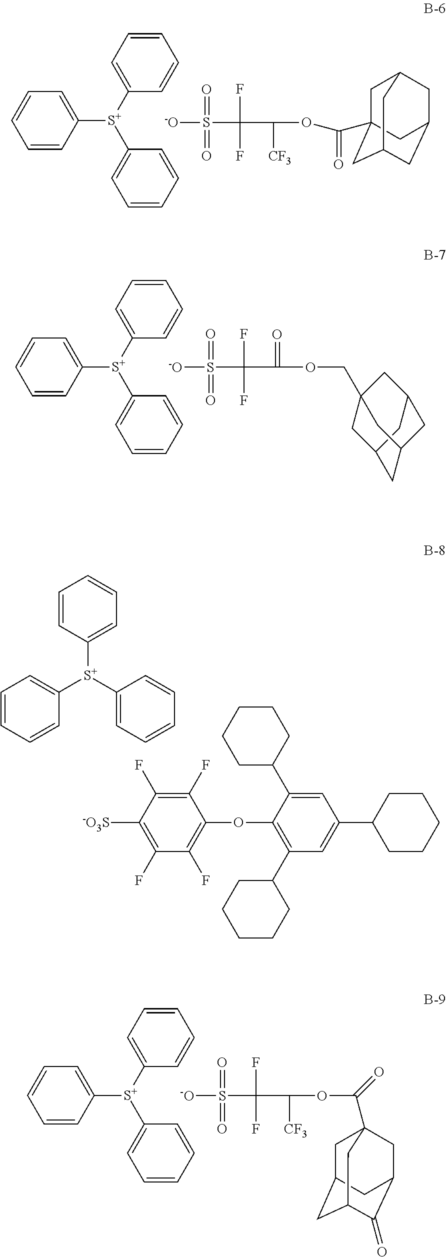

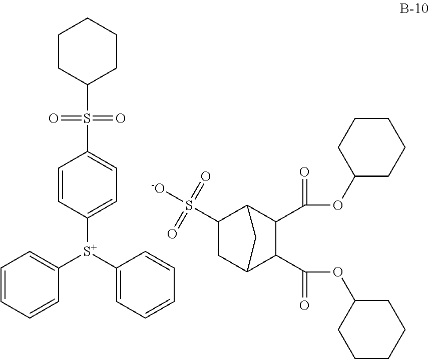

[Basic Compound]

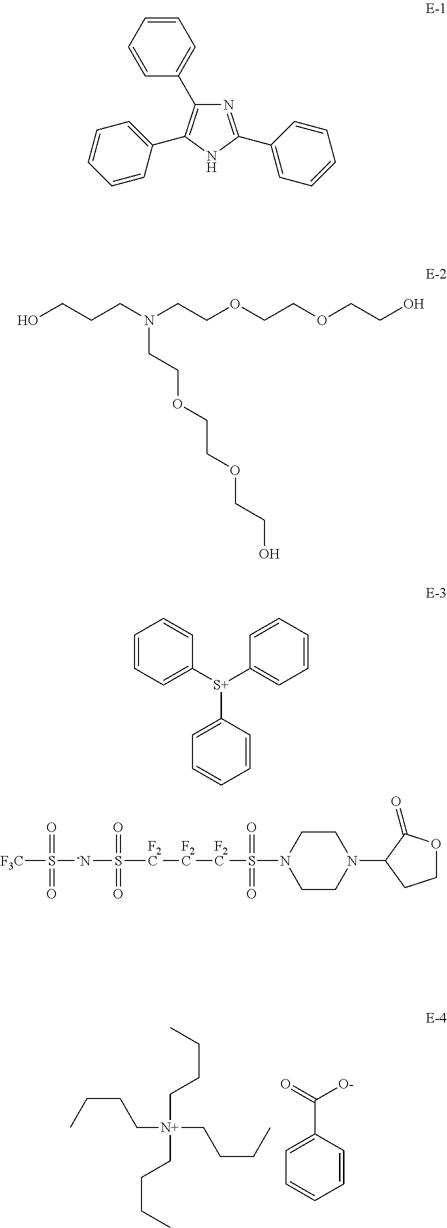

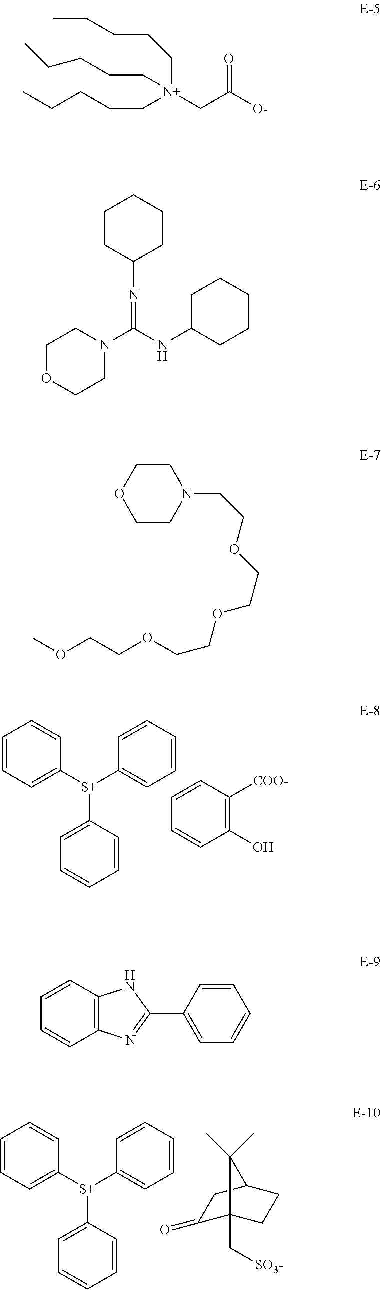

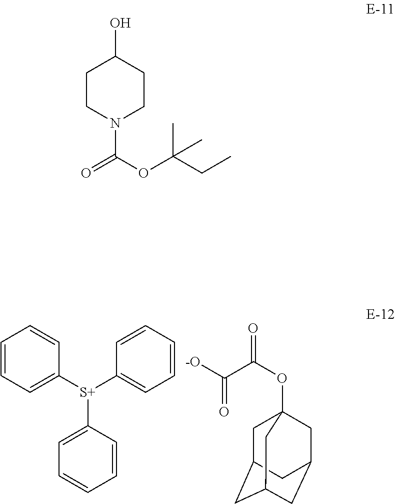

W-1: MEGAFACE F176 (manufactured by DIC Corp.) (fluorine-based)
W-2: MEGAFACE R08 (manufactured by DIC Corp.) (fluorine- and silicon-based)
W-3: Polysiloxane Polymer KP-341 (manufactured by Shin-Etsu Chemical Co., Ltd.)) (silicon-based)
W-4: TROYSOL S-366 (manufactured by Troy Chemical Corp.)
W-5: KH-20 (manufactured by Asahi Glass Co. Ltd.)

[Hydrophobic Resin]

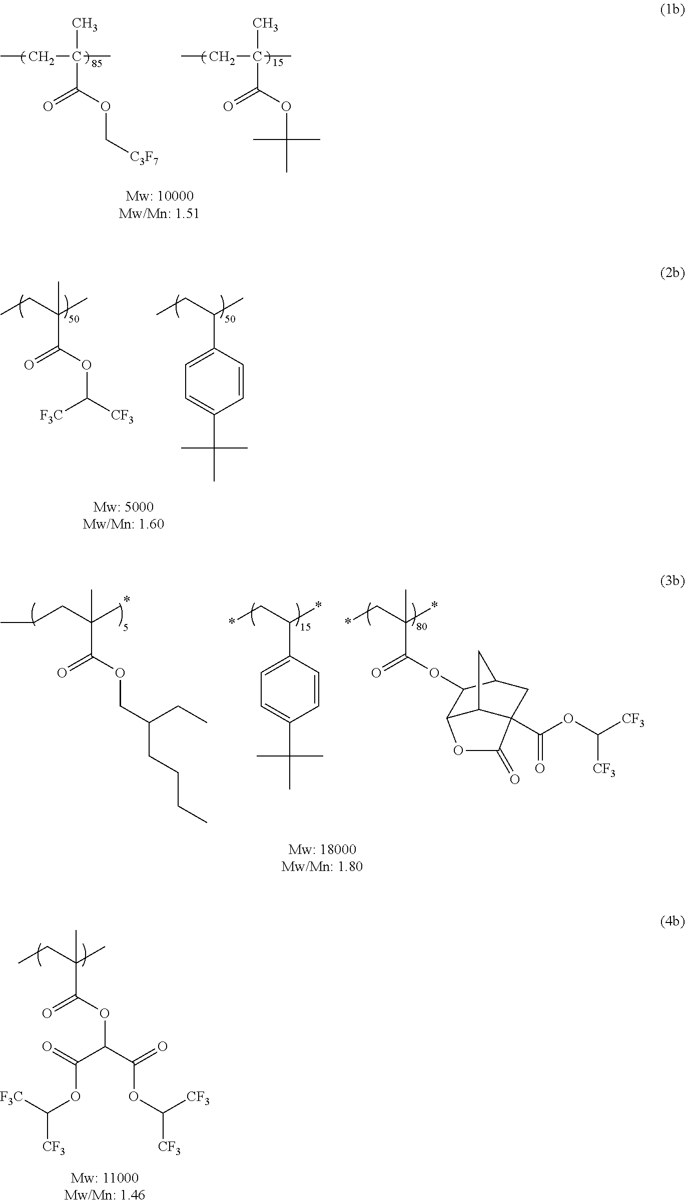

[Solvent]
C1: Propylene glycol monomethyl ether acetate (PGMEA)
C2: Propylene glycol monomethyl ether (PGME)
C3: Ethyl lactate
C4: Cyclohexanone
C5: 2-Heptanone
C6: γ-Butyrolactone

[Developer and Rinsing Liquid]
G1: Butyl acetate
G2: 2-Heptanone
G3: Diisobutyl ketone
G4: Isoamyl acetate
G5: Dibutyl ether
G6: Undecane

<Preparation of Resist Composition>

A resist composition was prepared by mixing the respective components shown in Table 2 (the concentrations (% by mass) of the respective components represent the contents of the respective components with respect to the total solid content) and filtering each of the components using a polyethylene filter with a pore size of 0.03 μm.

TABLE 2

| Resist | | Photoacid | Basic | Hydrophobic | | |
|---|---|---|---|---|---|---|
| composition | Resin | generator | compound | resin | Surfactant | Solvent |
| N1 | A-1 | B-4 | E-1 | None | None | C1/C2 |
| | 0.77 g | 0.2 g | 0.03 g | | | 60 g/15 g |
| N2 | A-1 | B-5 | E-1 | None | None | C1/C2 |
| | 0.77 g | 0.2 g | 0.03 g | | | 60 g/15 g |
| N3 | A-1 | B-4 | E-8 | None | None | C1/C2 |
| | 0.77 g | 0.2 g | 0.03 g | | | 60 g/15 g |
| N4 | A-1 | B-1 | E-1 | None | None | C1/C3 |
| | 0.77 g | 0.2 g | 0.03 g | | | 60 g/15 g |
| N5 | A-1 | B-4 | E-1 | 1b | None | C1/C2 |
| | 0.76 g | 0.2 g | 0.03 g | 0.01 g | | 60 g/15 g |
| N6 | A-1 | B-4 | E-1 | 2b | None | C1/C2 |
| | 0.76 g | 0.2 g | 0.03 g | 0.01 g | | 60 g/15 g |
| N7 | A-1 | B-4 | E-1 | 3b | None | C1/C2 |
| | 0.76 g | 0.2 g | 0.03 g | 0.01 g | | 60 g/15 g |
| N8 | A-1 | B-4 | E-1 | 4b | None | C1/C2 |
| | 0.76 g | 0.2 g | 0.03 g | 0.01 g | | 60 g/15 g |
| N9 | A-2 | B-4 | E-1 | None | None | C1/C2 |
| | 0.77 g | 0.2 g | 0.03 g | | | 60 g/15 g |
| N10 | A-3 | B-4 | E-1 | None | None | C1/C2 |
| | 0.77 g | 0.2 g | 0.03 g | | | 60 g/15 g |
| N11 | A-4 | B-4 | E-1 | None | None | C1/C2 |
| | 0.77 g | 0.2 g | 0.03 g | | | 60 g/15 g |
| N12 | A-5 | B-4 | E-1 | None | None | C1/C2 |
| | 0.77 g | 0.2 g | 0.03 g | | | 60 g/15 g |
| N13 | A-6 | B-4 | E-1 | None | None | C1/C2 |
| | 0.77 g | 0.2 g | 0.03 g | | | 60 g/15 g |
| N14 | A-6 | B-9 | E-1 | None | None | C1/C2 |
| | 0.77 g | 0.2 g | 0.03 g | | | 60 g/15 g |
| N15 | A-6 | B-4/B-8 | E-1 | None | None | C1/C2 |
| | 0.77 g | 0.1 g/0.1 g | 0.03 g | | | 60 g/15 g |
| N16 | A-6 | B-4 | E-5 | None | None | C1/C2 |
| | 0.77 g | 0.2 g | 0.03 g | | | 60 g/15 g |
| N17 | A-7 | B-4 | E-1 | None | None | C1/C2 |
| | 0.77 g | 0.2 g | 0.03 g | | | 60 g/15 g |
| N18 | A-7 | B-5 | E-1 | None | None | C1/C2 |
| | 0.77 g | 0.2 g | 0.03 g | | | 60 g/15 g |
| N19 | A-8 | B-4 | E-1 | None | None | C1/C2 |
| | 0.77 g | 0.2 g | 0.03 g | | | 60 g/15 g |
| N20 | A-8 | B-6 | E-1 | None | None | C1/C2 |
| | 0.77 g | 0.2 g | 0.03 g | | | 60 g/15 g |
| N21 | A-8 | B-8 | E-1 | None | None | C1/C2 |
| | 0.72 g | 0.25 g | 0.03 g | | | 60 g/15 g |
| N22 | A-8 | B-4 | E-7 | None | None | C1/C2 |
| | 0.77 g | 0.2 g | 0.03 g | | | 60 g/15 g |
| N23 | A-9 | B-4 | E-1 | None | None | C1/C2 |
| | 0.77 g | 0.2 g | 0.03 g | | | 60 g/15 g |
| N24 | A-9 | B-4 | E-9 | None | None | C1/C2 |
| | 0.77 g | 0.2 g | 0.03 g | | | 60 g/15 g |
| N25 | A-10 | B-4 | E-1 | None | None | C1/C2 |
| | 0.77 g | 0.2 g | 0.03 g | | | 60 g/15 g |
| N26 | A-11 | B-4 | E-1 | None | None | C1/C2 |
| | 0.77 g | 0.2 g | 0.03 g | | | 60 g/15 g |
| N27 | A-12 | B-4 | E-1 | None | None | C1/C2 |
| | 0.77 g | 0.2 g | 0.03 g | | | 60 g/15 g |
| N28 | A-13 | B-4 | E-1 | None | None | C1/C2 |
| | 0.77 g | 0.2 g | 0.03 g | | | 60 g/15 g |
| N29 | A-13 | B-8 | E-2 | None | None | C1/C2 |
| | 0.72 g | 0.25 g | 0.03 g | | | 60 g/15 g |
| N30 | A-14 | B-4 | E-1 | None | W-1 | C1/C2 |
| | 0.76 g | 0.2 g | 0.03 g | | 0.01 g | 60 g/15 g |
| N31 | A-15 | B-4 | E-1 | None | None | C1/C2 |
| | 0.77 g | 0.2 g | 0.03 g | | | 60 g/15 g |
| N32 | A-16 | B-2 | E-1 | None | None | C1/C3 |
| | 0.72 g | 0.25 g | 0.03 g | | | 60 g/15 g |
| N33 | A-16 | B-3 | E-1 | None | None | C1/C3 |
| | 0.72 g | 0.25 g | 0.03 g | | | 60 g/15 g |
| N34 | A-17 | B-4 | E-1 | None | None | C1/C2 |
| | 0.77 g | 0.2 g | 0.03 g | | | 60 g/15 g |
| N35 | A-17 | B-7 | E-1 | None | None | C1/C2 |
| | 0.77 g | 0.2 g | 0.03 g | | | 60 g/15 g |
| N36 | A-18 | B-4 | E-1 | None | None | C1/C2 |
| | 0.77 g | 0.2 g | 0.03 g | | | 60 g/15 g |
| N37 | A-19 | B-4 | E-1 | None | None | C1/C2 |
| | 0.72 g | 0.25 g | 0.03 g | | | 60 g/15 g |
| N38 | A-20 | B-4 | E-1 | None | None | C1/C2 |
| | 0.77 g | 0.2 g | 0.03 g | | | 60 g/15 g |
| N39 | A-1/A-20 | B-4 | E-1 | None | None | C1/C2 |
| | 0.4 g/0.37 g | 0.2 g | 0.03 g | | | 60 g/15 g |
| N40 | A-20 | B-8 | E-1 | None | None | C1/C2 |
| | 0.72 g | 0.25 g | 0.03 g | | | 60 g/15 g |
| N41 | A-20 | B-4 | E-3 | None | W-2 | C1/C2 |
| | 0.77 g | 0.2 g | 0.03 g | | 0.01 g | 60 g/15 g |
| N42 | A-20 | B-5 | E-4 | None | None | C1/C2 |
| | 0.77 g | 0.2 g | 0.03 g | | | 60 g/15 g |
| N43 | A-21 | B-4 | E-1 | None | None | C1/C2 |
| | 0.77 g | 0.2 g | 0.03 g | | | 60 g/15 g |
| N44 | A-22 | B-4 | E-1 | None | None | C1/C2 |
| | 0.77 g | 0.2 g | 0.03 g | | | 60 g/15 g |
| N45 | A-23 | B-4 | E-1 | None | None | C1/C2 |
| | 0.77 g | 0.2 g | 0.03 g | | | 60 g/15 g |
| N46 | A-23 | B-4 | E-11 | None | None | C1/C2 |
| | 0.77 g | 0.2 g | 0.03 g | | | 60 g/15 g |
| N47 | A-24 | B-4 | E-1 | None | None | C1/C2 |
| | 0.77 g | 0.2 g | 0.03 g | | | 60 g/15 g |
| N48 | A-25 | B-4 | E-1 | None | None | C1/C2 |
| | 0.77 g | 0.2 g | 0.03 g | | | 60 g/15 g |
| N49 | A-26 | B-10 | E-1 | None | None | C1/C6 |
| | 0.72 g | 0.25 g | 0.03 g | | | 60 g/15 g |
| N50 | A-26 | B-3 | E-6 | None | None | C1/C3 |
| | 0.72 g | 0.25 g | 0.03 g | | | 60 g/15 g |
| N51 | A-27 | B-4 | E-1 | None | None | C1/C2 |
| | 0.77 g | 0.2 g | 0.03 g | | | 60 g/15 g |
| N52 | A-27 | B-5 | E-5 | None | None | C1/C2 |
| | 0.77 g | 0.2 g | 0.03 g | | | 60 g/15 g |
| N53 | A-28 | B-4 | E-1 | None | None | C1/C2 |
| | 0.77 g | 0.2 g | 0.03 g | | | 60 g/15 g |
| N54 | A-29 | B-4 | E-1 | None | None | C1/C2 |
| | 0.77 g | 0.2 g | 0.03 g | | | 60 g/15 g |
| N55 | A-30 | B-4 | E-1 | None | None | C1/C2 |
| | 0.77 g | 0.2 g | 0.03 g | | | 60 g/15 g |
| N56 | A-31 | B-4 | E-1 | None | None | C1/C2 |
| | 0.77 g | 0.2 g | 0.03 g | | | 60 g/15 g |
| N57 | A-31 | B-1 | E-1 | None | None | C1/C4 |
| | 0.77 g | 0.2 g | 0.03 g | | | 60 g/15 g |
| N58 | A-32 | B-4 | E-1 | None | None | C1/C2 |
| | 0.77 g | 0.2 g | 0.03 g | | | 60 g/15 g |
| N59 | A-33 | B-4 | E-1 | None | None | C1/C2 |
| | 0.77 g | 0.2 g | 0.03 g | | | 60 g/15 g |
| N60 | A-34 | B-4 | E-1 | None | None | C1/C2 |
| | 0.77 g | 0.2 g | 0.03 g | | | 60 g/15 g |
| N61 | A-35 | B-3 | E-1 | None | None | C1/C3 |
| | 0.72 g | 0.25 g | 0.03 g | | | 60 g/15 g |
| N62 | A-35 | B-10 | E-7 | None | None | C1/C3 |
| | 0.72 g | 0.25 g | 0.03 g | | | 60 g/15 g |
| N63 | A-36 | B-4 | E-1 | None | None | C1/C2 |
| | 0.77 g | 0.2 g | 0.03 g | | | 60 g/15 g |
| N64 | A-37 | B-4 | E-1 | None | None | C1/C2 |
| | 0.77 g | 0.2 g | 0.03 g | | | 60 g/15 g |
| N65 | A-37 | B-8 | E-12 | None | W-3 | C1/C2 |
| | 0.77 g | 0.2 g | 0.03 g | | 0.01 g | 60 g/15 g |
| N66 | A-38 | B-4 | E-1 | None | None | C1/C2 |
| | 0.77 g | 0.2 g | 0.03 g | | | 60 g/15 g |
| N67 | A-38 | B-5 | E-1 | None | None | C1/C2 |
| | 0.77 g | 0.2 g | 0.03 g | | | 60 g/15 g |
| N68 | A-38 | B-4 | E-8 | None | None | C1/C2 |
| | 0.77 g | 0.2 g | 0.03 g | | | 60 g/15 g |
| N69 | A-38 | B-4 | E-1 | 3b | None | C1/C2 |
| | 0.76 g | 0.2 g | 0.03 g | 0.01 g | | 60 g/15 g |
| N70 | A-39 | B-4 | E-1 | None | None | C1/C2 |
| | 0.77 g | 0.2 g | 0.03 g | | | 60 g/15 g |
| N71 | A-40 | B-4 | E-1 | None | None | C1/C2 |
| | 0.77 g | 0.2 g | 0.03 g | | | 60 g/15 g |
| N72 | A-41 | B-4 | E-1 | None | None | C1/C2 |
| | 0.77 g | 0.2 g | 0.03 g | | | 60 g/15 g |
| N73 | A-42 | B-4 | E-1 | None | None | C1/C2 |
| | 0.77 g | 0.2 g | 0.03 g | | | 60 g/15 g |
| N74 | A-42 | B-7 | E-1 | None | None | C1/C5 |
| | 0.72 g | 0.25 g | 0.03 g | | | 60 g/15 g |
| N75 | A-43 | B-4 | E-1 | None | None | C1/C2 |
| | 0.77 g | 0.2 g | 0.03 g | | | 60 g/15 g |
| N76 | A-43 | B-4 | E-1/E-7 | None | None | C1/C2 |
| | 0.77 g | 0.2 g | 0.02 g/0.01 g | | | 60 g/15 g |
| N77 | A-44 | B-4 | E-1 | None | None | C1/C2 |
| | 0.77 g | 0.2 g | 0.03 g | | | 60 g/15 g |
| N78 | A-44 | B-4 | E-10 | None | W-4 | C1/C2 |
| | 0.76 g | 0.2 g | 0.03 g | | 0.01 g | 60 g/15 g |
| N79 | A-45 | B-2 | E-1 | None | None | C1/C3 |
| | 0.72 g | 0.25 g | 0.03 g | | | 60 g/15 g |
| N80 | A-44/A-45 | B-8 | E-1 | None | None | C1/C3 |
| | 0.36 g/0.36 g | 0.25 g | 0.03 g | | | 60 g/15 g |
| N81 | A-46 | B-4 | E-1 | None | None | C1/C2 |
| | 0.77 g | 0.2 g | 0.03 g | | | 60 g/15 g |
| N82 | A-47 | B-4 | E-1 | None | None | C1/C2 |
| | 0.77 g | 0.2 g | 0.03 g | | | 60 g/15 g |
| N83 | A-48 | B-4 | E-1 | None | None | C1/C2 |
| | 0.77 g | 0.2 g | 0.03 g | | | 60 g/15 g |
| N84 | A-48 | B-10 | E-8 | None | None | C1/C2 |
| | 0.77 g | 0.2 g | 0.03 g | | | 60 g/15 g |
| N85 | A-49 | B-4 | E-1 | None | None | C1/C2 |
| | 0.77 g | 0.2 g | 0.03 g | | | 60 g/15 g |
| N86 | A-49 | B-4 | E-2 | None | None | C1/C2 |
| | 0.77 g | 0.2 g | 0.03 g | | | 60 g/15 g |
| N87 | A-50 | B-4 | E-1 | None | None | C1/C2 |
| | 0.77 g | 0.2 g | 0.03 g | | | 60 g/15 g |
| N88 | A-51 | B-4 | E-1 | None | None | C1/C2 |
| | 0.77 g | 0.2 g | 0.03 g | | | 60 g/15 g |
| N89 | A-52 | B-4 | E-1 | None | None | C1/C2 |
| | 0.77 g | 0.2 g | 0.03 g | | | 60 g/15 g |
| N90 | A-52 | B-4 | E-9 | None | None | C1/C2 |
| | 0.77 g | 0.2 g | 0.03 g | | | 60 g/15 g |
| N91 | A-53 | B-4 | E-1 | None | None | C1/C2 |
| | 0.77 g | 0.2 g | 0.03 g | | | 60 g/15 g |
| N92 | A-54 | B-4 | E-1 | None | None | C1/C2 |
| | 0.77 g | 0.2 g | 0.03 g | | | 60 g/15 g |
| N93 | A-55 | B-4 | E-1 | None | None | C1/C2 |
| | 0.77 g | 0.2 g | 0.03 g | | | 60 g/15 g |
| N94 | A-55 | B-1 | E-1 | None | None | C1/C2 |
| | 0.77 g | 0.2 g | 0.03 g | | | 60 g/15 g |
| N95 | A-56 | B-4 | E-1 | None | None | C1/C2 |
| | 0.77 g | 0.2 g | 0.03 g | | | 60 g/15 g |
| N96 | A-57 | B-10 | E-1 | None | None | C1/C3 |
| | 0.77 g | 0.2 g | 0.03 g | | | 60 g/15 g |
| N97 | A-57 | B-10 | E-11 | None | None | C1/C3 |
| | 0.77 g | 0.2 g | 0.03 g | | | 60 g/15 g |
| N98 | A-58 | B-4 | E-1 | None | None | C1/C2 |
| | 0.77 g | 0.2 g | 0.03 g | | | 60 g/15 g |
| N99 | A-59 | B-4 | E-1 | None | None | C1/C2 |
| | 0.77 g | 0.2 g | 0.03 g | | | 60 g/15 g |
| N100 | A-60 | B-4 | E-1 | None | None | C1/C2 |
| | 0.77 g | 0.2 g | 0.03 g | | | 60 g/15 g |
| N101 | A-61 | B-4 | E-1 | None | None | C1/C2 |
| | 0.77 g | 0.2 g | 0.03 g | | | 60 g/15 g |
| N102 | A-62 | B-4 | E-1 | None | None | C1/C2 |
| | 0.77 g | 0.2 g | 0.03 g | | | 60 g/15 g |
| N103 | A-62 | B-4 | E-5 | None | W-5 | C1/C2 |
| | 0.76 g | 0.2 g | 0.03 g | | 0.01 g | 60 g/15 g |
| N104 | A-63 | B-4 | E-1 | None | None | C1/C2 |
| | 0.77 g | 0.2 g | 0.03 g | | | 60 g/15 g |
| N105 | A-64 | B-3 | E-1 | None | None | C1/C3 |
| | 0.72 g | 0.25 g | 0.03 g | | | 60 g/15 g |
| N106 | A-65 | B-4 | E-1 | None | None | C1/C2 |
| | 0.77 g | 0.2 g | 0.03 g | | | 60 g/15 g |
| N107 | A-66 | B-4 | E-1 | None | None | C1/C2 |
| | 0.77 g | 0.2 g | 0.03 g | | | 60 g/15 g |
| N108 | A-67 | B-4 | E-1 | None | None | C1/C2 |
| | 0.77 g | 0.2 g | 0.03 g | | | 60 g/15 g |
| N109 | A-67 | B-6 | E-1 | None | None | C1/C2 |
| | 0.77 g | 0.2 g | 0.03 g | | | 60 g/15 g |
| N110 | A-67 | B-4 | E-3 | None | None | C1/C2 |
| | 0.77 g | 0.2 g | 0.03 g | | | 60 g/15 g |
| N111 | A-68 | B-4 | E-1 | None | None | C1/C2 |
| | 0.77 g | 0.2 g | 0.03 g | | | 60 g/15 g |
| N112 | A-69 | B-4 | E-1 | None | None | C1/C2 |
| | 0.77 g | 0.2 g | 0.03 g | | | 60 g/15 g |
| N113 | A-70 | B-4 | E-1 | None | None | C1/C2 |
| | 0.77 g | 0.2 g | 0.03 g | | | 60 g/15 g |
| N114 | A-71 | B-4 | E-1 | None | None | C1/C2 |
| | 0.77 g | 0.2 g | 0.03 g | | | 60 g/15 g |
| N115 | A-72 | B-4 | E-1 | None | None | C1/C2 |
| | 0.77 g | 0.2 g | 0.03 g | | | 60 g/15 g |
| N116 | A-72 | B-4/B-5 | E-1 | None | None | C1/C2 |
| | 0.77 g | 0.1 g/0.1 g | 0.03 g | | | 60 g/15 g |
| N117 | A-73 | B-4 | E-1 | None | None | C1/C2 |
| | 0.77 g | 0.2 g | 0.03 g | | | 60 g/15 g |
| N118 | A-74 | B-4 | E-1 | None | None | C1/C2 |
| | 0.77 g | 0.2 g | 0.03 g | | | 60 g/15 g |
| N119 | A-75 | B-4 | E-1 | None | None | C1/C2 |
| | 0.77 g | 0.2 g | 0.03 g | | | 60 g/15 g |
| NR1 | R-1 | B-4 | E-1 | None | | C1/C2 |
| | 0.77 g | 0.2 g | 0.03 g | | | 60 g/15 g |
| NR2 | R-2 | B-4 | E-1 | None | | C1/C2 |
| | 0.77 g | 0.2 g | 0.03 g | | | 60 g/15 g |

[Evaluation]

The resist compositions were used for evaluation by the following methods.

[Formation of Resist Pattern (Line-and-Space Pattern)/EUV Exposure (Solvent Development)]

A composition for forming an organic antireflection film, ARC29SR (manufactured by Brewer Science, Inc.), was applied onto a silicon wafer and baked at 205° C. for 60 seconds to form an antireflection film having a film thickness of 86 nm on the silicon wafer. Then, a resist composition shown in Table 2 was applied onto the antireflection film and baked at 120° C. for 60 seconds to form a resist film having a thickness of 40 nm on the silicon wafer.

A silicon wafer comprising the resist film was subjected to pattern exposure through an exposure mask (a mask with line/space=1/1), using an EUV exposure device (Micro Exposure Tool manufactured by Exitech Ltd., NA 0.3, Quadrupole, an outer sigma of 0.68, and an inner sigma of 0.36). After the pattern exposure, the exposed silicon wafer comprising the resist film was placed on a heated hot plate, with the silicon wafer surface being on the lower side and baked at a temperature described in Table 3 for 60 seconds. The baked resist film was puddle-developed for 30 seconds with a developer described in Table 3 and then rinsed with a rinsing liquid described in Table 3. Subsequently, the wafer was rotated for 30 seconds at a rotation speed of 2,000 rpm and then a 1:1 line-and-space pattern having a line width of 16 to 30 nm was obtained. In addition, an optimal exposure dose (Eopt) in the evaluation of a resolution and scum which will be described later was taken as irradiation energy at a time of resolution of a 1:1 line-and-space pattern with a line width of 30 nm.

[Evaluation of Resist Pattern/EUV Exposure]

Performance evaluation of a resist pattern was performed using a scanning electron microscope (S-9380II manufactured by Hitachi Ltd.).

<Resolution>

Each of the resist films was exposed at an optimal exposure dose (Eopt) and a limit resolution (a minimum line width for separate resolution while not being resolved) in a case of forming a 1:1 line-and-space pattern with a line width of 16 to 30 nm was taken as a resolution (nm). A smaller value thereof indicates that the resist film has excellent resolution, which is thus preferable.

<Scum Evaluation>

In the resolution evaluation above, the scum was evaluated as follows.

A: Scum was not seen at all.

B: At a line width which is larger than the limit resolution, scum was seen.

[Resist Pattern (Formation of Line-and-Space Pattern)/EUV Exposure (Alkali Development)]

A 1:1 line-and-space pattern was formed according to the same procedure as above except that an aqueous tetramethylammonium hydroxide solution (2.38% by mass, denoted as TMAH in Table 4) was used instead of a developer described in Table 3, and pure water was used instead of a rinsing liquid described in Table 3, and the resolution and the scum were evaluated. The results are shown in Table 4.

[Evaluation of Case Using Electron Beam (EB) Irradiating Apparatus]

A pattern was formed by the same method except that exposure was performing using an electron beam irradiating apparatus (JBX 6000 manufactured by JEOL Ltd., an accelerating voltage of 50 keV) instead of the EUV exposure device, while changing the irradiation dose so as to form a line-and-space pattern (longitudinal direction: 0.2 mm, lithography lines: 40 lines) having a line width of 18 to 30 nm at 2.5 nm intervals, and the resolution and the scum were evaluated. Further, as the developer and the rinsing liquid, those described in Tables 5 and 6, respectively, were used.

TABLE 3

| | Resist | PEB | | | Limit resolution | |
|---|---|---|---|---|---|---|
| EUV evaluation results | composition | (° C.) | Developer | Rinsing liquid | (nm) | Scum |
| Example 1E | N1 | 90 | G1 | None | 16 | A |
| Example 2E | N1 | 90 | G1 | G5 | 16 | A |
| Example 3E | N1 | 90 | G1 | G6 | 16 | A |
| Example 4E | N2 | 90 | G1 | None | 16 | A |
| Example 5E | N3 | 90 | G1 | None | 17 | A |
| Example 6E | N4 | 90 | G1 | None | 16 | A |
| Example 7E | N5 | 90 | G1 | None | 16 | A |
| Example 8E | N6 | 90 | G1 | None | 16 | A |
| Example 9E | N7 | 90 | G1 | None | 16 | A |
| Example 10E | N8 | 90 | G1 | None | 16 | A |
| Example 11E | N9 | 90 | G1 | None | 16 | A |
| Example 12E | N10 | 90 | G1 | None | 18 | A |
| Example 13E | N11 | 90 | G1 | None | 19 | A |
| Example 14E | N12 | 90 | G1 | None | 22 | A |
| Example 15E | N13 | 90 | G1 | None | 17 | A |
| Example 16E | N13 | 90 | G4 | None | 16 | A |
| Example 17E | N13 | 90 | G4 | G6 | 16 | A |
| Example 18E | N13 | 90 | G3 | None | 16 | A |
| Example 19E | N14 | 90 | G1 | None | 17 | A |
| Example 20E | N15 | 90 | G1 | None | 17 | A |
| Example 21E | N16 | 90 | G1 | None | 17 | A |
| Example 22E | N17 | 90 | G1 | None | 20 | A |
| Example 23E | N18 | 90 | G1 | None | 19 | A |
| Example 24E | N19 | 100 | G1 | None | 17 | A |
| Example 25E | N19 | 90 | G2 | None | 17 | A |
| Example 26E | N25 | 90 | G1 | None | 17 | A |
| Example 27E | N26 | 90 | G1 | None | 17 | A |
| Example 28E | N27 | 85 | G1 | None | 16 | A |
| Example 29E | N28 | 80 | G1 | None | 17 | A |
| Example 30E | N28 | 80 | G4 | None | 16 | A |
| Example 31E | N29 | 90 | G1 | None | 17 | A |
| Example 32E | N30 | 110 | G1 | None | 17 | A |
| Example 33E | N36 | 85 | G1 | None | 16 | A |
| Example 34E | N37 | 90 | G4 | None | 19 | A |
| Example 35E | N38 | 90 | G1 | None | 16 | A |
| Example 36E | N38 | 90 | G1 | G6 | 16 | A |
| Example 37E | N39 | 90 | G1 | None | 16 | A |
| Example 38E | N40 | 90 | G1 | None | 17 | A |
| Example 39E | N41 | 90 | G1 | None | 16 | A |
| Example 40E | N42 | 90 | G1 | None | 16 | A |
| Example 41E | N43 | 90 | G1 | None | 18 | A |
| Example 42E | N44 | 90 | G4 | None | 16 | A |
| Example 43E | N47 | 85 | G1 | None | 16 | A |
| Example 44E | N51 | 100 | G1 | None | 17 | A |
| Example 45E | N52 | 100 | G1 | None | 17 | A |
| Example 46E | N53 | 90 | G1 | None | 17 | A |
| Example 47E | N56 | 90 | G1 | None | 17 | A |
| Example 48E | N56 | 90 | G4 | None | 16 | A |
| Example 49E | N56 | 90 | G4 | G5 | 16 | A |
| Example 50E | N57 | 90 | G1 | None | 17 | A |
| Example 51E | N58 | 90 | G1 | None | 18 | A |
| Example 52E | N60 | 85 | G1 | None | 17 | A |
| Example 53E | N64 | 80 | G1 | None | 16 | A |
| Example 54E | N65 | 80 | G1 | None | 16 | A |
| Example 55E | N66 | 90 | G1 | None | 17 | A |
| Example 56E | N66 | 90 | G1 | G5 | 16 | A |
| Example 57E | N66 | 90 | G1 | G6 | 16 | A |
| Example 58E | N67 | 90 | G1 | None | 17 | A |
| Example 59E | N68 | 90 | G1 | None | 17 | A |
| Example 60E | N69 | 90 | G1 | None | 17 | A |
| Example 61E | N70 | 90 | G1 | None | 18 | A |
| Example 62E | N71 | 90 | G1 | None | 19 | A |
| Example 63E | N72 | 90 | G1 | None | 18 | A |
| Example 64E | N73 | 90 | G1 | None | 18 | A |
| Example 65E | N73 | 90 | G3 | None | 18 | A |
| Example 66E | N74 | 90 | G1 | None | 18 | A |
| Example 67E | N77 | 90 | G1 | None | 17 | A |
| Example 68E | N78 | 90 | G1 | None | 16 | A |
| Example 69E | N82 | 90 | G4 | None | 16 | A |
| Example 70E | N85 | 90 | G4 | None | 16 | A |
| Example 71E | N86 | 90 | G4 | None | 16 | A |
| Example 72E | N87 | 85 | G4 | None | 16 | A |
| Example 73E | N88 | 110 | G4 | None | 17 | A |
| Example 74E | N91 | 85 | G1 | None | 21 | A |
| Example 75E | N92 | 90 | G1 | None | 17 | A |
| Example 76E | N98 | 90 | G1 | None | 21 | A |
| Example 77E | N99 | 100 | G1 | None | 19 | A |
| Example 78E | N100 | 90 | G1 | None | 21 | A |
| Example 79E | N101 | 90 | G1 | None | 17 | A |
| Example 80E | N107 | 90 | G1 | None | 22 | A |
| Example 81E | N108 | 90 | G1 | None | 18 | A |
| Example 82E | N108 | 90 | G1 | G6 | 18 | A |
| Example 83E | N109 | 90 | G1 | None | 18 | A |
| Example 84E | N110 | 90 | G1 | None | 18 | A |
| Example 85E | N113 | 110 | G1 | None | 18 | A |
| Example 86E | N115 | 90 | G1 | None | 17 | A |
| Example 87E | N116 | 90 | G1 | None | 16 | A |
| Example 88E | N117 | 85 | G1 | None | 19 | A |
| Example 89E | N118 | 90 | G1 | None | 18 | A |
| Comparative | NR1 | 90 | G1 | None | 26 | A |
| Example 1ER | | | | | | |
| Comparative | NR2 | 90 | G1 | None | 19 | B |
| Example 2ER | | | | | | |

TABLE 4

| (EUV evaluation | Resist | PEB | | | Limit resolution | |
|---|---|---|---|---|---|---|
| results) | composition | (° C.) | Developer | Rinsing liquid | (nm) | Scum |
| Example 1EA | N1 | 90 | TMAH | Pure water | 17 | A |
| Example 2EA | N2 | 90 | TMAH | Pure water | 17 | A |
| Example 3EA | N5 | 90 | TMAH | Pure water | 17 | A |
| Example 4EA | N6 | 90 | TMAH | Pure water | 17 | A |
| Example 5EA | N9 | 90 | TMAH | Pure water | 17 | A |
| Example 6EA | N10 | 90 | TMAH | Pure water | 18 | A |
| Example 7EA | N11 | 90 | TMAH | Pure water | 20 | A |
| Example 8EA | N12 | 90 | TMAH | Pure water | 21 | A |
| Example 9EA | N19 | 100 | TMAH | Pure water | 17 | A |
| Example 10EA | N19 | 90 | TMAH | Pure water | 17 | A |
| Example 11EA | N20 | 90 | TMAH | Pure water | 17 | A |
| Example 12EA | N21 | 90 | TMAH | Pure water | 17 | A |
| Example 13EA | N22 | 90 | TMAH | Pure water | 17 | A |
| Example 14EA | N23 | 90 | TMAH | Pure water | 17 | A |
| Example 15EA | N24 | 90 | TMAH | Pure water | 17 | A |
| Example 16EA | N25 | 90 | TMAH | Pure water | 17 | A |
| Example 17EA | N26 | 90 | TMAH | Pure water | 17 | A |
| Example 18EA | N30 | 110 | TMAH | Pure water | 17 | A |
| Example 19EA | N31 | 90 | TMAH | Pure water | 17 | A |
| Example 20EA | N32 | 80 | TMAH | Pure water | 20 | A |
| Example 21EA | N33 | 80 | TMAH | Pure water | 20 | A |
| Example 22EA | N34 | 85 | TMAH | Pure water | 17 | A |
| Example 23EA | N35 | 85 | TMAH | Pure water | 17 | A |
| Example 24EA | N37 | 90 | TMAH | Pure water | 19 | A |
| Example 25EA | N45 | 90 | TMAH | Pure water | 17 | A |
| Example 26EA | N46 | 90 | TMAH | Pure water | 17 | A |
| Example 27EA | N47 | 85 | TMAH | Pure water | 17 | A |
| Example 28EA | N48 | 85 | TMAH | Pure water | 17 | A |
| Example 29EA | N49 | 85 | TMAH | Pure water | 19 | A |
| Example 30EA | N50 | 85 | TMAH | Pure water | 19 | A |
| Example 31EA | N51 | 100 | TMAH | Pure water | 17 | A |
| Example 32EA | N52 | 100 | TMAH | Pure water | 17 | A |
| Example 33EA | N54 | 85 | TMAH | Pure water | 17 | A |
| Example 34EA | N55 | 110 | TMAH | Pure water | 17 | A |
| Example 35EA | N59 | 90 | TMAH | Pure water | 17 | A |
| Example 36EA | N60 | 85 | TMAH | Pure water | 17 | A |
| Example 37EA | N61 | 85 | TMAH | Pure water | 19 | A |
| Example 38EA | N62 | 85 | TMAH | Pure water | 19 | A |
| Example 39EA | N63 | 90 | TMAH | Pure water | 17 | A |
| Example 40EA | N64 | 80 | TMAH | Pure water | 17 | A |
| Example 41EA | N65 | 80 | TMAH | Pure water | 17 | A |
| Example 42EA | N75 | 90 | TMAH | Pure water | 17 | A |
| Example 43EA | N76 | 90 | TMAH | Pure water | 17 | A |
| Example 44EA | N77 | 90 | TMAH | Pure water | 17 | A |
| Example 45EA | N78 | 90 | TMAH | Pure water | 17 | A |
| Example 46EA | N79 | 85 | TMAH | Pure water | 19 | A |
| Example 47EA | N80 | 85 | TMAH | Pure water | 18 | A |
| Example 48EA | N81 | 85 | TMAH | Pure water | 17 | A |
| Example 49EA | N83 | 85 | TMAH | Pure water | 17 | A |
| Example 50EA | N84 | 85 | TMAH | Pure water | 17 | A |
| Example 51EA | N89 | 90 | TMAH | Pure water | 18 | A |
| Example 52EA | N90 | 90 | TMAH | Pure water | 18 | A |
| Example 53EA | N93 | 90 | TMAH | Pure water | 18 | A |
| Example 54EA | N94 | 90 | TMAH | Pure water | 18 | A |
| Example 55EA | N95 | 85 | TMAH | Pure water | 18 | A |
| Example 56EA | N96 | 85 | TMAH | Pure water | 19 | A |
| Example 57EA | N97 | 85 | TMAH | Pure water | 19 | A |
| Example 58EA | N102 | 90 | TMAH | Pure water | 18 | A |
| Example 59EA | N103 | 90 | TMAH | Pure water | 18 | A |
| Example 60EA | N104 | 110 | TMAH | Pure water | 21 | A |
| Example 61EA | N105 | 85 | TMAH | Pure water | 19 | A |
| Example 62EA | N106 | 90 | TMAH | Pure water | 21 | A |
| Example 63EA | N111 | 90 | TMAH | Pure water | 18 | A |
| Example 64EA | N112 | 90 | TMAH | Pure water | 18 | A |
| Example 65EA | N113 | 110 | TMAH | Pure water | 18 | A |
| Example 66EA | N114 | 85 | TMAH | Pure water | 19 | A |
| Example 67EA | N119 | 85 | TMAH | Pure water | 18 | A |
| Comparative | NR1 | 90 | TMAH | Pure water | 27 | A |
| Example 1EA | | | | | | |
| Comparative | NR2 | 90 | TMAH | Pure water | 20 | B |
| Example 2EA | | | | | | |

TABLE 5

| (EB evaluation | Resist | PEB | | | Limit resolution | |
|---|---|---|---|---|---|---|
| results) | composition | (° C.) | Developer | Rinsing liquid | (nm) | Scum |
| Example 1EB | N1 | 90 | G1 | None | 19 | A |
| Example 2EB | N1 | 90 | G1 | G5 | 18 | A |
| Example 3EB | N1 | 90 | G1 | G6 | 18 | A |
| Example 4EB | N7 | 90 | G1 | None | 18 | A |
| Example 5EB | N9 | 90 | G1 | None | 19 | A |
| Example 6EB | N10 | 90 | G1 | None | 20 | A |
| Example 7EB | N11 | 90 | G1 | None | 22 | A |
| Example 8EB | N12 | 90 | G1 | None | 23 | A |
| Example 9EB | N13 | 90 | G4 | None | 19 | A |
| Example 10EB | N15 | 90 | G1 | None | 19 | A |
| Example 11EB | N17 | 90 | G1 | None | 22 | A |
| Example 12EB | N19 | 100 | G1 | None | 19 | A |
| Example 13EB | N27 | 85 | G1 | None | 19 | A |
| Example 14EB | N36 | 85 | G1 | None | 19 | A |
| Example 15EB | N37 | 90 | G4 | None | 21 | A |
| Example 16EB | N38 | 90 | G1 | None | 19 | A |
| Example 17EB | N39 | 90 | G1 | None | 19 | A |
| Example 18EB | N40 | 90 | G1 | None | 19 | A |
| Example 19EB | N43 | 90 | G1 | None | 20 | A |
| Example 20EB | N47 | 85 | G1 | None | 19 | A |
| Example 21EB | N53 | 90 | G1 | None | 19 | A |
| Example 22EB | N56 | 90 | G1 | None | 19 | A |
| Example 23EB | N58 | 90 | G1 | None | 20 | A |
| Example 24EB | N64 | 80 | G1 | None | 19 | A |
| Example 25EB | N66 | 90 | G1 | None | 19 | A |
| Example 26EB | N68 | 90 | G1 | None | 19 | A |
| Example 27EB | N70 | 90 | G1 | None | 20 | A |
| Example 28EB | N71 | 90 | G1 | None | 22 | A |
| Example 29EB | N72 | 90 | G1 | None | 20 | A |
| Example 30EB | N73 | 90 | G1 | None | 20 | A |
| Example 31EB | N74 | 90 | G1 | None | 20 | A |
| Example 32EB | N77 | 90 | G1 | None | 19 | A |
| Example 33EB | N82 | 90 | G4 | None | 19 | A |
| Example 34EB | N85 | 90 | G4 | None | 19 | A |
| Example 35EB | N87 | 85 | G4 | None | 19 | A |
| Example 36EB | N88 | 110 | G4 | None | 19 | A |
| Example 37EB | N91 | 85 | G1 | None | 24 | A |
| Example 38EB | N92 | 90 | G1 | None | 19 | A |
| Example 39EB | N98 | 90 | G1 | None | 23 | A |
| Example 40EB | N99 | 100 | G1 | None | 21 | A |
| Example 41EB | N100 | 90 | G1 | None | 25 | A |
| Example 42EB | N101 | 90 | G1 | None | 20 | A |
| Example 43EB | N107 | 90 | G1 | None | 24 | A |
| Example 44EB | N108 | 90 | G1 | None | 20 | A |
| Example 45EB | N109 | 90 | G1 | None | 20 | A |
| Example 46EB | N110 | 90 | G1 | None | 20 | A |
| Example 47EB | N113 | 110 | G1 | None | 20 | A |
| Example 48EB | N115 | 90 | G1 | None | 19 | A |
| Example 49EB | N116 | 90 | G1 | None | 19 | A |
| Example 50EB | N117 | 85 | G1 | None | 21 | A |
| Example 51EB | N118 | 90 | G1 | None | 20 | A |
| Comparative | NR1 | 90 | G1 | None | 29 | A |
| Example 1EBR | | | | | | |
| Comparative | NR2 | 90 | G1 | None | 21 | B |
| Example 2EBR | | | | | | |

TABLE 6

| (EB evaluation | Resist | PEB | | | Limit resolution | |
|---|---|---|---|---|---|---|
| results) | composition | (° C.) | Developer | Rinsing liquid | (nm) | Scum |
| Example 1EC | N1 | 90 | TMAH | Pure water | 20 | A |
| Example 2EC | N2 | 90 | TMAH | Pure water | 20 | A |
| Example 3EC | N5 | 90 | TMAH | Pure water | 19 | A |
| Example 4EC | N9 | 90 | TMAH | Pure water | 20 | A |
| Example 5EC | N10 | 90 | TMAH | Pure water | 21 | A |
| Example 6EC | N11 | 90 | TMAH | Pure water | 23 | A |
| Example 7EC | N12 | 90 | TMAH | Pure water | 24 | A |
| Example 8EC | N19 | 90 | TMAH | Pure water | 20 | A |
| Example 9EC | N21 | 90 | TMAH | Pure water | 20 | A |
| Example 10EC | N22 | 90 | TMAH | Pure water | 20 | A |
| Example 11EC | N23 | 90 | TMAH | Pure water | 20 | A |
| Example 12EC | N25 | 90 | TMAH | Pure water | 20 | A |
| Example 13EC | N26 | 90 | TMAH | Pure water | 20 | A |
| Example 14EC | N32 | 80 | TMAH | Pure water | 22 | A |
| Example 15EC | N33 | 80 | TMAH | Pure water | 22 | A |
| Example 16EC | N34 | 85 | TMAH | Pure water | 20 | A |
| Example 17EC | N37 | 90 | TMAH | Pure water | 22 | A |
| Example 18EC | N45 | 90 | TMAH | Pure water | 19 | A |
| Example 19EC | N47 | 85 | TMAH | Pure water | 20 | A |
| Example 20EC | N49 | 85 | TMAH | Pure water | 22 | A |
| Example 21EC | N55 | 110 | TMAH | Pure water | 20 | A |
| Example 22EC | N59 | 90 | TMAH | Pure water | 20 | A |
| Example 23EC | N61 | 85 | TMAH | Pure water | 22 | A |
| Example 24EC | N63 | 90 | TMAH | Pure water | 20 | A |
| Example 25EC | N66 | 90 | TMAH | Pure water | 20 | A |
| Example 26EC | N70 | 90 | TMAH | Pure water | 21 | A |
| Example 27EC | N71 | 90 | TMAH | Pure water | 23 | A |
| Example 28EC | N72 | 90 | TMAH | Pure water | 21 | A |
| Example 29EC | N75 | 90 | TMAH | Pure water | 19 | A |
| Example 30EC | N76 | 90 | TMAH | Pure water | 19 | A |
| Example 31EC | N77 | 90 | TMAH | Pure water | 20 | A |
| Example 32EC | N79 | 85 | TMAH | Pure water | 22 | A |
| Example 33EC | N80 | 85 | TMAH | Pure water | 21 | A |
| Example 34EC | N83 | 85 | TMAH | Pure water | 20 | A |
| Example 35EC | N89 | 90 | TMAH | Pure water | 21 | A |
| Example 36EC | N93 | 90 | TMAH | Pure water | 21 | A |
| Example 37EC | N96 | 85 | TMAH | Pure water | 22 | A |
| Example 38EC | N102 | 90 | TMAH | Pure water | 21 | A |
| Example 39EC | N106 | 90 | TMAH | Pure water | 24 | A |
| Example 40EC | N111 | 90 | TMAH | Pure water | 21 | A |
| Example 41EC | N114 | 85 | TMAH | Pure water | 22 | A |
| Example 42EC | N119 | 85 | TMAH | Pure water | 21 | A |
| Comparative | NR1 | 90 | TMAH | Pure water | 30 | A |
| Example 1ECR | | | | | | |
| Comparative | NR2 | 90 | TMAH | Pure water | 22 | B |
| Example 2ECR | | | | | | |

From the results shown in Tables 4 to 6, it is seen that a resist film formed using the resist composition of each of Examples had excellent resolution. In other words, the limit resolution was low and generation of residues (scum) in the unexposed area during development was suppressed.

On the other hand, in Comparative Examples in which the resist composition NR1 containing a resin not containing the repeating unit (a) (not containing a plurality of hydroxyl groups) was used, the resist film thus formed had a high limit resolution and the effect of the present invention was not exhibited.

Furthermore, in Comparative Examples in which the resist composition NR2 containing the resin (R-2) produced by a process not including the first step and the second step was used, the resist film thus formed had low limit resolution, but residues (scum) were generated in the unexposed area after development, and thus, the effect of the present invention was not exhibited.

Moreover, each of the resist compositions of Example 1E; Example 1EA; Example 1EB; and Example 1EC in which the repeating unit containing a group that decomposes by the action of an acid to generate a polar group was represented by General Formula (3), the resist film thus formed had lower limit resolution and more excellent resolution, as compared with the resist compositions of Example 34E; Example 20EA, Example 21EA, Example 24EA, Example 29EA, Example 30EA, Example 37EA, Example 38EA, Example 46EA, Example 47EA, Example 56EA, and Example 57EA; Example 15EB; Example 14EC, Example 15EC, Example 17EC, Example 20EC, Example 23EC, Example 37EC, and Example 41EC.

In addition, in Example 47EA, the limit resolution was lower since a larger amount of the resin containing the repeating unit represented by General Formula (3) was contained, as compared with Example 46EA.

Furthermore, with each of the resist compositions of Example 1E; Example 1EA; Example 1EB; and Example 1EC, the resist film thus obtained had lower limit resolution and more excellent resolution, as compared with the resist compositions of Example 14E; Example 8EA; Example 8EB; and Example 7EC, in which Y in General Formula (2) was represented by General Formula (4) and the group represented by —OY was deprotected with a base in the second step.

Moreover, with each of the resist compositions of Example 12E; Example 7EA; Example 7EB; and Example 6EC, in which in the second step, the group represented by —OY was deprotected with a base having an acid dissociation constant of the conjugate acid of 6.0 or more, the resist film thus obtained had lower limit resolution and more excellent resolution, as compared with the resist compositions of Example 13E; Example 8EA; Example 8EB; and Example 7EC.

Furthermore, with each of the resist compositions of Example 1E; Example 1EA; Example 1EB; and Example 1EC, in which in the second step, the group represented by —OY was deprotected with a base having an acid dissociation constant of the conjugate acid of 9.0 or more, the resist film thus obtained had lower limit resolution and more excellent resolution, as compared with the resist compositions of Example 12E; Example 7EA; Example 7EB; and Example 6EC.

Moreover, with each of the resist compositions of Example 77E and Example 40EB, in which in a case where Y in General Formula (2) was represented by General Formula (5) or the repeating unit represented by General Formula (2) was represented by General Formula (6), the group represented by —OY was deprotected with an acid in the second step, the resist film thus obtained had lower limit resolution and more excellent resolution, as compared with the resist compositions of Example 74E, Example 78E; Example 37EB; and Example 41EB.

Furthermore, with each of the resist compositions of Example 57E and Example 25EB, in which in a case where the repeating unit represented by General Formula (2) was represented by General Formula (6), the group represented by —OY was deprotected with an acid in the second step, the resist film thus obtained had lower limit resolution and more excellent resolution, as compared with the resist compositions of Example 77E and Example 40EB.

Moreover, with each of the resist compositions of Example 61E and Example 27EB, in which the group represented by —OY was deprotected with an acid having an acid dissociation constant of −1.0 or more in the second step, the resist film thus obtained had lower limit resolution and more excellent resolution, as compared with the resist compositions of Example 62E and Example 28EB.

Furthermore, with each of the resist compositions of Example 60E and Example 26E, in which the group represented by —OY was deprotected with an acid having an acid dissociation constant of 1.0 or more in the second step, the resist film thus obtained had lower limit resolution and more excellent resolution, as compared with the resist compositions of Example 61E and Example 27EB.

In addition, with each of the resist compositions of Example 1E and Example 1EB, in which the content of the repeating unit represented by General Formula (2) in the resin precursor was 15% by mole or more with respect to all the repeating units of the resin precursor, the resist film thus obtained had lower limit resolution and more excellent resolution, as compared with the resist compositions of Example 22E; Example 23E; and Example 11EB.

What is claimed is:

1. A method for producing a resin containing a repeating unit represented by General Formula (1) and a repeating unit containing a group that decomposes by the action of an acid to generate a polar group, the method comprising:
a first step of obtaining a resin precursor containing a repeating unit represented by General Formula (2) and the repeating unit containing a group that decomposes by the action of an acid to generate a polar group; and
a second step of obtaining the repeating unit represented by General Formula (1) by deprotecting a group represented by —OY in the repeating unit represented by General Formula (2) in the resin precursor with an acid or a base, 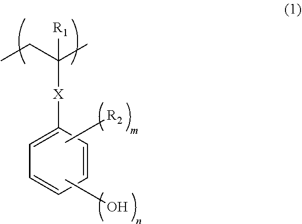
in General Formula (1), R₁ represents a hydrogen atom, a halogen atom, an alkyl group, a cycloalkyl group, a cyano group, or an alkoxycarbonyl group, X represents a single bond, —COO—, or —CONR₃—, R₂ represents a substituent, R₃ represents a hydrogen atom, or an alkyl group, n represents an integer of 2 to 5, and m represents an integer of 0 to 3; and R₂'s which are present in plural number may be the same as or different from each other, and 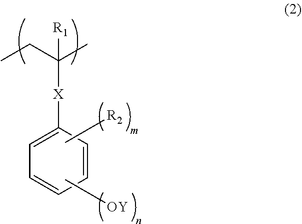
in General Formula (2), the group represented by —OY is a group that is deprotected by the action of an acid or a base to generate a hydroxyl group and Y is a protective group; in a case where two groups represented by —OY's are present in ortho positions with respect to each other, the two Y's may be bonded to each other to form a ring; and R₁, R₂, X, m, and n have the same definitions as R₁, R₂, X, m, and n in General Formula (1), respectively.

2. The method for producing a resin according to claim 1,
wherein the repeating unit containing a group that decomposes by the action of an acid to generate a polar group is represented by General Formula (3), 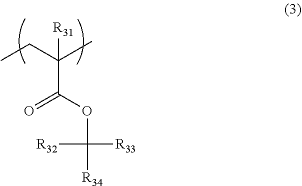
in General Formula (3), R₃₁ represents a hydrogen atom, a halogen atom, an alkyl group, a cycloalkyl group, a cyano group, or an alkoxycarbonyl group, R₃₂, R₃₃, and R₃₄ each independently represent an alkyl group or a cycloalkyl group, and R₃₃ and R₃₄ may be bonded to each other to form a ring.

3. The method for producing a resin according to claim 1,
wherein Y is represented by General Formula (4) and the group represented by —OY is deprotected with a base in the second step, 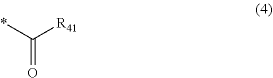
in General Formula (4), R₄₁ represents an alkyl group, a cycloalkyl group, or an aryl group, and * represents a bonding position with an oxygen atom.

4. The method for producing a resin according to claim 2,
wherein Y is represented by General Formula (4) and the group represented by —OY is deprotected with a base in the second step, 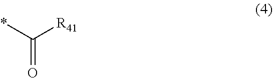
in General Formula (4), R₄₁ represents an alkyl group, a cycloalkyl group, or an aryl group, and * represents a bonding position with an oxygen atom.

5. The method for producing a resin according to claim 3,
wherein an acid dissociation constant of a conjugate acid of the base is 6.0 or more.

6. The method for producing a resin according to claim 4,
wherein an acid dissociation constant of a conjugate acid of the base is 6.0 or more.

7. The method for producing a resin according to claim 1,
wherein Y is represented by General Formula (5) and the group represented by —OY is deprotected with an acid in the second step; or
the repeating unit represented by General Formula (2) is represented by General Formula (6) and a group represented by —O—Z—O— is deprotected with an acid in the second step, 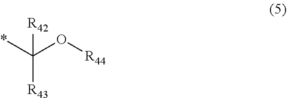
in General Formula (5), R₄₂ represents an alkyl group, R₄₃ and R₄₄ each independently represent a hydrogen atom or an alkyl group, R₄₂ and R₄₄ may be bonded to each other to form a ring, and * represents a bonding position with an oxygen atom, 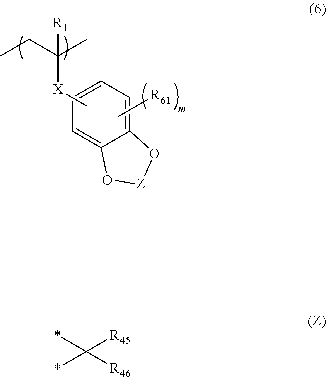
in General Formula (6), R₆₁ represents a substituent, Z represents a group represented by General Formula (Z), and R₁, X, and m have the same definitions as R₁, X, and m in General Formula (1), respectively; and in General Formula (Z), R₄₅ and R₄₆ each independently represent a hydrogen atom, an alkyl group, or an alkoxy group, provided that at least one selected from the group consisting of R₄₅ and R₄₆ is an alkyl group or an alkoxy group, and * represents a bonding position with an oxygen atom.

8. The method for producing a resin according to claim 2,
wherein Y is represented by General Formula (5) and the group represented by —OY is deprotected with an acid in the second step; or
the repeating unit represented by General Formula (2) is represented by General Formula (6) and a group represented by —O—Z—O— is deprotected with an acid in the second step, 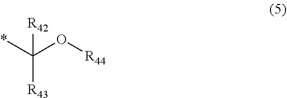
in General Formula (5), R₄₂ represents an alkyl group, R₄₃ and R₄₄ each independently represent a hydrogen atom or an alkyl group, R₄₂ and R₄₄ may be bonded to each other to form a ring, and * represents a bonding position with an oxygen atom, 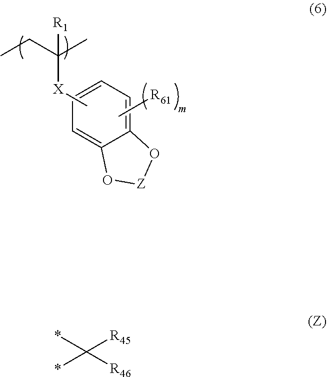
in General Formula (6), R₆₁ represents a substituent, Z represents a group represented by General Formula (Z), and R₁, X, and m have the same definitions as R₁, X, and m in General Formula (1), respectively; and in General Formula (Z), R₄₅ and R₄₆ each independently represent a hydrogen atom, an alkyl group, or an alkoxy group, provided that at least one selected from the group consisting of R₄₅ and R₄₆ is an alkyl group or an alkoxy group, and * represents a bonding position with an oxygen atom.

9. The method for producing a resin according to claim 7,
wherein the repeating unit represented by General Formula (2) is represented by General Formula (6) and the group represented by —O—Z—O— is deprotected with an acid in the second step.

10. The method for producing a resin according to claim 8,
wherein the repeating unit represented by General Formula (2) is represented by General Formula (6) and the group represented by —O—Z—O— is deprotected with an acid in the second step.

11. The method for producing a resin according to claim 7,
wherein an acid dissociation constant of the acid is −1.0 or more.

12. The method for producing a resin according to claim 8,
wherein an acid dissociation constant of the acid is −1.0 or more.

13. The method for producing a resin according to claim 9,
wherein an acid dissociation constant of the acid is −1.0 or more.

14. The method for producing a resin according to claim 1,
wherein the content of the repeating unit represented by General Formula (1) in the resin is 15% by mole or more with respect to all the repeating units in the resin.

15. A method for producing an actinic ray-sensitive or radiation-sensitive composition, the method comprising a step of mixing a resin produced by the method for producing a resin according to claim 1 and a compound that generates an acid upon irradiation with actinic rays or radiation.
